(19) United States
(12) Patent Application Publication
(10) Pub. No.: US 2022/0213296 A1
(43) Pub. Date: Jul. 7, 2022

(54) DISPERSION LIQUID, COMPOSITION, CURED FILM, COLOR FILTER, SOLID-STATE IMAGING ELEMENT, AND IMAGE DISPLAY DEVICE

(71) Applicant: FUJIFILM Corporation, Tokyo (JP)

(72) Inventors: Yushi KANEKO, Shizuoka (JP); Ryosuke KATO, Shizuoka (JP); Takahiro OYA, Shizuoka (JP); Junichi ITO, Shizuoka (JP); Yoshinori TAGUCHI, Shizuoka (JP)

(73) Assignee: FUJIFILM Corporation, Tokyo (JP)

(21) Appl. No.: 17/700,427

(22) Filed: Mar. 21, 2022

Related U.S. Application Data
(63) Continuation of application No. PCT/JP2020/032383, filed on Aug. 27, 2020.

(30) Foreign Application Priority Data
Sep. 27, 2019 (JP) 2019-177534
Jun. 10, 2020 (JP) 2020-100804

(51) Int. Cl. C08K 9/06; C08K 3/36; C08G 77/04; C08G 77/20; C08G 77/26; C08G 77/24; C08G 77/28; G03F 7/075; G03F 7/00; G02B 5/22

(52) U.S. Cl. CPC C08K 9/06; C08K 3/36; C08G 77/04; C08G 77/20; C08G 77/26; C08G 77/24; C08G 77/80; G03F 7/0757; G03F 7/0758; G03F 7/0007; G03F 7/0005; G02B 5/223; C08G 77/28

(57) ABSTRACT

A dispersion liquid contains an inorganic oxide particle surface-treated with at least one of a compound represented by Formula Si(R^{A1})(X^{A1})₃ or a compound represented by Formula Si(R^{A2})(R^{A20})(X^{A2})², polysiloxane having at least one of a T unit represented by Formula [R^{B1}SiO_{3/2}] or a D unit represented by Formula [R^{B2}R^{B20}SiO], and an organic solvent, where a content of the polysiloxane is 0.5% to 39% by mass with respect to a total amount of the inorganic oxide particle and the polysiloxane, in which in the formula, R^{A1}, R^{A2}, R^{B1}, and R^{B2} represent a functional group, X^{A1} and X^{A2} represent a hydroxyl group or a hydrolyzable group, and R^{A20} and R^{B20} represent an alkyl group or an aryl group.

### CROSS-REFERENCE TO RELATED APPLICATIONS

This application is a Continuation of PCT International Application No. PCT/JP2020/032383 filed on Aug. 27, 2020, which claims priority under 35 U.S.C § 119(a) to Japanese Patent Application No. 2019-177534 filed on Sep. 27, 2019, and Japanese Patent Application No. 2020-100804 filed on Jun. 10, 2020. Each of the above application(s) is hereby expressly incorporated by reference, in its entirety, into the present application.

### BACKGROUND OF THE INVENTION

### 1. Field of the Invention

The present invention relates to a dispersion liquid, a composition, a cured film, a color filter, a solid-state imaging element, and an image display device.

### 2. Description of the Related Art

In the related art, dispersion liquids in which inorganic oxide particles such as silica particles are dispersed in an organic solvent have been used for various use applications. For example, JP2005-184011A discloses that a composition for forming an insulating film, containing silica particles, polysiloxane, and an organic solvent, is used to form an insulating film having mechanical properties and insulating properties.

### SUMMARY OF THE INVENTION

The inventors of the present invention examined a dispersion liquid containing inorganic oxide particles, polysiloxane, and an organic solvent with reference to the formulation of the composition described in JP2005-184011A and, as a result of the examination, revealed that the viscosity of the dispersion liquid temporally changes and thus there is room for improvement in the storage stability of the dispersion liquid.

An object of the present invention is to provide a dispersion liquid having excellent storage stability and a composition containing this dispersion liquid. In addition, another object of the present invention is to provide a cured film, a color filter, a solid-state imaging element, and an image display device, which are formed from the above composition.

As a result of diligent studies to achieve the above objects, the inventors of the present invention have found that in a dispersion liquid containing inorganic oxide particles, polysiloxane, and an organic solvent, in a case where inorganic oxide particles surface-treated with a predetermined compound and polysiloxane containing a predetermined unit are used and the content of the polysiloxane with respect to the total amount of the inorganic oxide particles and the polysiloxane is within a predetermined range, a dispersion liquid having excellent storage stability is obtained and have completed the present invention.

That is, the inventors of the present invention have found that the objects can be achieved by the following configurations.

[1] A dispersion liquid comprising:

an inorganic oxide particle surface-treated with at least one compound selected from the group consisting of a compound represented by Formula A1 and a compound represented by Formula A2;

polysiloxane having at least one unit selected from the group consisting of a T unit represented by Formula B1 and a D unit represented by Formula B2; and

an organic solvent,

in which a content of the polysiloxane is 0.5% to 39% by mass with respect to a total amount of the inorganic oxide particle and the polysiloxane,

Formula A1: Si(R^{A1})(X^{A1})³

Formula A2: Si(R^{A2})(R^{A20})(X^{A2})²

Formula B1: [R^{B1}SiO_{3/2}]

Formula B2: [R^{B2}R^{B20}SiO]

in Formula A1, R^{A1} represents a monovalent functional group, and X^{A1} represents a hydroxyl group or a monovalent hydrolyzable group,

in Formula A1, three pieces of X^{A1} may be the same or different from each other,

in Formula A2, R^{A2} represents a monovalent functional group, R^{A20} represents an alkyl group or an aryl group, and X^{A2} represents a hydroxyl group or a monovalent hydrolyzable group,

in Formula A2, two pieces of X^{A2} may be the same or different from each other,

in Formula B1, R^{B1} represents a monovalent functional group, and

in Formula B2, R^{B2} represents a monovalent functional group, and R^{B20} represents an alkyl group or an aryl group.

[2] The dispersion liquid according to [1], in which a content of the polysiloxane is 1% to 25% by mass with respect to the total amount of the inorganic oxide particle and the polysiloxane.

[3] The dispersion liquid according to [1] or [2], further comprising:

water,

in which a content of the water is 0.01% to 5% by mass with respect to a total mass of the dispersion liquid.

[4] The chemical liquid according to [3], in which the content of the water is 0.1% to 3% by mass.

[5] The dispersion liquid according to any one of [1] to [4], in which R^{A1} of Formula A1, R^{A2} of Formula A2, R^{B1} of Formula B1, and R^{B2} of Formula B2 each independently contain at least one group selected from the group consisting of an aliphatic hydrocarbon group, an aryl group, an acryloyloxy group, a methacryloyloxy group, a fluoroalkyl group, a group having a polysiloxane structure, an epoxy group, an amino group, a group having a quaternary ammonium group or a salt thereof, a cyano group, and a thiol group.

[6] The dispersion liquid according to any one of [1] to [5], in which R^{A1} of Formula A1, R^{A2} of Formula A2, R^{B1} of Formula B1, and R^{B2} of Formula B2 each independently contain at least one group selected from the group consisting of a fluoroalkyl group and a group having a polysiloxane structure.

[7] The dispersion liquid according to any one of [1] to [6], in which in a case where the inorganic oxide particle is surface-treated with the compound represented by Formula A1 and the polysiloxane contains the T unit represented by Formula B1,

R^{A1} of Formula A1 and R^{B1} of Formula B1 are the same group.

[8] The dispersion liquid according to any one of [1] to [7], in which in a case where the inorganic oxide particle is surface-treated with the compound represented by Formula A2 and the polysiloxane contains the D unit represented by Formula B2,

R^{A2} of Formula A2 and R^{B2} of Formula B2 are the same group.

[9] The dispersion liquid according to any one of [1] to [8], in which the inorganic oxide particle includes silica.

[10] The dispersion liquid according to any one of [1] to [9], in which the inorganic oxide particle is a silica particle.

[11] A composition comprising:

the dispersion liquid according to any one of [1] to [10]; and

a polymerizable compound.

[12] The composition according to [11], further comprising a resin.

[13] The composition according to [11] or [12], further comprising a polymerization initiator.

[14] The composition according to any one of [11] to [13], further comprising a coloring material.

[15] A cured film formed from the composition according to any one of [11] to [14].

[16] A color filter comprising:

the cured film according to [15].

[17] A solid-state imaging element comprising:

the cured film according to [15].

[18] An image display device comprising:

the cured film according to [15].

According to the present invention, it is possible to provide a dispersion liquid having excellent storage stability and a composition containing this dispersion liquid. In addition, according to the present invention, it is also possible to provide a cured film, a color filter, a light shielding film, a solid-state imaging element, and an image display device, which are formed from the above composition.

### BRIEF DESCRIPTION OF THE DRAWINGS

FIG. 1 is a schematic cross-sectional view illustrating an example of the configuration of a solid-state imaging device.

FIG. 2 is a schematic cross-sectional view illustrating an imaging unit included in the solid-state imaging device illustrated in FIG. 1 in an enlarged manner.

FIG. 3 is a schematic cross-sectional view illustrating an example of a configuration of an infrared sensor.

FIG. 4 is a schematic view illustrating an example of a configuration of a headlight unit.

FIG. 5 is a schematic perspective view illustrating an example of a configuration of a light shielding unit of the headlight unit.

FIG. 6 is a schematic view illustrating an example of a light distribution pattern formed by the light shielding unit of the headlight unit.

FIG. 7 is a schematic view illustrating another example of the light distribution pattern formed by the light shielding unit of the headlight unit.

FIG. 8 is a graph showing a transmission spectrum of the black resist film produced in the section of Examples.

FIG. 9 is a graph showing a transmission spectrum of the black resist film produced in the section of Examples.

FIG. 10 is a graph showing a transmission spectrum of the black resist film produced in the section of Examples.

FIG. 11 is a graph showing a reflection spectrum of the black resist film produced in the section of Examples.

FIG. 12 is a graph showing a reflection spectrum of the black resist film produced in the section of Examples.

FIG. 13 is a graph showing a reflection spectrum of the black resist film produced in the section of Examples.

FIG. 14 is a schematic perspective view illustrating a light shielding film for fingerprint authentication, produced in the section of Examples.

FIG. 15 is a schematic end view illustrating a light shielding film for fingerprint authentication, produced in the section of Examples.

FIG. 16 is a schematic perspective view illustrating a light shielding film for fingerprint authentication, produced in the section of Examples.

FIG. 17 is a schematic end view illustrating a light shielding film for fingerprint authentication, produced in the section of Examples.

### DESCRIPTION OF THE PREFERRED EMBODIMENTS

Hereinafter, the present invention will be described in detail.

The description of the following configuration requirements is made based on representative embodiments of the present invention in some cases; however, the present invention is not limited to the embodiments.

It is noted that in the present specification, a numerical value range expressed using “to” means a range including numerical values described before and after “to” as a lower limit value and an upper limit value.

In the present specification, regarding the description of a group (an atomic group), in a case where whether the group is substituted or unsubstituted is not described, the group includes a group which has a substituent as well as a group which does not have a substituent. For example, an “alkyl group” includes not only an alkyl group (an unsubstituted alkyl group) which does not have a substituent but also an alkyl group (a substituted alkyl group) which has a substituent.

In addition, in the present specification, “actinic rays” or “radiation” refers to, for example, far ultraviolet rays, extreme ultraviolet rays (EUV), X-rays, electron beams. In addition, in the present specification, light refers to actinic rays and radiation. In the present specification, unless otherwise specified, “exposure” includes not only exposure with far ultraviolet rays, X-rays, EUV light, or the like, but also drawing by particle beams such as electron beams and ion beams.

In the present specification, “(meth)acrylate” represents acrylate and methacrylate. In the present specification, “(meth)acryl” represents acryl and methacryl. In the present specification, “(meth)acryloyl” represents acryloyl and methacryloyl. In the present specification, “(meth)acrylamide” represents acrylamide and methacrylamide. In the present specification, a “monomeric substance” and a “monomer” have the same definition.

In the present specification, “ppm” means “parts per million (10⁻⁶)”, “ppb” means “parts per billion (10⁻⁹)”, and “ppt” means “parts per trillion (10⁻¹²)”.

In addition, in the present specification, a weight-average molecular weight (Mw) is a value in terms of polystyrene, which is measured by gel permeation chromatography (GPC).

In the present specification, the GPC method is based on a method in which HLC-8020 GPC (manufactured by TOSOH CORPORATION) is used, TSKgel SuperHZM-H, TSKgel SuperHZ4000, and TSKgel SuperHZ2000 (manufactured by TOSOH CORPORATION, 4.6 mm ID×15 cm) are used as columns, and tetrahydrofuran (THF) is used as an eluent.

A bonding direction of a divalent group (for example, —COO—) described in the present specification is not limited, unless otherwise specified. For example, in a case where Y is —COO— in a compound represented by the general formula of “X—Y—Z”, the compound may be “X—O—CO—Z” or “X—CO—O—Z”.

In the present specification, the “total solid content” of the dispersion liquid refers to all components except for a solvent in a case where the dispersion liquid contains the solvent (the organic solvent, water, or the like).

In the present specification, the “total solid content” of the composition refers to components forming a cured film and refers to all components except a solvent in a case where the composition contains the solvent (an organic solvent, water, or the like). In addition, in a case where the components are components forming a cured film, the components are considered to be solid contents even in a case where the components are liquid components.

[Dispersion Liquid]

The dispersion liquid according to the embodiment of the present invention contains inorganic oxide particles surface-treated with at least one compound selected from the group consisting of a compound (hereinafter, also referred to as a “compound A1”) represented by Formula A1 described later and a compound (hereinafter, also referred to as a “compound A2”) represented by Formula A2 described later, polysiloxane having at least one unit selected from the group consisting of a T unit represented by Formula B1 described later and a D unit represented by Formula B2 described later, an organic solvent, where the content of the polysiloxane is 0.5% to 39% by mass with respect to the total amount of the inorganic oxide particle and the polysiloxane.

The dispersion liquid according to the embodiment of the present invention is excellent in storage stability. The details of the reason for the above effect are not clear; however, it is presumed as follows. That is, it is presumed that in the dispersion liquid containing inorganic oxide particles surface-treated with a predetermined compound, polysiloxane functions like a dispersing agent since a predetermined amount of polysiloxane are contained, whereby it is possible to suppress the temporal aggregation of the inorganic oxide particles, or the like.

In the following description, that the storage stability of the dispersion liquid is excellent is also referred to as that the effects of the present invention are excellent.

[Inorganic Oxide Particle]

The dispersion liquid according to the embodiment of the present invention contains inorganic oxide particles. The inorganic oxide particle in the present invention is surface-treated with at least one compound selected from the group consisting of the compound A1 and the compound A2.

In the following description, the compound A1 and the compound A2 may be collectively referred to as the “compound A”. The inorganic oxide particle surface-treated with the compound A is also referred to as a “surface-modified particle”. In addition, the inorganic oxide particle not surface-treated with the compound A is also referred to as an “unmodified particle”.

The content of the surface-modified particles in the dispersion liquid is preferably 1% to 100% by mass, more preferably 10% to 100% by mass, and still more preferably 20% to 100% by mass, with respect to the total solid content of the dispersion liquid, from the viewpoint that the effects of the present invention are more excellent.

In a case where the particle diameter of the surface-modified particle is large, the unevenness of the surface of the cured film (particularly, the light shielding film) obtained from the composition containing a dispersion liquid are likely to be large, and thus the low reflection properties of the cured film are more excellent. On the other hand, in a case where the particle diameter of the inorganic particles is small, the inorganic particles are more likely to be unevenly distributed on the surface side of the cured film, and thus the presence proportion of the coloring material inside the cured film is likely to be improved, and the light shielding properties of the cured film are more excellent. As described above, from the viewpoint that the balance between the low reflection properties and the light shielding properties of the cured film to be obtained (particularly, the light shielding film) is excellent, the particle diameter of the inorganic particles is preferably 1 to 200 nm, more preferably 10 to 100 nm, and still more preferably 15 to 78 nm.

It is noted that the particle diameter of the particles (the surface-modified particle, a coloring material which will be described later, or the like) in the present specification refers to an average primary particle diameter of particles measured by the following method. The average primary particle diameter can be measured using a scanning electron microscope (SEM).

A maximum length (Dmax: a maximum length between two points on a contour of the particle image) and a length vertical to the maximum length (DV-max: in a case where an image is sandwiched between two straight lines parallel to the maximum length, the shortest length that vertically connects the two straight lines) of a particle image obtained using the SEM are measured, and a geometric mean value thereof (Dmax×DV-max)^{1/2} is taken as a particle diameter. Particle diameters of 100 particles are measured by this method, and an arithmetic average value thereof is taken as an average primary particle diameter of the particles.

The refractive index of the surface-modified particle is not particularly limited; however, it is preferably 1.10 to 1.60 and more preferably 1.15 to 1.45 from the viewpoint that the low reflection properties of the cured film are more excellent.

In addition, the surface-modified particle may be a hollow particle or a solid particle.

The hollow particles refer to particles in which a cavity is present inside the particle. The hollow particle may have a structure in which the particle consists of an inner cavity and an outer shell surrounding the cavity. In addition, the hollow particle may have a structure in which a plurality of cavities are present inside the particle.

The solid particle refers to a particle in which a cavity is substantially not present in the inside of the particle.

The hollow particle preferably has a void volume of 3% or more, and the solid particle preferably has a void volume of less than 3%.

The surface-modified particle is preferably a hollow particle from the viewpoint that the effects of the present invention are more excellent.

It is conceived that since the hollow particle has a cavity inside thereof and has a low specific gravity as compared with a particle having no hollow structure, the hollow particle floats on the surface of the coating film formed from the composition, and thus the effect of being unevenly distributed on the surface of the cured film is further enhanced.

In addition, in the hollow particle, the particle itself has a low refractive index as compared with a particle having no hollow structure. For example, in a case where the hollow particle is formed of silica, the hollow silica particle has air having a low refractive index (refractive index=1.0), and thus the refractive index of the particle itself is 1.2 to 1.4, which is significantly low as compared with normal silica (refractive index=1.6). As a result, it is conceived that in a case where the cured film is formed by using the composition containing the hollow particles, the hollow particles having a low refractive index are unevenly distributed on the surface of the cured film, an anti-reflection (AR)-type low-reflection effect is achieved, and thus the low reflection properties of the cured film are improved.

Examples of the hollow particles include the hollow silica particles described in JP2001-233611A and JP3272111B.

As the hollow particle, for example, THRULYA 4110 (product name, manufactured by JGC Catalysts and Chemicals Ltd.) can also be used.

As the solid particle, IPA-ST, IPA-ST-L, IPA-ST-ZL, MIBK-ST, MIBK-ST-L, CHO-ST-M, PGM-AC-2140Y, PGM-AC-4130Y (all of them are product names, manufactured by Nissan Chemical Corporation), or the like can be used as a preferred aspect.

As the surface-modified particle, beaded silica particles which are a particle aggregate in which a plurality of silica particles are connected in a chain shape may be used. As the beaded silica particles, particles in which a plurality of spherical colloidal silica particles having a particle diameter of 5 to 50 nm are bonded to each other by metal oxide-containing silica are preferable.

Examples of the beaded colloidal silica particles include the silica sols described in JP4328935B and JP2013-253145A.

The surface-modified particle preferably has a color other than black. The surface-modified particle may have a color such as red, blue, yellow, green, purple, orange, or white, or may have no color. Among the above, the surface-modified particle is preferably white or colorless.

Examples of the inorganic oxide that constitutes at least a part of the surface-modified particle include silica (silicon oxide), titania (titanium oxide), alumina (aluminum oxide), zirconia (zircon oxide), zinc oxide, and tin oxide. Among them, silica, titania, or zirconia is preferable, and silica is more preferable from the viewpoint that the effects of the present invention are more excellent.

In other words, the surface-modified particle preferably includes silica, and it is preferably a silica particle.

The surface-modified particle may contain a component other than the inorganic oxide. The content of the inorganic oxide in the surface-modified particle is preferably 75% to 100% by mass, more preferably 90% to 100% by mass, and still more preferably 99% to 100% by mass, with respect to the total mass of the surface-modified particle.

The surface-modified particle can be said to be a particle obtained by surface-treating an unmodified particle with the compound A.

For this reason, in general, in a case where the surface-modified particle is a solid particle, the unmodified particle is also a solid particle, and in a case where the surface-modified particle is a hollow particle, the unmodified particle is also a hollow particle.

Examples of the component that constitutes the unmodified particle include the above-described inorganic oxide, and the preferred aspect thereof is the same as that of the surface-modified particle.

The compound A1 is a compound represented by Formula A1. The compound A1 is used as a so-called silane coupling agent.

Si(R^{A1})(X^{A1})³ Formula A1:

R^{A1} represents a monovalent functional group.

Examples of the monovalent functional group include a group including at least one group selected from the group consisting of an aliphatic hydrocarbon group, an aryl group, an acryloyloxy group, a methacryloyloxy group, a fluoroalkyl group, a group having a polysiloxane structure, an epoxy group, an amino group, a group having a quaternary ammonium group or a salt thereof, a cyano group, a thiol group, and an oxetanyl group.

Among the above, a group including at least one group selected from the group consisting of a fluoroalkyl group and a group having a polysiloxane structure is more preferable from the viewpoint that the cured film which is formed from the composition containing a dispersion liquid has excellent peeling resistance.

Examples of the aliphatic hydrocarbon group include an alkyl group and an alkenyl group.

The alkyl group preferably has 1 to 25 carbon atoms, more preferably 3 to 20 carbon atoms, and still more preferably 5 to 18 carbon atoms. The alkyl group may have any linear, branched or cyclic structure; however, it is preferably linear from the viewpoint that the effects of the present invention are more excellent.

The alkenyl group preferably has 2 to 20 carbon atoms, more preferably 2 to 10 carbon atoms, and still more preferably 2 to 5 carbon atoms. The alkenyl group may have any linear, branched or cyclic structure; however, it is preferably linear from the viewpoint that the effects of the present invention are more excellent.

Further, the aliphatic hydrocarbon group may be a cyclic hydrocarbon group having a bridged structure such as a norbornenyl group or a norbornyl group.

The aryl group preferably has 6 to 30 carbon atoms, more preferably 6 to 20 carbon atoms, and still more preferably 6 to 12 carbon atoms. The aryl group may be monocyclic or may have a fused-ring structure of two or more rings. The aryl group may have a substituent, and examples of the substituent include a vinyl group and a halogen atom.

The fluoroalkyl group preferably has 1 to 10 carbon atoms, more preferably 1 to 5 carbon atoms, and still more preferably 1 to 3 carbon atoms.

The amino group preferably has 0 to 20 carbon atoms, more preferably 0 to 10 carbon atoms, and still more preferably 0 to 8 carbon atoms.

Examples of the group having a polysiloxane structure include a group represented by Formula (S1).

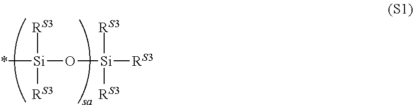

In Formula S1, * represents a bonding position.

In Formula S1, sa represents an integer of 2 to 1,000.

In Formula S1, R^{S3} represents a hydrocarbon group, which may have a substituent and has 1 to 20 carbon atoms, or a group represented by Formula S2 described later.

In Formula S1, a plurality of R^{S3}'s may be the same or different from each other.

The hydrocarbon group has 1 to 20 carbon atoms, preferably 1 to 10 carbon atoms, and more preferably 1 to 5 carbon atoms. In a case where the hydrocarbon group has a substituent, the number of carbon atoms mentioned here is intended to be the number of carbon atoms which also includes the number of carbon atoms that can be present in the substituent. The hydrocarbon group is preferably an alkyl group. The alkyl group may be linear or branched. In addition, the alkyl group may have a cyclic structure as a whole, or may partially have a cyclic structure.

Among them, it is preferable that R^{S3}'s bonded to rightmost Si in Formula S1 are each independently the hydrocarbon group.

The number of R^{S3}'s, which are groups represented by Formula S2, among “2×sa” pieces of R^{S3}'s in “—(—SiR^{S3}₂—O—)ₛₐ—” is preferably 0 to 1,000, more preferably 0 to 10, and still more preferably 0 to 2.

The group represented by Formula S2, which can be represented by R^{S3}, is shown below.

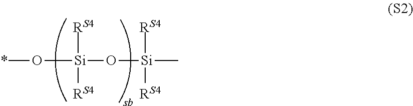

In Formula S2, * represents a bonding position.

In Formula S2, sb represents an integer of 0 to 300.

In Formula S2, R^{S4} represents a hydrocarbon group which may have a substituent and has 1 to 20 carbon atoms.

In Formula S2, a plurality of R^{S4}'s may be the same or different from each other.

Examples of the hydrocarbon group which can be represented by R^{S4} include the above-described hydrocarbon group which may have a substituent and which can be represented by the R^{S3}.

X^{A1} represents a hydroxyl group or a monovalent hydrolyzable group, and a monovalent hydrolyzable group is preferable. In Formula A1, three pieces of X^{A1} may be the same or different from each other.

Examples of the hydrolyzable group include an alkoxy group, an allyloxy group, and a halogen atom, and from the viewpoint that the effects of the present invention are more excellent, an alkoxy group or a halogen atom is preferable, and an alkoxy group is more preferable. The alkoxy group is preferably an alkoxy group having 1 to 4 carbon atoms and more preferably an alkoxy group having 1 or 2 carbon atoms. The allyloxy group is preferably an allyloxy group having 6 to 10 carbon atoms. The halogen atom is preferably a chlorine atom.

The compound A2 is a compound represented by Formula A2. The compound A2 is used as a so-called silane coupling agent.

Si(R^{A2})(R^{A20})(X^{A2})² Formula A2:

R^{A2} represents a monovalent functional group and is synonymous with R^{A1} in Formula A1.

R^{A20} represents an alkyl group or an aryl group, and an alkyl group is preferable from the viewpoint that the effects of the present invention are more excellent.

The alkyl group as R^{A20} preferably has 1 to 10 carbon atoms, more preferably 1 to 5 carbon atoms, and still more preferably 1 to 3 carbon atoms. The alkyl group may have any linear, branched or cyclic structure; however, it is preferably linear from the viewpoint that the effects of the present invention are more excellent.

The aryl group in R^{A20} preferably has 6 to 30 carbon atoms, more preferably 6 to 20 carbon atoms, still more preferably 6 to 12 carbon atoms, and particularly preferably 6 carbon atoms (that is, a phenyl group). The aryl group may be monocyclic or may have a fused-ring structure of two or more rings; however, it is preferably monocyclic.

X^{A2} represents a hydroxyl group or a monovalent hydrolyzable group and is synonymous with X^{A1} in Formula A1. In Formula A2, two pieces of X^{A2} may be the same as or different from each other.

The surface-modified particle is obtained by surface-treating an unmodified particle with the compound A.

The surface treatment method is not particularly limited; however, examples thereof include a method of bringing the compound A into contact with an unmodified particle in the presence of water and a method of bringing a self-condensate of the compound A into contact with an unmodified particle in the presence of water. In this case, it can be said that a layer (a coating layer) formed by a reaction (preferably a hydrolysis reaction) of the compound A and/or a self-condensate of the compound A with an inorganic oxide that constitutes the unmodified particle is formed on the surface of the surface-modified particle. In other words, it can be said that the surface-modified particle has a particle containing an inorganic oxide and a coating layer formed on the surface of the particles containing an inorganic oxide.

[Polysiloxane]

The dispersion liquid according to the embodiment of the present invention contains polysiloxane (hereinafter, also referred to as a specific polysiloxane) having at least one unit selected from the group consisting of a T unit represented by Formula B1 and a D unit represented by Formula B2; and

The content of the specific polysiloxane is 0.5% to 39% by mass with respect to the total amount of the surface-modified particle and the specific polysiloxane, and it is preferably 1% to 25% by mass and particularly preferably 2% to 20% by mass from the viewpoint that the effects of the present invention are more excellent.

The weight-average molecular weight of the specific polysiloxane is preferably 500 to 30,000, more preferably 1,000 to 20,000, and still more preferably 1,500 to 10,000, from the viewpoint that the effects of the present invention are more excellent.

The T unit that can be contained in the specific polysiloxane is a unit represented by Formula B1.

[R^{B1}SiO_{3/2}] Formula B1:

R^{B1} represents a monovalent functional group and is synonymous with R^{A1} in Formula A1.

The D unit that can be contained in the specific polysiloxane is a unit represented by Formula B2.

[R^{B2}R^{B20}SiO] Formula B2:

R^{B2} represents a monovalent functional group and is synonymous with R^{A2} in Formula A2.

R^{B20} represents an alkyl group or an aryl group and is synonymous with R^{A20} in Formula A2.

In a case where the surface-modified particle is a particle surface-treated with the compound A1 and the specific polysiloxane contains the T unit represented by Formula B1, it is preferable that R^{A1} in Formula A1 and R^{B1} of Formula B1 are the same group from the viewpoint that the effects of the present invention are more excellent.

In a case where the surface-modified particle is a particle surface-treated with the compound A2 and the specific polysiloxane contains the D unit represented by Formula B2, it is preferable that R^{A2} in Formula A2 and R^{B2} of Formula B2 are the same group from the viewpoint that the effects of the present invention are more excellent.

Polysiloxane is obtained, for example, by hydrolyzing and condensing a silane coupling agent in the presence of water. As the silane coupling agent, a known silane coupling agent can be used; however, it is preferably at least one compound selected from the group consisting of the above-described compound A1 and compound A2 from the viewpoint that the effects of the present invention are more excellent.

[Organic Solvent]

The dispersion liquid according to the embodiment of the present invention contains an organic solvent.

The content of the organic solvent is preferably 10% to 97% by mass with respect to the total mass of the dispersion liquid. The lower limit thereof is preferably 30% by mass or more, more preferably 40% by mass or more, still more preferably 50% by mass or more, even still more preferably 60% by mass or more, and particularly preferably 70% by mass or more. The upper limit thereof is preferably 96% by mass or less and more preferably 95% by mass or less. The dispersion liquid may contain only one kind of organic solvent or may contain two or more kinds thereof. In a case where two or more kinds thereof are contained, the total amount thereof is preferably within the above range.

Examples of the organic solvent include an ester solvent, a ketone solvent, an alcohol solvent, an amide solvent, an ether solvent, and a hydrocarbon solvent. For details thereof, paragraph No. 0223 of WO2015/166779A can be referenced, the content of which is incorporated into the present specification. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether (1-methoxy-2-propanol), and propylene glycol monomethyl ether acetate. However, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. An organic solvent at a level of parts per trillion (ppt) by mass may be used, as necessary, and such an organic solvent is provided by Toyo Gosei Co., Ltd., for example (The Chemical Daily, Nov. 13, 2015).

Examples of the method of removing impurities such as a metal from the organic solvent include distillation (molecular distillation, thin film distillation, or the like) or filtration with a filter. The filter pore diameter of the filter that is used for the filtration is preferably 10 μm or less, more preferably 5 μm or less, and still more preferably 3 μm or less. The material of the filter is preferably polytetrafluoroethylene, polyethylene, or nylon.

The organic solvent may contain isomers (compounds which have the same number of atoms but have different structures). In addition, only one isomer may be contained, or a plurality of isomers may be contained.

The content of the peroxide in the organic solvent is preferably 0.8 mmol/L or less, and it is more preferable that the peroxide is substantially not contained.

[Water]

The dispersion liquid according to the embodiment of the present invention may contain water.

The content of the water is preferably 0.01% to 5% by mass, more preferably 0.1% to 3% by mass, and still more preferably 0.1% to 1% by mass, with respect to the total mass of the dispersion liquid. In a case where the water content is within the above range, it is easy to suppress the deterioration of the temporal viscosity stability of the components in the dispersion liquid, and thus the effects of the present invention are more excellent.

[Another Component]

The dispersion liquid according to the embodiment of the present invention may further contain another optional component other than the above-described components.

Examples of the other component include a metal atom and a halogen atom.

<Production Method for Dispersion Liquid>

The dispersion liquid can be prepared by mixing the above-described respective components through a known mixing method (for example, a mixing method using a stirrer, a homogenizer, a high-pressure emulsification device, a wet-type pulverizer, a wet-type disperser, or the like).

In a case of preparing the dispersion liquid, the respective components may be formulated at once, or each of the components may be dissolved or dispersed in a solvent and then sequentially formulated. In addition, the input order and the operation conditions during the formulation are not particularly limited.

For the purpose of removing foreign substances, reducing defects, and the like, the dispersion liquid may be filtered with a filter. Any filter can be used without particular limitation as long as it is a filter, for example, which has been used in the related art for the use application to filtration or the like. Examples of the filter include filters made of a fluororesin such as polytetrafluoroethylene (PTFE), a polyamide-based resin such as nylon, a polyolefin-based resin (having a high density and an ultrahigh molecular weight) such as polyethylene and polypropylene (PP), or the like. Among these materials, polypropylene (including high-density polypropylene) and nylon are preferable.

The pore diameter of the filter is preferably 0.1 to 7.0 μm, more preferably 0.2 to 2.5 μm, still more preferably 0.2 to 1.5 μm, and particularly preferably 0.3 to 0.7 μm.

In a case of using a filter, different filters may be combined. In this case, filtering with a first filter may be carried out only once, or may be carried out twice or more times. In a case where filtering is carried out twice or more times with the combination of different filters, the pore diameters of the filters that are used in the second and subsequent filtering are preferably the same as or larger than the pore diameter of the filter that is used in the first filtering. In addition, the first filters having different pore diameters within the above range may be combined. Regarding the pore diameter mentioned here, reference can be made to nominal values of filter manufacturers. A commercial filter can be selected from various filters provided by, for example, Nihon Pall Ltd., Advantec Toyo Kaisha, Ltd., Nihon Entegris K. K. (formerly Nippon Microlith Co., Ltd.), Kitz Micro Filter Corporation.

As a second filter, a filter formed of the same material as that of the first filter, or the like can be used. The pore diameter of the second filter is preferably 0.2 to 10.0 μm, more preferably 0.2 to 7.0 μm, and still more preferably 0.3 to 6.0 μm.

The dispersion liquid preferably does not contain impurities such as a metal, a halogen-containing metal salt, an acid, and an alkali. The content of impurities contained in these materials is preferably 1 ppm by mass or less, more preferably 1 ppb by mass or less, still more preferably 100 ppt by mass or less, and particularly preferably 10 ppt by mass or less, and it is most preferable that the impurities are substantially not contained (the content is equal to or less than the detection limit of the measuring device).

It is noted that the impurities can be measured using an inductively coupled plasma mass spectrometer (manufactured by Agilent Technologies, Inc., Agilent 7500cs model).

[Composition]

The composition according to the embodiment of the present invention contains the above-described dispersion liquid and a polymerizable compound, and as necessary, may further contain a resin, a polymerization initiator, a coloring material, a polymerization inhibitor, a solvent, and the like. Hereinafter, components that are contained in the composition according to the embodiment of the present invention and components that may be contained therein will be described.

[Dispersion Liquid]

The composition according to the embodiment of the present invention contains the dispersion liquid described above. Since the dispersion liquid is as described above, the description thereof will be omitted.

From the viewpoint that the effects of the present invention are more excellent, the content of the dispersion liquid is preferably 5% to 95% by mass, more preferably 10% to 90% by mass, and still more preferably 15% to 85% by mass, with respect to the total mass of the composition.

[Polymerizable Compound]

The composition according to the embodiment of the present invention contains a polymerizable compound.

The content of the polymerizable compound is not particularly limited; however, it is preferably 5% to 60% by mass, more preferably 7% to 35% by mass, and still more preferably 9% to 20% by mass, with respect to the total solid content of the composition.

One kind of the polymerizable compound may be used alone, or two or more kinds thereof may be used. In a case where two or more polymerizable compounds are used, the total content thereof is preferably within the above range.

The molecular weight (or the weight-average molecular weight) of the polymerizable compound is not particularly limited; however, it is preferably equal to or less than 2,500.

The polymerizable compound is preferably a compound containing an ethylenic unsaturated group (a group containing an ethylenically unsaturated bond).

That is, the composition according to the embodiment of the present invention preferably contains, as a polymerizable compound, a low-molecular-weight compound containing an ethylenic unsaturated group.

The polymerizable compound is preferably a compound containing one or more ethylenically unsaturated bonds, more preferably a compound containing two or more ethylenically unsaturated bonds, still more preferably a compound containing three or more ethylenically unsaturated bonds, and particularly preferably a compound containing four or more ethylenically unsaturated bonds. The upper limit thereof is, for example, 15 or less. Examples of the ethylenic unsaturated group include a vinyl group, a (meth)allyl group, and a (meth)acryloyl group.

As the polymerizable compound, for example, the compounds described in paragraph 0050 of JP2008-260927A and paragraph 0040 of JP2015-68893A can be used, the contents of which are incorporated into the present specification.

The polymerizable compound may have any chemical form such as a monomer, a prepolymer, an oligomer, a mixture thereof, or a multimer thereof.

The polymerizable compound is preferably a tri- to pentadeca-functional (meth)acrylate compound, more preferably a tri- to hexa-functional (meth)acrylate compound, and still more preferably a penta- or hexa-functional (meth)acrylate compound.

As the polymerizable compound, a compound which contains one or more ethylenic unsaturated groups and has a boiling point of 100° C. higher under normal pressure is also preferable. Reference can be made to, for example, the compounds described in paragraph 0227 of JP2013-29760A and paragraphs 0254 to 0257 of JP2008-292970A, the contents of which are incorporated into the present specification.

The polymerizable compound is preferably dipentaerythritol triacrylate (as a commercially available product, for example, KAYARAD D-330; manufactured by Nippon Kayaku Co., Ltd.), dipentaerythritol tetraacrylate (as a commercially available product, for example, KAYARAD D-320; manufactured by Nippon Kayaku Co., Ltd.), dipentaerythritol penta(meth)acrylate (as a commercially available product, for example, KAYARAD D-310; manufactured by Nippon Kayaku Co., Ltd.), dipentaerythritol hexa(meth)acrylate (as a commercially available product, for example, KAYARAD DPHA; manufactured by Nippon Kayaku Co., Ltd., and A-DPH-12E; manufactured by SHIN-NAKAMURA CHEMICAL Co., Ltd.), or a structure (for example, SR454 and SR499 commercially available from Sartomer Company Inc.) in which an ethylene glycol residue or a propylene glycol residue is between these (meth)acryloyl groups. Oligomer types thereof can also be used. In addition, NK ESTER A-TMMT (pentaerythritol tetraacrylate, manufactured by SHIN-NAKAMURA CHEMICAL Co., Ltd.), KAYARAD RP-1040, KAYARAD DPEA-12LT, KAYARAD DPHA LT, KAYARAD RP-3060, and KAYARAD DPEA-12 (all are product names, manufactured by Nippon Kayaku Co., Ltd.), and the like may be used. In addition, as the polymerizable compound, a urethane (meth)acrylate-based compound, which is a compound having both a (meth)acryloyl group and a urethane bond, may be used, and, for example, KAYARAD DPHA-40H (product name, manufactured by Nippon Kayaku Co., Ltd.) may be used.

The preferred aspects of the polymerizable compound are shown below.

The polymerizable compound may have an acid group such as a carboxylic acid group, a sulfonic acid group, and a phosphoric acid group. The polymerizable compound containing an acid group is preferably an ester of an aliphatic polyhydroxy compound and an unsaturated carboxylic acid, more preferably a polymerizable compound having an acid group by reacting a nonaromatic carboxylic acid anhydride with an unreacted hydroxyl group of an aliphatic polyhydroxy compound, and still more preferably a compound in which the aliphatic polyhydroxy compound in the ester is pentaerythritol and/or dipentaerythritol. Examples of the commercially available product thereof include ARONIX TO-2349, M-305, M-510, and M-520 manufactured by TOAGOSEI CO., LTD.

The acid value of the polymerizable compound containing an acid group is preferably 0.1 to 40 mg KOH/g and more preferably 5 to 30 mg KOH/g. In a case where the acid value of the polymerizable compound is 0.1 mg KOH/g or more, development dissolution characteristics are favorable, and in a case where the acid value is 40 mg KOH/g or less, the polymerizable compound is advantageous in terms of production and/or handling. Moreover, a photopolymerization performance is favorable, and curing properties are excellent.

As the polymerizable compound, a compound having a caprolactone structure is also a preferred aspect.

The compound having a caprolactone structure is not particularly limited, for example, as long as the compound has a caprolactone structure in a molecule, but examples thereof include ε-caprolactone-modified polyfunctional (meth)acrylate which is obtained by esterifying polyhydric alcohol such as trimethylolethane, ditrimethylolethane, trimethylolpropane, ditrimethylolpropane, pentaerythritol, dipentaerythritol, tripentaerythritol, glycerin, diglycerol, and trimethylol melamine, (meth)acrylic acid, and ε-caprolactone. Among them, a compound which has a caprolactone structure and is represented by Formula (Z-1) is preferable.

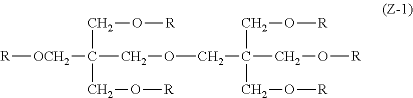

In Formula (Z-1), all six R's are groups represented by Formula (Z-2), or one to five among the six R's are groups represented by Formula (Z-2) and the others are groups represented by Formula (Z-3).

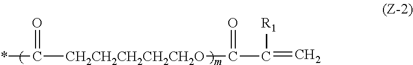

In Formula (Z-2), R¹ represents a hydrogen atom or a methyl group, m represents the number of 1 or 2, and “*” represents a bonding site.

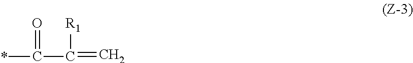

In Formula (Z-3), R¹ represents a hydrogen atom or a methyl group, and “*” represents a bonding position.

The polymerizable compound having a caprolactone structure is commercially available, for example, as KAYARAD DPCA series from Nippon Kayaku Co., Ltd., and examples thereof include DPCA-20 (a compound in which, in Formulae (Z-1) to (Z-3), m is 1, the number of groups represented by Formula (Z-2) is 2, and all of R¹'s represent hydrogen atoms), DPCA-30 (a compound in which, in Formulae (Z-1) to (Z-3), m is 1, the number of groups represented by Formula (Z-2) is 3, and all of R¹'s represent hydrogen atoms), DPCA-60 (a compound in which, in Formulae (Z-1) to (Z-3), m is 1, the number of groups represented by Formula (Z-2) is 6, and all of R¹'s represent hydrogen atoms), and DPCA-120 (a compound in which, in Formulae (Z-1) to (Z-3), m is 2, the number of groups represented by Formula (Z-2) is 6, and all of R¹'s represent hydrogen atoms). In addition, examples of the commercially available product of the polymerizable compound having a caprolactone structure also include M-350 (product name) (trimethylolpropane triacrylate) manufactured by TOAGOSEI CO., LTD.

As the polymerizable compound, a compound represented by Formula (Z-4) or (Z-5) can also be used.

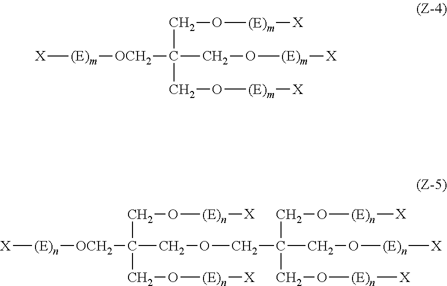

In Formulae (Z-4) and (Z-5), E represents —((CH₂)_{y}CH₂O)— or ((CH₂)_{y}CH(CH₃)O)—, y represents an integer of 0 to 10, and X represents a (meth)acryloyl group, a hydrogen atom, or a carboxylic acid group.

In Formula (Z-4), the total number of (meth)acryloyl groups is 3 or 4, m represents an integer of 0 to 10, and the total number of m's is an integer of 0 to 40.

In Formula (Z-5), the total number of (meth)acryloyl groups is 5 or 6, n represents an integer of 0 to 10, and the total number of n's is an integer of 0 to 60.

In Formula (Z-4), m is preferably an integer of 0 to 6 and more preferably an integer of 0 to 4.

In addition, the total number of m's is preferably an integer of 2 to 40, more preferably an integer of 2 to 16, and still more preferably an integer of 4 to 8.

In Formula (Z-5), n is preferably an integer of 0 to 6 and more preferably an integer of 0 to 4.

In addition, the total number of n's is preferably an integer of 3 to 60, more preferably an integer of 3 to 24, and still more preferably an integer of 6 to 12.

In addition, a form in which a terminal on the oxygen atom side of —((CH₂)_{y}CH₂O)— or ((CH₂)_{y}CH(CH₃)O)— in Formula (Z-4) or Formula (Z-5) is bonded to X is preferable.

The compound represented by Formula (Z-4) or Formula (Z-5) may be used alone, or two or more thereof may be used in combination. In particular, a form in which all of six X's in Formula (Z-5) are acryloyl groups or an aspect which is a mixture of a compound in which all of six X's in Formula (Z-5) are acryloyl groups and a compound in which at least one among the six X's is a hydrogen atom is preferable. With such a configuration, the developability can be further improved.

In addition, the total content of the compounds represented by Formula (Z-4) or Formula (Z-5) in the polymerizable compound is preferably 20% by mass or more and more preferably 50% by mass or more.

Among the compounds represented by Formula (Z-4) or Formula (Z-5), a pentaerythritol derivative and/or a dipentaerythritol derivative is more preferable.

In addition, the polymerizable compound may have a cardo skeleton.

The polymerizable compound having a cardo skeleton is preferably a polymerizable compound having a 9,9-bisarylfluorene skeleton.

Examples of the polymerizable compound having a cardo skeleton include ONCOAT EX series (manufactured by NAGASE & CO., LTD.), and OGSOL (manufactured by Osaka Gas Chemicals Co., Ltd.).

As the polymerizable compound, a compound having an isocyanuric acid skeleton as a core is also preferable. Examples of such a polymerizable compound include NK ESTER A-9300 (manufactured by SHIN-NAKAMURA CHEMICAL Co., Ltd.).

The ethylenically unsaturated bond equivalent (which means a value obtained by dividing the number of ethylenic unsaturated groups in the polymerizable compound by the molecular weight (g/mol) of the polymerizable compound) of the polymerizable compound is preferably 5.0 mmol/g or more. The upper limit thereof is not particularly limited; however, it is generally 20.0 mmol/g or less.

[Resin]

The composition according to the embodiment of the present invention preferably contains a resin. The resin is blended in, for example, a use application for dispersing particles such as a pigment in a composition or a use application as a binder. It is noted that a resin which is mainly used for dispersing particles such as a pigment is also referred to as a dispersing agent. However, such use applications of the resin are only exemplary, and the resin can also be used for another purpose in addition to such use applications.

The weight-average molecular weight (Mw) of the resin is preferably 2,000 to 2,000,000. The upper limit thereof is preferably 1,000,000 or less and more preferably 500,000 or less. The lower limit thereof is preferably 3,000 or more and more preferably 5,000 or more.

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. These resins may be used alone, or two or more kinds thereof may be mixed and used. From the viewpoint of improving heat resistance, the cyclic olefin resin is preferably a norbornene resin. Examples of the commercially available product of the norbornene resin include ARTON series (for example, ARTON F4520) manufactured by JSR Corporation. Examples of the epoxy resin include an epoxy resin which is a glycidyl etherified product of a phenol compound, an epoxy resin which is a glycidyl etherified product of various novolak resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. In addition, as the epoxy resin, MARPROOF G-0150M, G-0105SA, G-0130SP, G-0250SP, G-1005S, G-1005SA, G-1010S, G-2050M, G-01100, or G-01758 (manufactured by NOF Corporation, an epoxy group-containing polymer) can also be used. In addition, as the resin, resins described in Examples of WO2016/088645A can be used. In addition, in a case where the resin has an ethylenic unsaturated group, particularly a (meth)acryloyl group in the side chain, it is also preferable that the main chain and the ethylenic unsaturated group are bonded through a divalent linking group having an alicyclic structure.

The composition according to the embodiment of the present invention preferably contains an alkali-soluble resin. In a case where the composition according to the embodiment of the present invention contains an alkali-soluble resin, the developability of the composition is improved, and in a case where a pattern is formed by a photolithography method using the composition according to the embodiment of the present invention, the generation of development residues and the like can be effectively suppressed. Examples of the alkali-soluble resin include resins having an acid group. Examples of the acid group include a carboxy group, a phosphoric acid group, a sulfo group, and a phenolic hydroxyl group, and a carboxy group is preferable. The acid group contained in the alkali-soluble resin may be one kind or two or more kinds. The alkali-soluble resin can also be used as a dispersing agent.

The alkali-soluble resin preferably contains a repeating unit having an acid group in the side chain, and in the total repeating units of the resin, it more preferably contains 5% to 70% by mole of a repeating unit having an acid group in the side chain. The upper limit of the content of the repeating unit having an acid group in the side chain is preferably 50% by mole or less and more preferably 30% by mole or less. The lower limit of the content of the repeating unit having an acid group in the side chain is preferably 10% by mole or more and more preferably 20% by mole or more.

It is also preferable that the alkali-soluble resin is an alkali-soluble resin having a polymerizable group. Examples of the polymerizable group include a (meth)allyl group (which means both an allyl group and a methallyl group) and a (meth)acryloyl group. The alkali-soluble resin having a polymerizable group is preferably a resin including a repeating unit having a polymerizable group in the side chain and a repeating unit having an acid group in the side chain.

It is also preferable that the alkali-soluble resin includes a repeating unit derived from a monomer component including a compound represented by Formula (ED1) and/or a compound represented by Formula (ED2) (hereinafter, these compounds may be referred to as an “ether dimer”).

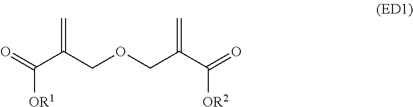

In Formula (ED1), R¹ and R² each independently represent a hydrogen atom or a hydrocarbon group having 1 to 25 carbon atoms, which may have a substituent.

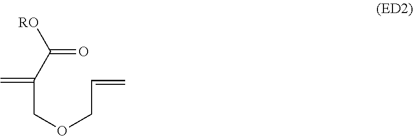

In Formula (ED2), R represents a hydrogen atom or an organic group having 1 to 30 carbon atoms. With regard to details of Formula (ED2), reference can be made to the description in JP2010-168539A, the content of which is incorporated into the present specification by reference.

With regard to the specific examples of the ether dimer, reference can be made to the description in paragraph No. 0317 of JP2013-029760A, the content of which is incorporated into the present specification by reference.

It is also preferable that the alkali-soluble resin contains a repeating unit derived from a compound represented by Formula (X).

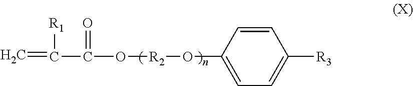

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may contain a benzene ring. n represents an integer of 1 to 15.

With regard to the alkali-soluble resin having an acid group, reference can be made to the description in paragraph Nos. “0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated into the present specification by reference.

The resin (particularly, the alkali-soluble resin) preferably has an acid value of 10 to 500 mgKOH/g. The lower limit is preferably 30 mgKOH/g or more, more preferably 50 mgKOH/g or more, and still more preferably 70 mgKOH/g or more. The upper limit is preferably 400 mgKOH/g or less, more preferably 300 mgKOH/g or less, still more preferably 200 mgKOH/g or less, and particularly preferably 100 mgKOH/g or less.

The ethylenically unsaturated bond equivalent (which means a value obtained by dividing the number of ethylenic unsaturated groups in the polymerizable compound by the molecular weight (g/mol) of the polymerizable compound) of the resin (particularly, the alkali-soluble resin) is preferably 0.4 to 2.5 mmol/g. The lower limit is preferably 1.0 mmol/g and more preferably 1.2 mmol/g. The upper limit is preferably 2.3 mmol/g or less and more preferably 2.0 mmol/g or less.

In particular, in a case where the composition according to the embodiment of the present invention contains a resin having an acid value of 10 to 100 mgKOH/g and an ethylenically unsaturated bond equivalent of 1.0 to 2.0 mmol/g, it is possible to further suppress the occurrence of peeling after the humidity test.

Specific examples of the alkali-soluble resin having an acid group include resins having the following structures. In the following structural formulae, Me represents a methyl group.

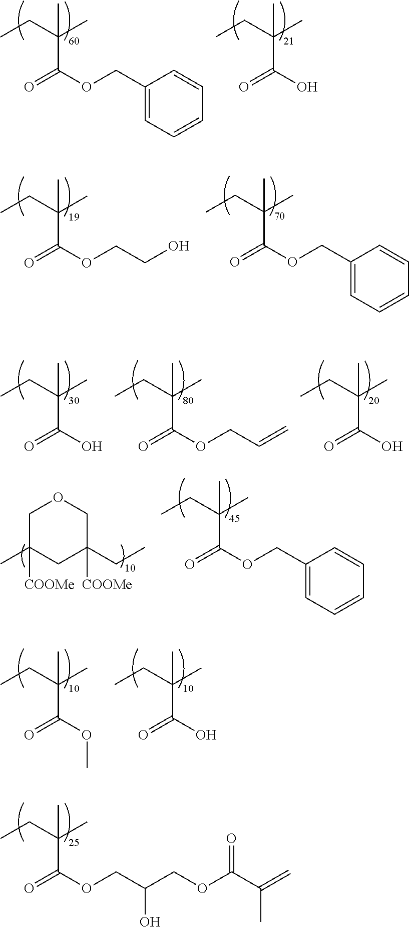

It is also preferable that composition according to the embodiment of the present invention contains a resin having a basic group. Examples of the basic group include an amino group and an ammonium base. The resin having a basic group may further have an acid group in addition to the basic group. In a case where the resin having a basic group further has an acid group, such a resin is also an alkali-soluble resin.

Examples of the resin having a basic group include a resin having a tertiary amino group and a quaternary ammonium base. The resin having a tertiary amino group and a quaternary ammonium base is preferably a resin having a repeating unit having a tertiary amino group and a repeating unit having a quaternary ammonium base. In addition, the resin having a tertiary amino group and a quaternary ammonium base may further have a repeating unit having an acid group. The resin having a tertiary amino group and a quaternary ammonium base preferably has a block structure. The resin having a tertiary amino group and a quaternary ammonium base preferably has an amine value of 10 to 250 mgKOH/g and a quaternary ammonium salt value of 10 to 90 mgKOH/g, and more preferably an amine value of 50 to 200 mgKOH/g and a quaternary ammonium salt value of 10 to 50 mgKOH/g. The weight-average molecular weight (Mw) of the resin having a tertiary amino group and a quaternary ammonium base is preferably 3,000 to 300,000 and more preferably 5,000 to 30,000. The resin having a tertiary amino group and a quaternary ammonium base can be manufactured by copolymerizing an ethylenically unsaturated monomer having a tertiary amino group, an ethylenically unsaturated monomer having a quaternary ammonium base, and as necessary, another ethylenically unsaturated monomer. Examples of the ethylenically unsaturated monomer having a tertiary amino group and the ethylenically unsaturated monomer having a quaternary ammonium base include those described in paragraph Nos. 0150 to 0170 of WO2018/230486A, the content of which is incorporated into the present specification. In addition, the resins having an acidic group described in paragraph Nos. 0079 to 0160 of JP2018-87939A may be used in combination.

Further, as the resin having a basic group, a resin containing a nitrogen atom in the main chain is also preferable. The resin including a nitrogen atom in the main chain (hereinafter, also referred to as an oligoimine-based resin) preferably includes at least one repeating unit having a nitrogen atom, selected from a poly(lower alkyleneimine)-based repeating unit, a polyallylamine-based repeating unit, a polydiallylamine-based repeating unit, a metaxylene diamine-epichlorohydrin polycondensate-based repeating unit, and a polyvinylamine-based repeating unit. In addition, the oligoimine-based resin is preferably a resin having a repeating unit that has a partial structure X having a functional group of pKa14 or less and a repeating unit that has a side chain containing an oligomer chain having 40 to 10,000 atoms or a polymer chain Y. The oligoimine-based resin may further have a repeating unit having an acid group. With regard to oligoimine-based resin, reference can be made to the description of paragraph Nos. 0102 to 0166 of JP2012-255128A, the content of which is incorporated into the present specification by reference.

The composition according to the embodiment of the present invention can also contain a resin as the dispersing agent, and it preferably contains a resin as the dispersing agent. Examples of the dispersing agent include an acidic dispersing agent (an acidic resin) and a basic dispersing agent (a basic resin). Here, the acidic dispersing agent (the acidic resin) represents a resin in which the amount of the acid group is larger than the amount of the basic group. The acidic dispersing agent (the acidic resin) is preferably a resin in which the amount of the acid group occupies 70% by mole or more in a case where the total content of the acid group and the basic group is 100% by mole, and more preferably a resin substantially consisting of only an acid group. The acid group contained in the acidic dispersing agent (acidic resin) is preferably a carboxy group. In addition, the basic dispersing agent (the basic resin) represents a resin in which the amount of the basic group is larger than the amount of the acid group. The basic dispersing agent (the basic resin) is preferably a resin in which the amount of the basic group is more than 50% by mole in a case where the total amount of the acid group and the basic group is 100% by mole. The dispersing agent is preferably a resin having a basic group and more preferably a basic dispersing agent.

Examples of the resin that is used as the dispersing agent include the above-described resin having a tertiary amino group and a quaternary ammonium base and an oligoimine-based resin. In addition, it is also preferable that the resin that is used as a dispersing agent is a graft resin. Examples of the graft resin include a resin having a repeating unit having a graft chain. The graft resin may further have a repeating unit having an acid group. With regard to details of the graft resin, reference can be made to the description in paragraph Nos. 0025 to 0094 of JP2012-255128A, the content of which is incorporated into the present specification by reference.

In order to improve interactive properties between the graft chain and the solvent, and thus enhance the dispersibility of the coloring material or the like, the graft chain is preferably a graft chain having at least one selected from the group consisting of a polyester structure, a polyether structure, and a poly(meth)acrylate structure, and more preferably a graft chain having at least one of a polyester structure or a polyether structure.

In addition, it is also preferable that the resin that is used as a dispersing agent is a resin containing a repeating unit having an acid group. In addition, it is also preferable that the resin that is used as a dispersing agent is a resin having a structure in which a plurality of polymer chains are bonded to a core portion. Examples of such a resin include a dendrimer (including a star polymer). In addition, specific examples of the dendrimer include polymer compounds C-1 to C-31 described in paragraph Nos. 0196 to 0209 of JP2013-043962A. In addition, the alkali-soluble resin can also be used as a dispersing agent.

The dispersing agent is also available as a commercially available product, and specific examples thereof include Disperbyk-111 (manufactured by BYK Chemie) and Solsperse 76500 (manufactured by Lubrizol Japan Limited.). The dispersing agents described in paragraph Nos. 0041 to 0130 of JP2014-130338A can also be used, the content of which is incorporated into the present specification by reference.

It is also preferable to use the dispersing agent described in JP2019-078878A.

The content of the resin in the total solid content of the composition is preferably 1% to 50% by mass. The lower limit thereof is preferably 5% by mass or more and more preferably 7% by mass or more. The upper limit thereof is preferably 40% by mass or less and more preferably 30% by mass or less.

In a case where the composition according to the embodiment of the present invention contains an alkali-soluble resin, the content of the alkali-soluble resin is preferably 1% to 50% by mass in the total solid content of the composition. The lower limit thereof is preferably 5% by mass or more and more preferably 7% by mass or more. The upper limit thereof is preferably 40% by mass or less and more preferably 30% by mass or less. In addition, the content of the alkali-soluble resin in the resin contained in the composition is preferably 50% to 100% by mass, more preferably 75% to 100% by mass, and still more preferably 90% to 100% by mass.

In a case where the composition according to the embodiment of the present invention contains a resin as the dispersing agent, the content of the resin as the dispersing agent is preferably 0.1% to 40% by mass in the total solid content of the composition. The upper limit thereof is preferably 20% by mass or less and still more preferably 10% by mass or less. The lower limit thereof is preferably 0.5% by mass or more and still more preferably 1% by mass or more.

The composition according to the embodiment of the present invention may contain one kind of resin or may contain two or more kinds thereof. In a case where two or more kinds thereof are contained, the total amount thereof is preferably within the above range.

[Polymerization Initiator]

The composition according to the embodiment of the present invention preferably contains a polymerization initiator.

As the polymerization initiator, for example, a known polymerization initiator can be used. Examples of the polymerization initiator include a photopolymerization initiator and a thermal polymerization initiator, and a photopolymerization initiator is preferable.

The content of the polymerization initiator is preferably 0.5% to 20% by mass, more preferably 1.0% to 10% by mass, and still more preferably 1.5% to 8% by mass, with respect to the total solid content of the composition.

The polymerization initiator may be used alone, or two or more thereof may be used in combination. In a case where two or more polymerization initiators are used in combination, the total content thereof is preferably within the above range.

<Thermal Polymerization Initiator>

Examples of thermal polymerization initiator include an azo compound such as 2,2′-azobisisobutyronitrile (AIBN), 3-carboxypropionitrile, azobismalononitrile, and dimethyl-(2,2′)-azobis(2-methylpropionate) [V-601] and an organic peroxide such as benzoyl peroxide, lauroyl peroxide, and potassium persulfate.

Specific examples of thermal polymerization initiator include the polymerization initiator described in pp. 65 to 148 of “Ultraviolet Curing System” (published by Sogo Gijutsu Center, 1989) written by Kiyomi Kato.

<Photopolymerization Initiator>

The photopolymerization initiator is not particularly limited and can be appropriately selected from the known photopolymerization initiators. For example, a compound having photosensitivity to a ray in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. Examples of the photopolymerization initiator include compounds described in paragraphs 0065 to 0111 of JP2014-130173A, and JP6301489B, the content of which is incorporated into the present specification by reference.

Examples of the commercially available product of the α-hydroxyketone compound include Omnirad 184, Omnirad 1173, Omnirad 2959, and Omnirad 127 (all manufactured by IGM Resins B.V.) (corresponding to in the following order; Irgacure 184, Irgacure 1173, Irgacure 2959, and Irgacure 127, formerly manufactured by BASF SE). Examples of a commercially available product of the α-aminoketone compound include Omnirad 907, Omnirad 369, Omnirad 369E, and Omnirad 379EG (all manufactured by IGM Resins B.V.) (corresponding to in the following order; Irgacure 907, Irgacure 369, Irgacure 369E, and Irgacure 379EG, formerly manufactured by BASF SE). Examples of the commercially available product of the acylphosphine compound include Omnirad 819 and Omnirad TPO (both of which are manufactured by IGM Resins B.V.) (corresponding to in the following order; Irgacure 819 and Irgacure TPO, formerly manufactured by BASF SE).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2000-080068A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, the compounds described in WO2013/167515A, and the compounds described in WO2019/088055A. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one. Examples of the commercially available product of the oxime compound include IRGACURE-OXE01, IRGACURE-OXE02, IRGACURE-OXE03, or IRGACURE-OXE04 (all manufactured by BASF SE), TR-PBG-304 (manufactured by Changzhou Tronly New Electronic Materials Co., Ltd.), and ADEKA OPTOMER N-1919 (manufactured by ADEKA CORPORATION, the photopolymerization initiator 2 described in JP2012-014052A). In addition, as the oxime compound, it is also preferable to use a compound having no colorability or a compound having high transparency and being resistant to discoloration. Examples of the commercially available product thereof include ADEKA ARKLS NCI-730, NCI-831, and NCI-930 (all manufactured by ADEKA CORPORATION).

In the present invention, an oxime compound having a fluorene ring can also be used as the photopolymerization initiator. Specific examples of the oxime compound having a fluorene ring include the compound described in JP2014-137466A.

In addition, as the photopolymerization initiator, an oxime compound having a skeleton in which at least one benzene ring of a carbazole ring is a naphthalene ring can also be used. Specific examples of such an oxime compound include the compound disclosed in WO2013/083505A.

In the present invention, an oxime compound having a fluorine atom can also be used as the photopolymerization initiator. Specific examples of the oxime compound having a fluorine atom include the compound described in JP2010-262028A, the compounds 24 and 36 to 40 described in JP2014-500852A, and the compound (C-3) described in JP2013-164471A.

In the present invention, as the photopolymerization initiator, an oxime compound having a nitro group can be used. It is also preferable that the oxime compound having a nitro group is a dimer. Specific examples of the oxime compound having a nitro group include a compound described in paragraph Nos. 0031 to 0047 of JP2013-114249A and paragraph Nos. 0008 to 0012 and 0070 to 0079 of JP2014-137466A, a compound described in paragraph Nos. 0007 to 0025 of JP4223071B, and ADEKA ARKLS NCI-831 (manufactured by ADEKA CORPORATION).

In the present invention, as the photopolymerization initiator, an oxime compound having a benzofuran skeleton can also be used. Specific examples thereof include OE-01 to OE-75 described in WO2015/036910A.

Specific examples of the oxime compound which are preferably used in the present invention are shown below; however, the present invention is not limited thereto.

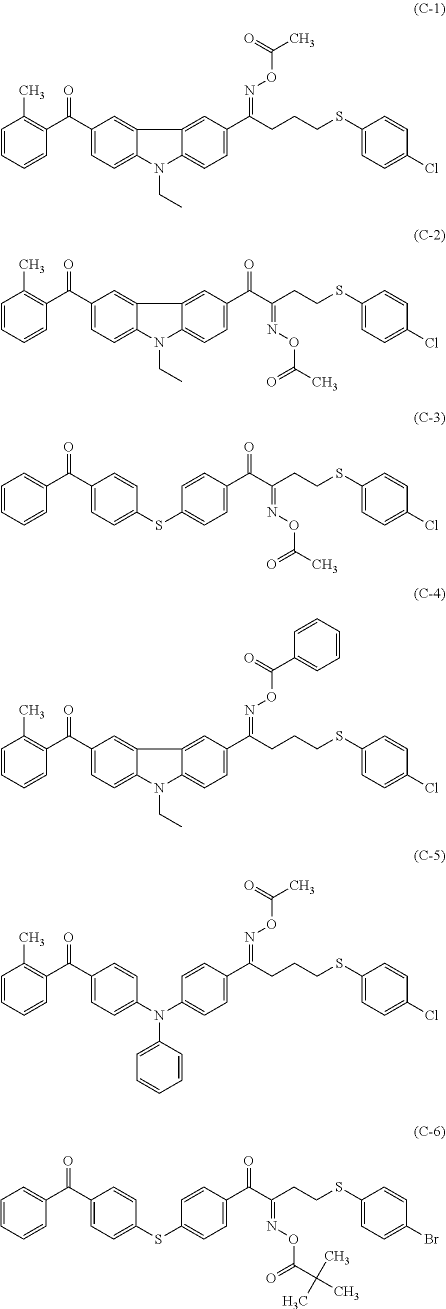 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

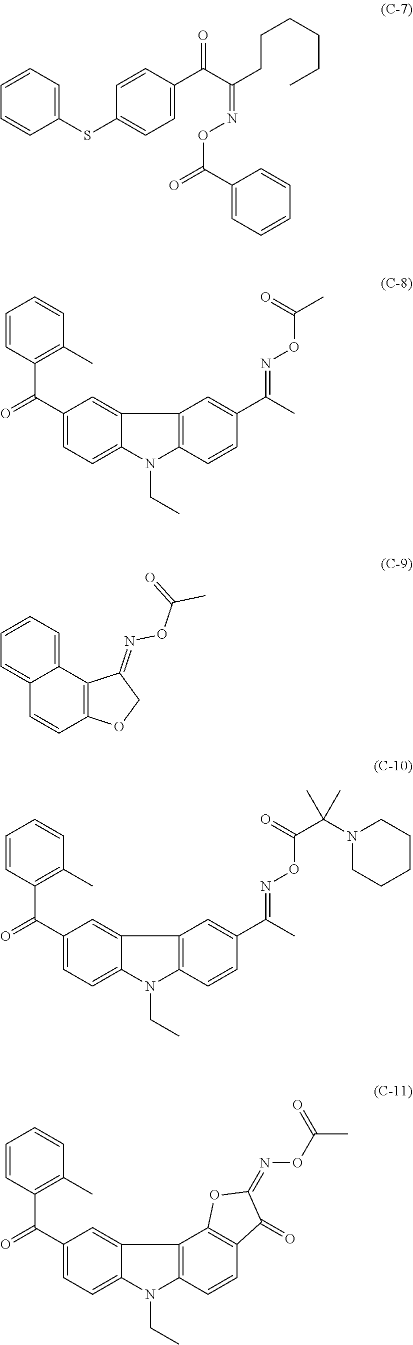 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

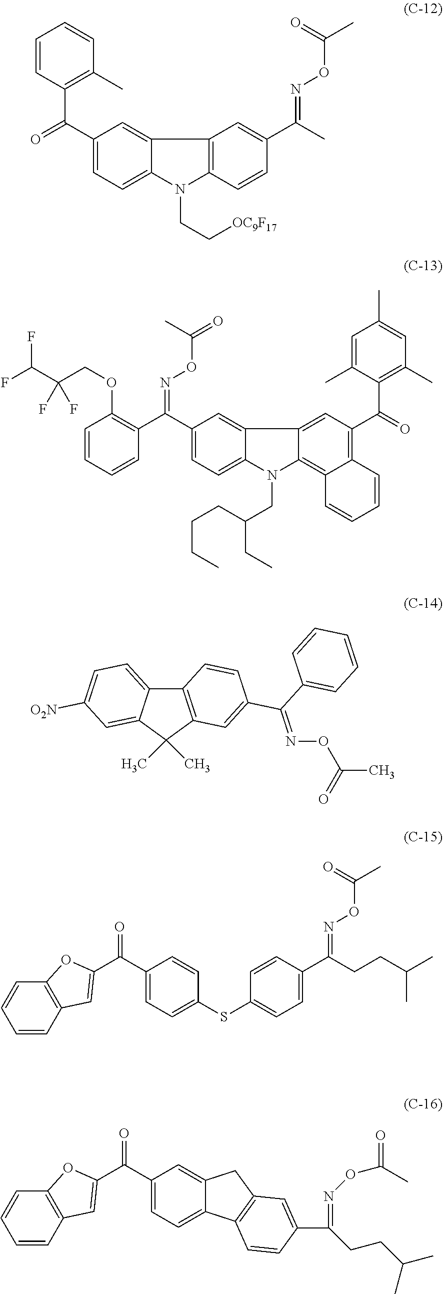

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, the molar absorption coefficient of the oxime compound at a wavelength of 365 nm or 405 nm is preferably high, more preferably 1,000 to 300,000, still more preferably 2,000 to 300,000, and particularly preferably 5,000 to 200,000. The molar absorption coefficient of the compound can be measured using a known method. For example, the molar absorption coefficient is preferably measured by a spectrophotometer (a Cary-5 spectrophotometer, manufactured by Varian Medical Systems, Inc.) using an ethyl acetate solvent at a concentration of 0.01 g/L.

As the photopolymerization initiator, a bifunctional or tri- or more functional photoradical polymerization initiator may be used. In a case where such a photoradical polymerization initiator is used, two or more radicals are generated from one molecule of the photoradical polymerization initiator, and thus good sensitivity is obtained. Further, in a case where a compound having an asymmetric structure is used, the crystallinity is reduced, the solubility in a solvent or the like is improved, and the compound is hardly precipitated over time, and the temporal stability of the composition can be improved. Specific examples of the bifunctional or tri- or more functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; and the photopolymerization initiator (A) described in paragraph Nos. 0017 to 0026 of JP2017-151342A.

It is also preferable that the photopolymerization initiator includes an oxime compound and an α-aminoketone compound. In a case where the oxime compound and the α-aminoketone compound are used in combination, the developability is improved, and a pattern having excellent rectangularity can be easily formed. In a case where the oxime compound and the α-aminoketone compound are used in combination, the content of the α-aminoketone compound is preferably 50 to 600 parts by mass and more preferably 150 to 400 parts by mass with respect to 100 parts by mass of the oxime compound.

The content of the photopolymerization initiator in the total solid content is preferably 0.1% to 40% by mass, more preferably 0.5% to 30% by mass, and still more preferably 1% to 20% by mass. The composition may contain one photopolymerization initiator or may contain two or more photopolymerization initiators. In a case where two or more kinds thereof are contained, the total amount thereof is preferably within the above range.

[Coloring Material]

The composition according to the embodiment of the present invention may contain a coloring material. It is noted that a material different from the above-described inorganic oxide particle and coloring material is used. One kind of coloring material may be used alone, or two or more kinds thereof may be used.

Examples of the coloring material include a chromatic colorant, an achromatic colorant, and an infrared absorbing agent. In the present invention, the “chromatic colorant” means a coloring agent other than the white colorant and the black colorant. The chromatic colorant is preferably a colorant having absorption in a wavelength range of 400 nm or more and less than 650 nm.

The content of the coloring material is preferably 10% to 80% by mass, more preferably 20% to 75% by mass, and still more preferably 30% to 70% by mass, with respect to the total solid content of the composition.

The composition according to the embodiment of the present invention may contain one kind of coloring material or may contain two or more thereof. In a case where two or more kinds thereof are contained, the total amount thereof is preferably within the above range.

<<Chromatic Colorant>>

Examples of the chromatic colorant include a red coloring agent, a green coloring agent, a blue coloring agent, a yellow coloring agent, a purple coloring agent, and an orange coloring agent. The chromatic colorant may be a pigment or a dye. The pigment and the dye may be used in combination. In addition, the pigment may be any one of an inorganic pigment or an organic pigment. In addition, as the pigment, a material in which a part of an inorganic pigment or an organic-inorganic pigment is replaced with an organic chromophore can also be used. The color tone design can be facilitated by replacing the inorganic pigment or the organic-inorganic pigment with the organic chromophore.

The average primary particle diameter of the pigment is preferably 1 to 200 nm. The lower limit thereof is preferably 5 nm or more and more preferably 10 nm or more. The upper limit thereof is preferably 180 nm or less, more preferably 150 nm or less, and still more preferably 100 nm or less. In a case where the average primary particle diameter of the pigment is within the above-described range, the dispersion stability of the pigment in the composition is good. In the present invention, the primary particle diameter of the pigment can be determined from an image photograph obtained by observing primary particles of the pigment using a transmission electron microscope. Specifically, a projected area of the primary particles of the pigment is determined, and the corresponding circle-equivalent diameter is calculated as the primary particle diameter of the pigment. In addition, the average primary particle diameter in the present invention shall be the arithmetic average value of the primary particle diameters with respect to 400 primary particles of the pigment. In addition, the primary particle of the pigment refers to a particle which is independent without being aggregated.

The chromatic colorant preferably includes a pigment. The content of the pigment in the chromatic colorant is preferably 50% by mass or more, more preferably 70% by mass or more, still more preferably 80% by mass or more, and particularly preferably 90% by mass or more. Examples of the pigment include the following pigments:

Color Index (C. I.) Pigment Yellow (hereinafter, may be referred to as “PY”) 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based) (all of which are yellow pigments), and the like,

C. I. Pigment Orange (hereinafter, also referred to as “PO”) 2, 5, 13, 16, 17:1, 31, 34, 36, 38, 43, 46, 48, 49, 51, 52, 55, 59, 60, 61, 62, 64, 71, 73, and the like (all of which are orange pigments),

C. I. Pigment Red (hereinafter, also referred to as “PR”) 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 294 (xanthene-based, Organo Ultramarine, Bluish Red), 295 (azo-based), 296 (azo-based), 297 (aminoketone-based), and the like (all of which are red pigments),

C. I. Pigment Green (hereinafter, may be referred to as “PG”) 7, 10, 36, 37, 58, 59, 62, 63, 64 (phthalocyanine-based), 65 (phthalocyanine-based), 66 (phthalocyanine-based), and the like (all of which are green pigments),

C. I. Pigment Violet (hereinafter, also referred to as “PV”) 1, 19, 23, 27, 32, 37, 42, 60 (triarylmethane-based), 61 (xanthene-based), and the like (all of which are violet pigments), and

C. I. Pigment Blue (hereinafter, also referred to as “PB”) 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In addition, as the green pigment, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include compounds described in WO2015/118720A. In addition, as the green pigment, compounds described in CN106909027A, phthalocyanine compounds described in WO2012/102395A, which have a phosphoric acid ester as a ligand, or the like can also be used.

In addition, as the blue pigment, an aluminum phthalocyanine compound having a phosphorus atom can also be used. Specific examples thereof include the compounds described in paragraph Nos. 0022 to 0030 of JP2012-247591A and paragraph No. 0047 of JP2011-157478A.

In addition, as the yellow pigment, the pigment described in JP2008-074985A, the compound described in JP2008-074987A, the quinophthalone compound described in JP2013-061622A, the quinophthalone compound described in JP2013-181015A, the colorant described in JP2014-085565A, the pigment described in JP2016-145282A, the pigment described in JP2017-201003A, the pigment described in JP2017-197719A, the pigments described in paragraph Nos. 0011 to 0062 and 0137 to 0276 of JP2017-171912A, the pigments described in paragraph Nos. 0010 to 0062 and 0138 to 0295 of JP2017-171913A, the pigments described in paragraph Nos. 0011 to 0062 and 0139 to 0190 of JP2017-171914, the pigments described in paragraph Nos. 0010 to 0065 and 0142 to 0222 in JP2017-171915A, the quinophthalone compound described in JP2017-197640, the quinophthalone-based pigment described in JP2018-040835A, the pigment described in JP2018-203798A, the pigment described in JP2018-062578A, the quinophthalone-based yellow pigment described in JP2018-155881A, the compound described in JP2018-062644A, the quinophthalone compound described in JP6432077B, and the pigment described in JP6443711B can also be used.

In addition, as the yellow pigment, the compound described in JP2018-062644A can also be used. These compounds can also be used as a pigment derivative.

As the red pigment, the diketopyrrolo pyrrole compound described in JP2017-201384A, of which the structure has at least one substituted bromine atom, the diketopyrrolo pyrrole compounds described in paragraph Nos. 0016 to 0022 of JP6248838B, the diketopyrrolo pyrrole compound described in WO2012/102399A, the diketopyrrolo pyrrole compound described in WO2012/117965A, the naphthol azo compound described in JP2012-229344, or the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolo pyrrole skeleton can be used.

In addition, as the red pigment, the compounds described in JP6516119B and JP6525101B can also be used. These compounds can also be used as a pigment derivative.

In the present invention, a dye can also be used as the chromatic colorant. The dye is not particularly limited, and a known dye can be used. Examples thereof include dyes such as a pyrazole azo-based dye, an anilino azo-based dye, a triarylmethane-based dye, an anthraquinone-based dye, an anthrapyridone-based dye, a benzylidene-based dye, an oxonol-based dye, a pyrazolotriazole azo-based dye, a pyridone azo-based dye, a cyanine-based dye, a phenothiazine-based dye, a pyrrolopyrazole azomethine-based dye, a xanthene-based dye, a phthalocyanine-based dye, a benzopyran-based dye, an indigo-based dye, and a pyrromethene-based dye. In addition, the thiazole compound described in JP2012-158649A, the azo compound described in JP2011-184493A, and the azo compound described in JP2011-145540A can also be preferably used. In addition, as yellow dyes, quinophthalone compounds described in paragraph Nos. 0011 to 0034 of JP2013-054339A, quinophthalone compounds described in paragraph Nos. 0013 to 0058 of JP2014-026228A, or the like can also be used.

<Achromatic Colorant>

Examples of the achromatic colorant include a black colorant and a white colorant.

(Black Colorant)

Examples of the black colorant include one or more selected from the group consisting of a black pigment and a black dye.

In addition, a plurality of coloring agents, each of which cannot be used as a black colorant, may be combined and adjusted to be black as a whole, and may be used as a black colorant.

For example, a plurality of pigments, each of which has a color other than the black color, are combined and may be used as a black pigment. Similarly, a combination of a plurality of dyes, each of which has a color other than a black color, may be used as a black dye, and a combination of a pigment having a color other than a black color alone and a dye having a color other than a black color alone may be used as a black dye.

In the present specification, the black colorant refers to a coloring material which has absorption over the entire wavelength range of 400 to 700 nm.

More specifically, for example, a black colorant which conforms to the evaluation standard Z described below is preferable.

First, a composition, which contains a coloring material, a transparent resin matrix (acrylic resin or the like), and a solvent, and in which the content of the coloring material with respect to the total solid content is 60% by mass, is prepared. A coating film is formed by applying the obtained composition onto a glass substrate so that the film thickness of the coating film after drying is 1 μm. The light shielding properties of the coating film after drying are evaluated using a spectrophotometer (UV-3600 manufactured by Shimadzu Corporation, or the like). In a case where the maximum value of a light transmittance of the coating film after drying is less than 10% at wavelengths of 400 to 700 nm, the coloring material can be determined to be a black colorant conforming to the evaluation standard Z. Regarding the black colorant, in the evaluation standard Z, the maximum value of the light transmittance of the coating film after drying is more preferably less than 8% and still more preferably less than 5%, at wavelengths of 400 to 700 nm.

Black Pigment

As the black pigment, various known black pigments can be used. The black pigment may be an inorganic pigment or an organic pigment.

The black colorant is preferably a black pigment from the viewpoint that the light resistance of the light shielding film is more excellent.

The black pigment is preferably a pigment which alone develops a black color, and more preferably a pigment which alone develops a black color and absorbs infrared rays.

Here, the black pigment which absorbs infrared rays has absorption, for example, in a wavelength range of an infrared range (preferably, wavelengths of 650 to 1,300 nm). A black pigment having a maximal absorption wavelength in a wavelength range of wavelengths of 675 to 900 nm is also preferable.

The particle diameter of the black pigment is not particularly limited; however, it is preferably 5 to 100 nm, more preferably 5 to 50 nm, and still more preferably 5 to 30 nm, from the viewpoint that a balance between handleability and the temporal stability (a black pigment is not sedimented) of the composition is more excellent.

In addition, the particle diameter of the black pigment in the present specification refers to an average primary particle diameter of particles measured by the following method. The average primary particle diameter can be measured using a transmission electron microscope (TEM). As the transmission electron microscope, it is possible to use, for example, a transmission microscope HT7700 manufactured by Hitachi High-Tech Corporation.

A maximum length (Dmax: a maximum length between two points on a contour of the particle image) and a length vertical to the maximum length (DV-max: in a case where an image is sandwiched between two straight lines parallel to the maximum length, the shortest length that vertically connects the two straight lines) of a particle image obtained using the transmission electron microscope are measured, and a geometric mean value thereof (Dmax×DV-max)^{1/2} is taken as a particle diameter. Particle diameters of 100 particles are measured by this method, and an arithmetic average value thereof is taken as an average primary particle diameter of the particles.

Inorganic Pigment that is Used as Black Colorant

The inorganic pigment that is used as the black colorant is not particularly limited as long as the inorganic pigment has light shielding properties and is a particle containing an inorganic compound, and a known inorganic pigment can be used.

From the viewpoint that the low reflection properties and the light shielding properties of the light shielding film are superior, an inorganic pigment is preferable as the black colorant.

Examples of the inorganic pigment include a metal oxide, a metal nitride, and a metal oxynitride which contain a metallic element of group 4 such as titanium (Ti) or zirconium (Zr), a metallic element of Group 5 such as vanadium (V) or niobium (Nb), or one or more metallic elements selected from the group consisting of cobalt (Co), chromium (Cr), copper (Cu), manganese (Mn), ruthenium (Ru), iron (Fe), nickel (Ni), tin (Sn), and silver (Ag).

As the metal oxide, the metal nitride, and the metal oxynitride, particles in which other atoms are further mixed may be used. For example, metal nitride-containing particle, which further contains an atom (preferably, an oxygen atom and/or a sulfur atom) selected from elements of Groups 13 to 17 of the periodic table, can be used.

The production method for the metal nitride, the metal oxide, or the metal oxynitride is not particularly limited as long as a black pigment having desired physical properties can be obtained, and a known production method such as a gas-phase reaction method can be used. Examples of the gas-phase reaction method include an electric furnace method and a thermal plasma method, but from the viewpoint that few impurities are mixed in, particle diameters are likely to be uniform, and productivity is high, a thermal plasma method is preferable.

The metal nitride, the metal oxide, or the metal oxynitride may be subjected to a surface modification treatment. For example, the surface modification treatment can be carried out with a surface-treating agent having both a silicone group and an alkyl group. Examples of such inorganic particles include “KTP-09” series (manufactured by Shin-Etsu Chemical Co., Ltd.).

Among them, from the viewpoint that the generation of undercut in a case of forming a light shielding film can be suppressed, nitrides or oxynitrides of one or more metals selected from the group consisting of titanium, vanadium, zirconium, and niobium are more preferable. In addition, from the viewpoint that moisture resistance of the light shielding film is more excellent, an oxynitride of one or more metals selected from the group consisting of titanium, vanadium, zirconium, and niobium is still more preferable, and titanium oxynitride (titanium black), zirconium nitride, or zirconium oxynitride is particularly preferable.

The titanium black is black particles containing titanium oxynitride. The surface of the titanium black can be modified as necessary, for example, for the purpose of improving dispersibility or suppressing aggregating properties. The titanium black can be coated with silicon oxide, titanium oxide, germanium oxide, aluminum oxide, magnesium oxide, or zirconium oxide, and can also be treated with a water-repellent substance such as the substance described in JP2007-302836A.

Examples of the production method for the titanium black include a method (JP1974-5432A (JP-S49-5432A)) for heating and reducing a mixture of titanium dioxide and titanium metal in a reduction atmosphere, a method (JP1982-205322A (JP-S57-205322A)) for reducing ultrafine titanium dioxide obtained by hydrolyzing titanium tetrachloride at a high temperature in a reduction atmosphere containing hydrogen, a method (JP1985-65069A (JP-S60-65069A) and JP1986-201610A (JP-S61-201610A)) for reducing titanium dioxide or titanium hydroxide at a high temperature in the presence of ammonia, and a method (JP1986-201610A (JP-S61-201610A)) for attaching a vanadium compound to titanium dioxide or titanium hydroxide, and reducing the resultant at a high temperature in the presence of ammonia, but the production method is not limited to these examples.

The particle diameter of the titanium black is not particularly limited; however, it is preferably 10 to 45 nm and more preferably 12 to 20 nm. The specific surface area of the titanium black is not particularly limited; however, the value measured by the Brunauer-Emmett-Teller (BET) method is preferably 5 to 150 m²/g and more preferably 20 to 100 m²/g so that the water repellency after the surface treatment with a water repelling agent has a predetermined performance.

Examples of the commercially available product of the titanium black include TITANIUM BLACK 10S, 12S, 13R, 13M, 13M-C, 13R, 13R-N, and 13M-T (product names, manufactured by Mitsubishi Materials Corporation), Tilack D (product name, manufactured by AKO KASEI CO., LTD.), and MT-150A (product name, manufactured by TAYCA CORPORATION).

It is also preferable that the composition contains titanium black in a form of a substance to be dispersed, which contains the titanium black and the Si atom. In this form, the titanium black is contained as a substance to be dispersed in the composition. The content ratio (Si/Ti) of the Si atom to the Ti atom in the substance to be dispersed is preferably 0.05 to 0.5 and more preferably 0.07 to 0.4, in terms of mass. Here, the substance to be dispersed includes both titanium black which is in a state of primary particles and titanium black which is in a state of an aggregate (secondary particles).

In addition, in a case where the Si/Ti of the substance to be dispersed is equal to or larger more than a predetermined value, residues are less likely to remain in a removal part in a case where a coating film using the substance to be dispersed is patterned by optical lithography or the like, and in a case where the Si/Ti of the substance to be dispersed is equal to or smaller than a predetermined value, a light shielding ability is likely to be favorable.

In order to change the Si/Ti of the substance to be dispersed (for example, in order to change to be 0.05 or more), the following means can be used. First, a dispersion is obtained by dispersing titanium oxide and silica particles using a disperser, this mixture is subjected to a reduction treatment at a high temperature (for example, 850° C. to 1,000° C.), and thus a substance to be dispersed, which has titanium black particles as a main component and contains Si and Ti, can be obtained. The titanium black having the adjusted Si/Ti can be produced, for example, by the method described in paragraph Nos. 0005 and 0016 to 0021 of JP2008-266045A.

It is noted that the content ratio (Si/Ti) of the Si atom to the Ti atom in the substance to be dispersed can be measured, for example, by using the method (2-1) or method (2-3) described in paragraphs 0054 to 0056 of WO2011/049090A.

In the substance to be dispersed, which contains the titanium black and the Si atom, the above-described titanium black can be used as titanium black. In addition, in this substance to be dispersed, for the purpose of adjusting dispersibility, colorability, or the like, one black pigment, which consists of a complex oxide of a plurality of metals selected from Cu, Fe, Mn, V, Ni, and the like, cobalt oxide, iron oxide, carbon black, aniline black, and the like, or a combination of two or more black pigments may be used as a substance to be dispersed in combination with the titanium black. In this case, it is preferable that a substance to be dispersed consisting of titanium black accounts for 50% by mass or more of the total substance to be dispersed.

As the zirconium nitride and the zirconium oxynitride, the composites or the powders described in JP4931011B, JP2017-222559A, and JP2018-203599A can be used.

As the inorganic pigment, carbon black is also mentioned.

Examples of the carbon black include furnace black, channel black, thermal black, acetylene black, and lamp black.

As the carbon black, carbon black manufactured by a known method such as an oil furnace method may be used, or a commercially available product thereof may be used. Specific examples of the commercially available product of the carbon black include an organic pigment such as C. I. Pigment Black 1 and an inorganic pigment such as C. I. Pigment Black 7.

As the carbon black, carbon black subjected to a surface treatment is preferable. The surface treatment can reform the particle surface state of the carbon black and improve the dispersion stability in the composition. Examples of the surface treatment include a coating treatment with a resin, a surface treatment for introducing an acidic group, and a surface treatment with a silane coupling agent.

The carbon black is preferably carbon black subjected to a coating treatment with a resin. The light shielding properties and the insulating properties of the light shielding film can be improved by coating the particle surface of carbon black with an insulating resin. In addition, the reliability or the like of the image display device can be improved by reducing the leakage current or the like. As a result, the above-described carbon black is suitable for a case where a light shielding film is used in use applications which require insulating properties.

Examples of the coating resin include an epoxy resin, polyamide, polyamide imide, a novolak resin, a phenol resin, a urea resin, a melamine resin, polyurethane, a diallyl phthalate resin, an alkylbenzene resin, polystyrene, polycarbonate, polybutylene terephthalate, and modified polyphenylene oxide.

From the viewpoint that the light shielding properties and the insulating properties of the light shielding film are more excellent, the content of the coating resin is preferably 0.1% to 40% by mass and more preferably 0.5% to 30% by mass, with respect to the total of the carbon black and the coating resin.

In addition, the zirconium nitride described in JP2017-222559A and WO2019/130772A can also be preferably used.

Organic Pigment that is Used as Black Colorant

The organic pigment that is used as the black colorant is not particularly limited as long as the organic pigment has light shielding properties and is a particle containing an organic compound, and a known organic pigment can be used.

In the present invention, examples of the organic pigment include a bisbenzofuranone compound, an azomethine compound, a perylene compound, and an azo-based compound, and a bisbenzofuranone compound or a perylene compound is preferable.

Examples of the bisbenzofuranone compound include the compounds described in JP2010-534726A, JP2012-515233A, and JP2012-515234A. The bisbenzofuranone compound is available as “Irgaphor Black” (product name) manufactured by BASF SE.

Examples of the perylene compound include the compounds described in JP1987-1753A (JP-562-1753A) and JP1988-26784B (JP-563-26784B). The perylene compound is available as C. I. Pigment Black 21, 30, 31, 32, 33, and 34.

Black Dye

As a black dye, a dye which alone develops a black color can be used, and, for example, a pyrazole azo compound, a pyrromethene compound, an anilino azo compound, a triphenylmethane compound, an anthraquinone compound, a benzylidene compound, an oxonol compound, a pyrazolotriazole azo compound, a pyridone azo compound, a cyanine compound, a phenothiazine compound, a pyrrolopyrazole azomethine compound, and the like can be used.

In addition, with regard to the black dye, reference can be made to the compounds described in JP1989-90403A (JP-564-90403A), JP1989-91102A (JP-564-91102A), JP1989-94301A (JP-H1-94301A), JP1994-11614A (JP-H6-11614A), JP2592207B, U.S. Pat. Nos. 4,808,501A, 5,667,920A, 505,950A, 5,667,920A, JP1993-333207A (JP-H5-333207A), JP1994-35183A (JP-H6-35183A), JP1994-51115A (JP-H6-51115A), JP1994-194828A (JP-H6-194828A), and the like, the contents of which are incorporated into the present specification.

Specific examples of these black dyes include dyes specified by Color Index (C. I.) of SOLVENT BLACK 27 to 47, and a dye specified by C. I. of SOLVENT BLACK 27, 29, or 34 is preferable.

In addition, examples of the commercially available products of these black dyes include dyes such as SPILON Black MH and Black BH (both produced by Hodogaya Chemical Co., Ltd.), VALIFAST Black 3804, 3810, 3820, and 3830 (all produced by Orient Chemical Industries Co., Ltd.), Savinyl Black RLSN (produced by Clariant), and KAYASET Black K-R and K-BL (both produced by Nippon Kayaku Co., Ltd.).

In addition, a dye multimer may be used as the black dye. Examples of the dye multimer include the compounds described in JP2011-213925A and JP2013-041097A. In addition, a polymerizable dye having polymerizability in a molecule may be used, and examples of the commercially available product thereof include RDW series manufactured by FUJIFILM Wako Pure Chemical Corporation.

Further, as described above, a combination of a plurality of dyes, each of which has a color other than a black color, may be used as a black dye. As such a coloring dye, for example, the dye described in paragraphs 0027 to 0200 of JP2014-42375A can also be used in addition to a dye (chromatic dye) having a chromatic color such as red (R), green (G), and blue (B).

(White Colorant)

Examples of the white colorant include one or more selected from the group consisting of a white pigment and a white dye, and a white pigment is preferable from the viewpoint of weather fastness or the like.

Examples of the white pigment include titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably a particle having a titanium atom, and it is more preferably titanium oxide. As the titanium oxide, the titanium oxide described in “Titanium Oxide—Physical Properties and Applied Technology, Manabu KIYONO, Jun. 25, 1991, published by Gihodo Shuppan Co., Ltd.) can also be suitably used.

In addition, as the white pigment, C.I. Pigment White 1, 3, 6, 16, 18, and 21 can be used.

<Infrared Absorbing Agent>

The infrared absorbing agent refers to a compound having absorption in a wavelength range of an infrared range (preferably, wavelengths of 650 to 1,300 nm). The infrared absorbing agent is preferably a compound having a maximal absorption wavelength in a wavelength range of wavelengths of 675 to 900 nm.

Examples of the coloring agent having such spectral characteristics include a pyrrolo pyrrole compound, a copper compound, a cyanine compound, a phthalocyanine compound, an iminium compound, a thiol complex-based compound, a transition metal oxide-based compound, a squarylium compound, a naphthalocyanine compound, a quaterrylene compound, a dithiol metal complex-based compound, and a croconium compound.

As the phthalocyanine compound, the naphthalocyanine compound, the iminium compound, the cyanine compound, the squarylium compound, and the croconium compound, the compounds disclosed in paragraphs 0010 to 0081 of JP2010-111750A may be used, the content of which is incorporated into the present specification. Regarding the cyanine compound, reference can be made to, for example, “Functional Dyes, written by Makoto OKAWARA, Masaru MATSUOKA, Teijiro KITAO, and Tsuneaki HIRASHIMA, Kodansha Scientific Ltd.”, the contents of which are incorporated into the specification of the present application.

As the coloring agent having the spectral characteristics, the compound disclosed in paragraphs 0004 to 0016 of JP1995-164729A (JP-H07-164729A) and/or the compound disclosed in paragraphs 0027 to 0062 of JP2002-146254A, and the near-infrared absorption particles which are disclosed in paragraphs 0034 to 0067 of JP2011-164583A, consist of crystallites of an oxide containing Cu and/or P, and have a number-average aggregated particle diameter of 5 to 200 nm can also be used.

As the compound having a maximal absorption wavelength in a wavelength range of wavelengths of 675 to 900 nm, at least one selected from the group consisting of a cyanine compound, a pyrrolo pyrrole compound, a squarylium compound, a phthalocyanine compound, and a naphthalocyanine compound is preferable.

In addition, the infrared absorbing agent is preferably a compound which is dissolved in an amount of 1% by mass or more in water at 25° C., and more preferably a compound which is dissolved in an amount of 10% by mass more in water at 25° C. In a case where such a compound is used, solvent resistance is improved.

Regarding the pyrrolo pyrrole compound, reference can be made to paragraphs 0049 to 0062 of JP2010-222557A, the content of which is incorporated into the present specification. Regarding the cyanine compound and the squarylium compound, reference can be made to paragraphs 0022 to 0063 of WO2014/088063A, paragraphs 0053 to 0118 of WO2014/030628A, paragraphs 0028 to 0074 of JP2014-59550A, paragraphs 0013 to 0091 of WO2012/169447A, paragraphs 0019 to 0033 of JP2015-176046A, paragraphs 0053 to 0099 of JP2014-63144A, paragraphs 0085 to 0150 of JP2014-52431A, paragraphs 0076 to 0124 of JP2014-44301A, paragraphs 0045 to 0078 of JP2012-8532A, paragraphs 0027 to 0067 of JP2015-172102A, paragraphs 0029 to 0067 of JP2015-172004A, paragraphs 0029 to 0085 of JP2015-40895A, paragraphs 0022 to 0036 of JP2014-126642A, paragraphs 0011 to 0017 of JP2014-148567A, paragraphs 0010 to 0025 of JP2015-157893A, paragraphs 0013 to 0026 of JP2014-095007A, paragraphs 0013 to 0047 of JP2014-80487A, paragraphs 0007 to 0028 of JP2013-227403A, and the like, the contents of which are incorporated into the present specification.

[Polymerization Inhibitor]

The composition according to the embodiment of the present invention may contain a polymerization inhibitor.

As the polymerization inhibitor, for example, a known polymerization inhibitor can be used. Examples of the polymerization inhibitor include a phenolic polymerization inhibitor (for example, p-methoxyphenol, 2,5-di-tert-butyl-4-methylphenol, 2,6-di-tert-butyl-4-methylphenol, 4,4′-thiobis(3-methyl-6-t-butylphenol), 2,2′-methylenebis(4-methyl-6-t-butylphenol), 4-methoxynaphthol, and the like); a hydroquinone-based polymerization inhibitor (for example, hydroquinone, 2,6-di-tert-butylhydroquinone, and the like); a quinone-based polymerization inhibitor (for example, benzoquinone and the like); a free radical-based polymerization inhibitor (for example, 2,2,6,6-tetramethylpiperidine 1-oxyl free radical, 4-hydroxy-2,2,6,6-tetramethylpiperidine 1-oxyl free radicals, and the like); a nitrobenzene-based polymerization inhibitor (for example, nitrobenzene, 4-nitrotoluene, and the like); and a phenothiazine-based polymerization inhibitor (for example, phenothiazine, 2-methoxyphenothiazine, and the like).

Among them, from the viewpoint that the composition has a more excellent effect, a phenolic polymerization inhibitor or a free radical-based polymerization inhibitor is preferable.

The content of the polymerization inhibitor is preferably 0.0001% to 0.5% by mass, more preferably 0.001% to 0.2% by mass, and still more preferably 0.008% to 0.05% by mass, with respect to the total solid content of the composition. The polymerization inhibitor may be used alone or in a combination of two or more thereof. In a case where two or more polymerization inhibitors are used in combination, the total content thereof is preferably within the above range.

In addition, the ratio (the content of the polymerization inhibitor/the content of the polymerizable compound (in terms of mass ratio)) of the content of the polymerization inhibitor to the content of the polymerizable compound in the composition is preferably 0.00005 to 0.02 and more preferably 0.0001 to 0.005.

[Organic Solvent]

The composition according to the embodiment of the present invention contains an organic solvent contained in the dispersion liquid; however, it may contain an organic solvent in addition to the organic solvent that is contained in the composition due to the addition of the dispersion liquid. Specific examples of such an organic solvent are the same as those of the organic solvent contained in the dispersion liquid, and thus the description thereof will be omitted.

The content of the organic solvent (including the organic solvent contained in the dispersion liquid) is preferably 10% to 97% by mass with respect to the total mass of the composition. The lower limit thereof is preferably 30% by mass or more, more preferably 40% by mass or more, still more preferably 50% by mass or more, even still more preferably 60% by mass or more, and particularly preferably 70% by mass or more. The upper limit thereof is preferably 96% by mass or less and more preferably 95% by mass or less. The composition may contain only one kind of organic solvent or may contain two or more kinds thereof. In a case where two or more kinds thereof are contained, the total amount thereof is preferably within the above range.

[Other Optional Components]

The composition may further contain an optional component in addition to the above-described components. Examples thereof include particle components other than the above-described components, an ultraviolet absorbing agent, a silane coupling agent, a surfactant, a sensitizer, a co-sensitizer, a crosslinking agent, a curing accelerator, a heat curing accelerator, a plasticizer, a diluent, and an oil sensitizing agent, and known additives such as an adhesion promoter to the surface of the substrate and other auxiliaries (for example, conductive particles, a filler, an anti-foaming agent, a flame retardant, a leveling agent, a peeling accelerator, an antioxidant, a fragrance, a surface tension adjuster, a chain transfer agent, and the like) may be further added, as necessary.

Regarding these components, reference can be made to, for example, the descriptions in paragraphs 0183 to 0228 of JP2012-003225A (corresponding to paragraphs 0237 to 0309 of US2013/0034812A), paragraphs 0101, 0102, 0103, 0104, and 0107 to 0109 of JP2008-250074A, and paragraphs 0159 to 0184 of JP2013-195480A, the contents of which are incorporated into the specification of the present application.

[Production Method for Composition]

The composition according to the embodiment of the present invention can be prepared by mixing the above-described respective components through a known mixing method (for example, a mixing method using a stirrer, a homogenizer, a high-pressure emulsification device, a wet-type pulverizer, a wet-type disperser, or the like).

Here, in a case where the composition according to the embodiment of the present invention contains a coloring material, it is preferable that a coloring material dispersion liquid in which the above-described dispersion liquid and a coloring material are dispersed is produced, and this coloring material dispersion liquid is further mixed with the other component to obtain a composition.

The coloring material dispersion liquid is preferably prepared by mixing a coloring material, a resin (preferably, a dispersing agent), and a solvent. In addition, it is also preferable that a polymerization inhibitor is contained in the coloring material dispersion liquid.

In a case of preparing the composition, the respective components may be formulated at once, or each of the components may be dissolved or dispersed in a solvent and then sequentially formulated. In addition, the input order and the operation conditions during the formulation are not particularly limited.

For the purpose of removing foreign substances, reducing defects, and the like, the composition is preferably filtered with a filter. Since the filter is the same as the filter described in the production method for a dispersion liquid, the description thereof will be omitted.

The composition preferably does not contain impurities such as a metal, a halogen-containing metal salt, an acid, and an alkali. The content of impurities contained in these materials is preferably 1 ppm by mass or less, more preferably 1 ppb by mass or less, still more preferably 100 ppt by mass or less, and particularly preferably 10 ppt by mass or less, and it is most preferable that the impurities are substantially not contained (the content is equal to or less than the detection limit of the measuring device).

It is noted that the impurities can be measured using an inductively coupled plasma mass spectrometer (manufactured by Agilent Technologies, Inc., Agilent 7500cs model).

[Cured Film]

The cured film according to the embodiment of the present invention is a film formed from the above-described composition according to the embodiment of the present invention. Specifically, a composition layer formed from the composition according to the embodiment of the present invention is cured to obtain a cured film (including a patterned cured film) as the cured film according to the embodiment of the present invention.

The manufacturing method for a cured film is not particularly limited; however, it preferably includes the following steps.
Composition layer forming step
Exposure step
Development step

Hereinafter, each of the steps will be described.

[Composition Layer Forming Step]

In the composition layer forming step, prior to exposure, the composition is applied on a support or the like to form a layer (composition layer) of the composition. As the support, for example, a substrate for a solid-state imaging element, in which an imaging element (light-receiving element) such as a charge coupled device (CCD) or a complementary metal-oxide semiconductor (CMOS) is provided on a substrate (for example, a silicon substrate), can be used. In addition, in order to improve adhesion with the upper layer, prevent the diffusion of substances, and planarize the surface of the substrate, an undercoat layer (a base layer) may be provided on the support, as needed.

As a method of applying the composition onto the support, for example, various coating methods such as a slit coating method, an ink jet method, a spin coating method, a cast coating method, a roll coating method, and a screen printing method can be applied. The film thickness of the composition layer is preferably 0.1 to 10 μm, more preferably 0.2 to 5 μm, and still more preferably 0.2 to 3 μm. The composition layer applied on the support can be dried (pre-baked) at a temperature of 50° C. to 140° C. for 10 to 300 seconds, for example, using a hot plate, an oven, or the like.

Examples of the undercoat layer include a film containing a resin such as a (meth)acrylic resin. Specific examples of the forming method of an undercoat layer include a method in which a composition containing (meth)acrylate, a crosslinking agent, a surfactant, a solvent, and the like is applied onto a support by a coating method such as a rotary coating method (a spin coating method) to obtain a coating film and then the coating film is dried.

The undercoat layer preferably has a contact angle of 20 to 70 degrees in a case of being measured with diiodomethane and has a contact angle of 30 to 80 degrees in a case of being measured with water. In a case where the contact angle is equal to or more than the lower limit of the above range, the wettability of the color filter is good, and in a case where it is equal to or lower than the upper limit thereof, the surface energy of the film is controlled so that the coating properties onto the undercoat layer is good. Examples of the method of adjusting the contact angle to the above range include a method of controlling the addition or drying speed of a surfactant, the spin coating, the rotation speed, or the like. The contact angle of the undercoat layer is measured using a contact angle meter based on a liquid droplet method.

As the undercoat layer, a commercially available product may be used, and examples thereof include CT-4000L manufactured by FUJIFILM Electronic Materials Co., Ltd.

[Exposure Step]

In the exposure step, the composition layer formed in the composition layer forming step is exposed by irradiation with actinic rays or radiation, and the composition layer irradiated with light is cured.

In the method of light irradiation, it is preferable to carry out light irradiation through a photo mask having a patterned opening portion.

The exposure is preferably carried out by irradiation with radiation. The radiation, which can be used during the exposure, is preferably ultraviolet rays such as a g-line, an h-line, or an i-line, and a light source is preferably a high-pressure mercury lamp. The irradiation intensity is preferably 5 to 1,500 mJ/cm² and more preferably 10 to 1,000 mJ/cm².

In addition, in a case where the composition contains a thermal polymerization initiator, the composition layer may be heated in the exposure step. The heating temperature is not particularly limited; however, it is preferably 80° C. to 250° C. In addition, the heating time is preferably 30 to 300 seconds.

It is noted that in a case where the composition layer is heated in the exposure step, the exposure step may serve as a post-heating step which will be described later. In other words, in a case where the composition layer is heated in the exposure step, the manufacturing method for a cured film may not include the post-heating step.

[Development Step]

The development step is a step of developing the exposed composition layer to form a cured film. By this step, the composition layer in a portion which is not irradiated with light in the exposure step is eluted, only a photo-cured portion remains, and thus a patterned cured film can be obtained.

The kind of the developer used in the development step is not particularly limited; however, an alkali developer which does not damage the underlying imaging element and circuit or the like is desirable.

The development temperature is, for example, 20° C. to 30° C.

The development time is, for example, 20 to 90 seconds. In order to further efficiently remove the residues, in recent years, the development may be carried out for 120 to 180 seconds. Furthermore, in order to further improve residue removability, a step of shaking off the developer every 60 seconds and further supplying a fresh developer may be repeated several times.

The alkali developer is preferably an alkaline aqueous solution which is prepared by dissolving an alkaline compound in water so that the concentration thereof is 0.001% to 10% by mass (preferably 0.01% to 5% by mass).

Examples of the alkaline compound include sodium hydroxide, potassium hydroxide, sodium carbonate, sodium silicate, sodium metasilicate, aqueous ammonia, ethylamine, diethylamine, dimethylethanolamine, tetramethylammonium hydroxide, tetraethylammonium hydroxide, tetrapropylammonium hydroxide, tetrabutylammonium hydroxide, benzyltrimethylammonium hydroxide, choline, pyrrole, piperidine, and 1,8-diazabicyclo[5.4.0]-7-undecene (among them, an organic alkali is preferable).

It is noted that in a case where the alkaline compound is used as an alkali developer, the alkaline compound is generally subjected to a washing treatment with water after development.

[Post-Baking]

A heating treatment (post-baking) is preferably carried out after the exposure step. The post-baking is a heating treatment after development for completing the curing. The heating temperature is preferably 240° C. or higher and more preferably 220° C. or higher. The lower limit thereof is not particularly limited; however, it is preferably 50° C. or more and more preferably 100° C. or more, in consideration of efficient and effective treatment.

The post-baking can be carried out continuously or batchwise by using a heating unit such as a hot plate, a convection oven (hot-air circulating dryer), and a high-frequency heater.

The post-baking is preferably carried out in an atmosphere of a low oxygen concentration. The oxygen concentration is preferably 19% by volume or less, more preferably 15% by volume or less, still more preferably 10% by volume or less, particularly preferably 7% by volume or less, and most preferably 3% by volume or less. The lower limit thereof is not particularly limited; however, it is practically 10 ppm by volume or more.

In addition, the curing may be completed by irradiation with ultraviolet rays (UV) instead of the post-baking by heating.

In this case, it is preferable that the composition described above further contains a UV curing agent. The UV curing agent is preferably a UV curing agent which can be cured at a wavelength shorter than 365 nm that is an exposure wavelength of a polymerization initiator added for a lithography step by ordinary i-line exposure. Examples of the UV curing agent include CIBA IRGACURE 2959 (product name). In a case where UV irradiation is carried out, the composition layer is preferably a material which is cured at a wavelength of 340 nm or less. The lower limit value of the wavelength is not particularly limited; however, it is generally 220 nm or more. In addition, the exposure amount of the UV irradiation is preferably 100 to 5,000 mJ, more preferably 300 to 4,000 mJ, and still more preferably 800 to 3,500 mJ. The UV curing step is preferably carried out after the exposure step, in order to more effectively carry out low-temperature curing. As the exposure light source, an ozoneless mercury lamp is preferably used.

[Physical Properties, Shape, Use Application, and the Like of Cured Film]

The film thickness of the cured film is, for example, preferably 0.1 to 4.0 μm and more preferably 1.0 to 2.5 μm. In addition, the cured film may be thinner or thicker than the above range depending on the use application.

The reflectivity of the cured film is preferably 10% or less, more preferably 5% or less, and still more preferably 3% or less. The lower limit thereof is 0% or more.

The reflectivity mentioned here is obtained from the reflectivity spectrum obtained by causing light having wavelengths of 400 to 1,100 nm to be incident at an incidence angle of 5° using a VAR unit of a spectrometer V7200 (product name) manufactured by JASCO Corporation. Specifically, the reflectivity of light having a wavelength at which the maximum reflectivity is exhibited in a wavelength range of 400 to 1,100 nm shall be taken as the reflectivity of the cured film.

In a case where the cured film has a patterned shape, the size of one side of the pattern of the cured film is preferably 3 μm or less, more preferably 2 μm or less, and still more preferably 1.4 μm or less. The lower limit of the size of one side of the pattern of the cured film is not particularly limited; however, it is preferably 0.3 μm.

The pattern shape of the cured film is not particularly limited; however, in a case where the cured film is a color filter that is used in a solid-state imaging element or the like, the pattern shape of the cured film is generally rectangular.

In addition, the cured film is suitable for a light shielding member and a light shielding film as well as an antireflection member and an antireflection film of an optical filter (for example, a color filter) and a module that are used in portable instruments such as a personal computer, a tablet PC, a mobile phone, a smartphone, and a digital camera; office automation (OA) instruments such as a printer composite machine and a scanner; industrial instruments such as a surveillance camera, a barcode reader, an automated teller machine (ATM), a high-speed camera, and an instrument having a personal authentication function using face image authentication or biometric authentication; in-vehicle camera instruments; medical camera instruments such as an endoscope, a capsule endoscope, and a catheter; a biosensor, a military reconnaissance camera, a camera for a three-dimensional map, a camera for observing weather and sea, a camera for a land resource exploration, and space instruments such as an exploration camera for the astronomy of the space and a deep space target.

The cured film can also be used in applications of a micro light emitting diode (LED), a micro organic light emitting diode (OLED). The cured film is suitable for an optical filter and an optical film (for example, a color filter) that are used in the micro LED and the micro OLED as well as a member which imparts a light shielding function or an antireflection function.

Examples of the micro LED and the micro OLED include the examples described in JP2015-500562A and JP2014-533890A.

The cured film is also suitable as an optical filter and an optical film (for example, a color filter) that are used in a quantum dot sensor and a quantum dot solid-state imaging element. In addition, the cured film is suitable as a member which imparts a light shielding function or an antireflection function. Examples of the quantum dot sensor and the quantum dot solid-state imaging element include the examples described in US2012/37789A and WO2008/131313A.

[Light Shielding Film, Color Filter, Optical Element, and Solid-State Imaging Element as Well as Solid-State Imaging Device]

In a case where the cured film according to the embodiment of the present invention is formed from the composition according to the embodiment of the present invention in which a black colorant is used as the coloring material, it is also preferable that it is used as a so-called light shielding film. It is also preferable that such a light shielding film is used in a solid-state imaging element.

It is noted that the light shielding film is one of the preferred use applications in the cured film according to the embodiment of the present invention, and the light shielding film according to the embodiment of the present invention can be manufactured by the same method as the method described as the above manufacturing method for a cured film.

In a case of being formed from the composition according to the embodiment of the present invention, in which a chromatic colorant is used as the coloring material, the cured film according to the embodiment of the present invention is also preferable to be used as a so-called color filter. It is also preferable that such a color filter is used in a solid-state imaging element.

It is noted that the color filter is one of the preferred use applications in the cured film according to the embodiment of the present invention, and the color filter according to the embodiment of the present invention can be manufactured by the same method as the method described as the above manufacturing method for a cured film.

The present invention also includes an invention of an optical element. The optical element according to the embodiment of the present invention is an optical element including the above-described cured film. Examples of the optical element include an optical element that is used in an optical instrument such as a camera, binoculars, a microscope, and a semiconductor exposure device.

Among them, the optical element is preferably, for example, a solid-state imaging element mounted on a camera or the like.

In addition, the solid-state imaging element according to the embodiment of the present invention is a solid-state imaging element including the cured film according to the embodiment of the present invention.

Examples of the form in which the solid-state imaging element according to the embodiment of the present invention includes the cured film include a form in which a plurality of photodiodes and light-receiving elements formed of polysilicon or the like, which constitute a light-receiving area of a solid-state imaging element (a CCD image sensor, a CMOS image sensor, or the like), are provided on a substrate, and the cured film is provided on a surface side (for example, a portion other than light-receiving parts and/or pixels for adjusting color) of a support on which the light-receiving elements are formed or on a side opposite to the surface on which the light-receiving elements are formed.

In addition, in a case where the cured film is used as a light attenuating film, for example, by disposing the light attenuating film so that a part of the light passes through the light attenuating film and then is incident on a light-receiving element, the dynamic range of the solid-state imaging element can be improved.

The solid-state imaging device is equipped with the above-described solid-state imaging element.

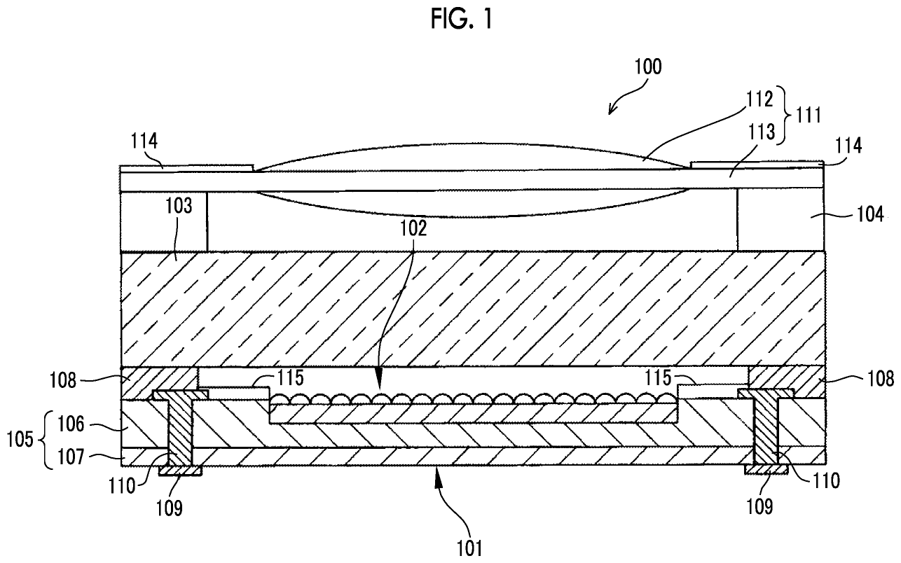

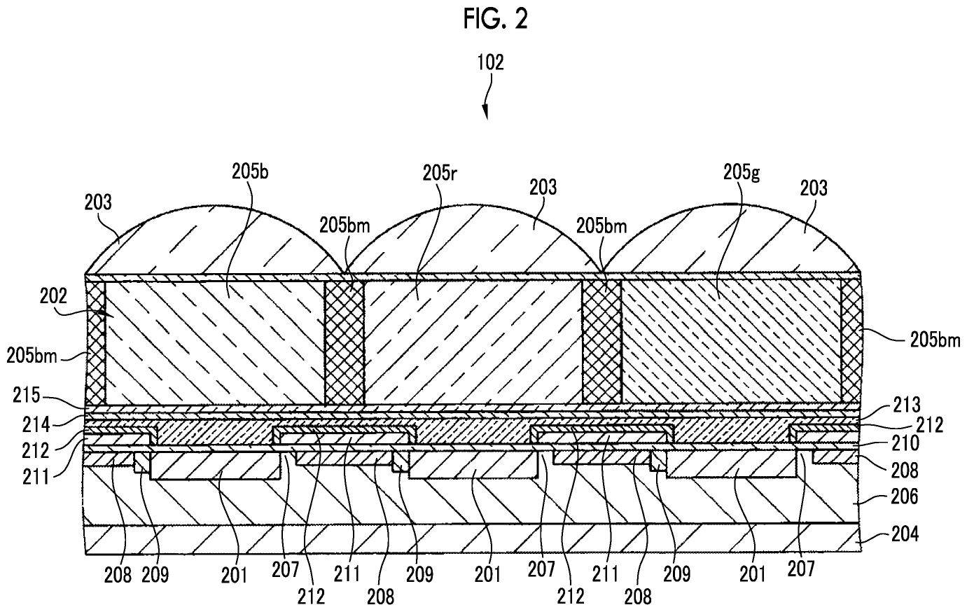

Examples of the configurations of the solid-state imaging device and the solid-state imaging element will be described with reference to FIGS. 1 and 2. In FIGS. 1 and 2, some parts are magnified in disregard of the thickness ratio and/or the width ratio between the parts so that the respective parts are clearly seen.

FIG. 1 is a schematic cross-sectional view illustrating an example of the configuration of the solid-state imaging device including the solid-state imaging element according to the embodiment of the present invention.

As illustrated in FIG. 1, a solid-state imaging device 100 includes a rectangular solid-state imaging element 101 and a transparent cover glass 103 which is held above the solid-state imaging element 101 and seals the solid-state imaging element 101. Further, on the cover glass 103, a lens layer 111 is superposably provided through a spacer 104. The lens layer 111 includes a support 113 and a lens material 112. The lens layer 111 may have a configuration in which the support 113 and the lens material 112 are integrally formed. In a case where stray light is incident on the peripheral edge region of the lens layer 111, due to the diffusion of light, an effect of light condensation on the lens material 112 is weakened, and thus the light reaching an imaging unit 102 is reduced. In addition, noise is also generated due to the stray light. For this reason, a light shielding film 114 is provided in the peripheral edge region of the lens layer 111 so that light is shielded. The cured film according to the embodiment of the present invention can also be used as the light shielding film 114.

The solid-state imaging element 101 carries out photoelectric conversion on an optical image formed on the imaging unit 102 serving as a light-receiving surface of the solid-state imaging element 101, and outputs the converted optical image as an image signal. The solid-state imaging element 101 includes a laminated substrate 105 obtained by laminating two sheets of substrates. The laminated substrate 105 consists of a chip substrate 106 and a circuit board 107 which have the same size and a rectangular shape, and the circuit board 107 is laminated on the rear surface of the chip substrate 106.

As the material of the substrate that is used as the chip substrate 106, for example, a known material can be used.

The imaging unit 102 is provided in the central part of the surface of the chip substrate 106. In addition, a light shielding film 115 is provided in the peripheral edge region of the imaging unit 102. Since the stray light incident on the peripheral edge region is shielded by the light shielding film 115, the generation of a dark current (noise) from a circuit in the peripheral edge region can be prevented. The cured film according to the embodiment of the present invention can be used as the light shielding film 115.

A plurality of electrode pads 108 are provided at an edge part of the surface of the chip substrate 106. The electrode pads 108 are electrically connected to the imaging unit 102 through a signal line (a bonding wire can also be used) (not shown) provided on the surface of the chip substrate 106.

On the rear surface of the circuit board 107, external connection terminals 109 are provided at positions approximately below the electrode pads 108, respectively. The external connection terminals 109 are respectively connected to the electrode pads 108 through a through-electrode 110 vertically passing through the laminated substrate 105. In addition, the external connection terminals 109 are connected to a control circuit controlling the driving of the solid-state imaging element 101, an image processing circuit carrying out image processing on an imaging signal output from the solid-state imaging element 101, and the like through a wiring line (not shown).

A schematic cross-sectional view of the imaging unit 102 is illustrated in FIG. 2. As illustrated in FIG. 2, the imaging unit 102 includes the parts, such as a light-receiving element 201, a color filter 202, and a micro lens 203, which are provided on a substrate 204. The color filter 202 has a blue pixel 205b, a red pixel 205r, a green pixel 205g, and a black matrix 205bm. The cured film according to the embodiment of the present invention may be used as the blue pixel 205b, the red pixel 205r, the green pixel 205g, and the black matrix 205bm.

As the material of the substrate 204, for example, the same material as that of the chip substrate 106 can be used. On the surface layer of the substrate 204, a p-well layer 206 is formed. In the p-well layer 206, the light-receiving elements 201, which consist of an n-type layer and generate and accumulate signal charges by photoelectric conversion, are formed to be arranged in the square lattice form.

On one lateral side of each light-receiving element 201, through a reading gate part 207 on the surface layer of the p-well layer 206, a vertical electric charge transfer path 208 consisting of an n-type layer is formed. In addition, on the other lateral side of each light-receiving element 201, through an element separation region 209 consisting of a p-type layer, a vertical electric charge transfer path 208 belonging to the adjacent pixel is formed. The reading gate part 207 is a channel region for the signal charges accumulated in the light-receiving element 201 to be read out toward the vertical electric charge transfer path 208.

On the surface of the substrate 204, a gate insulating film 210 consisting of an oxide-nitride-oxide (ONO) film is formed. On the gate insulating film 210, vertical electric charge transfer electrodes 211 consisting of polysilicon or amorphous silicon are formed to cover the portions which are approximately immediately above the vertical electric charge transfer path 208, the reading gate part 207, and the element separation region 209. The vertical electric charge transfer electrodes 211 function as driving electrodes for driving the vertical electric charge transfer path 208 and carrying out charge transfer, and as reading electrodes for driving the reading gate part 207 and reading out signal charges. The signal charges are transferred to a horizontal electric charge transfer path and an output part (floating diffusion amplifier), which are not shown in the drawing, in this order from the vertical electric charge transfer path 208, and then output as voltage signals.

On each of the vertical electric charge transfer electrodes 211, a light shielding film 212 is formed to cover the surface of the electrode. The light shielding film 212 has an opening portion at a position immediately above the light-receiving element 201 and shields a region other than the opening portion from light. The cured film according to the embodiment of the present invention may be used as the light shielding film 212.

On the light shielding film 212, a transparent interlayer, which consists of an insulating film 213 consisting of borophosphosilicate glass (BPSG), an insulating film (passivation film) 214 consisting of P—SiN, and a planarization film 215 formed of a transparent resin or the like, is provided. The color filter 202 is formed on the interlayer.

[Image Display Device]

An image display device according to the embodiment of the present invention is equipped with the cured film according to the embodiment of the present invention.

Examples of the form in which the image display device has a cured film include a form in which the color filter formed from the cured film according to the embodiment of the present invention is used in the image display device. The color filter may include a black matrix.

Next, a black matrix and a color filter including the black matrix will be described, and further, a liquid crystal display device including such a color filter will be described as a specific example of the image display device.

<Black Matrix>

It is also preferable that the cured film according to the embodiment of the present invention is contained in the black matrix. The black matrix may be included a color filter, a solid-state imaging element, and an image display device such as a liquid crystal display device in some cases.

Examples of the black matrix include those described above; a black rim provided in the peripheral edge part of an image display device such as a liquid crystal display device; a lattice-formed and/or stripe-like black portion between pixels of red, blue, and green; and a dot-like and/or linear black pattern for shielding a thin film transistor (TFT) from light. The definition of the black matrix is described in, for example, “Glossary of liquid crystal display manufacturing device”, written by Yasuhira KANNO, 2nd edition, NIKKAN KOGYO SHIMBUN, LTD., 1996, p. 64.

In order to improve the display contrast, and to prevent image quality deterioration resulting from current leakage of light in a case of an active matrix driving-type liquid crystal display device using a thin film transistor (TFT), the black matrix preferably has high light shielding properties (the optical density OD is 3 or more).

As the manufacturing method for the black matrix, for example, the black matrix can be manufactured in the same manner as the manufacturing method for the cured film. Specifically, by applying the composition onto a substrate to form a composition layer and carrying out exposure and development on the composition layer, a patterned cured film (a black matrix) can be manufactured. It is noted that the film thickness of the cured film used as the black matrix is preferably 0.1 to 4.0 μm.

The material of the substrate preferably has a light transmittance of 80% or more for visible light (wavelength of 400 to 800 nm). Examples of such a material include: glass such as soda lime glass, alkali-free glass, quartz glass, and borosilicate glass; and plastic such as a polyester-based resin and a polyolefin-based resin, and from the viewpoints of chemical resistance and heat resistance, alkali-free glass, quartz glass, or the like is preferable.

<Color Filter>

It is also preferable that the cured film according to the embodiment of the present invention is included in a color filter.

Examples of the form in which the color filter includes a cured film include a color filter including a substrate and colored pixels (a cured film) of red, green, and blue which are formed on the substrate. In addition, the color filter may be a color filter including a substrate, the above black matrix, and colored pixels (a cured film) of red, green, and blue which are formed in the opening portion of the black matrix formed on the substrate.

The color filter including a black matrix can be manufactured, for example, by the following method.

First, in an opening portion of a patterned black matrix formed on a substrate, a coating film (composition layer) of a composition containing each of coloring materials corresponding to the respective colored pixels of the color filter is formed.

Subsequently, the composition layer is subjected to exposure through a photo mask having a pattern corresponding to the opening portion of the black matrix. Next, colored pixels can be formed in the opening portion of the black matrix by removing non-exposed portions by a development treatment, and then carrying out baking. In a case where the series of operations are carried out using, for example, a composition containing red, green, and blue pigments, a color filter having red, green, and blue pixels can be manufactured.

[Liquid Crystal Display Device]

It is also preferable that the cured film according to the embodiment of the present invention is included in a liquid crystal display device. Examples of the form in which the liquid crystal display device includes the cured film include a form in which a liquid crystal display device includes the color filter described above.

Examples of the liquid crystal display device according to the present embodiment include a form in which a liquid crystal display device includes a pair of substrates disposed to face each other and a liquid crystal compound sealed in the space between the substrates. The substrate is as described above, for example, as the substrate for a black matrix.

Examples of the specific form of the liquid crystal display device include a laminate including polarizing plate/substrate/color filter/transparent electrode layer/alignment film/liquid crystal layer/alignment film/transparent electrode layer/thin film transistor (TFT) element/substrate/polarizing plate/backlight unit in this order from the user side.

In addition, examples of the liquid crystal display device include the liquid crystal display devices described in “Electronic display device (written by Akio SASAKI, Kogyo CHOSAKAI Publishing Co., Ltd., published in 1990)”, “Display device (written by Sumiaki IBUKI, Sangyo Tosho Publishing Co., Ltd., published in 1989)”, or the like. In addition, examples thereof include the liquid crystal display device described in “Next-Generation Liquid Crystal Display Technology (edited by Tatsuo UCHIDA, Kogyo Chosakai Publishing Co., Ltd., published in 1994)”.

[Infrared Sensor]

It is also preferable that the cured film according to the embodiment of the present invention is included in an infrared sensor.

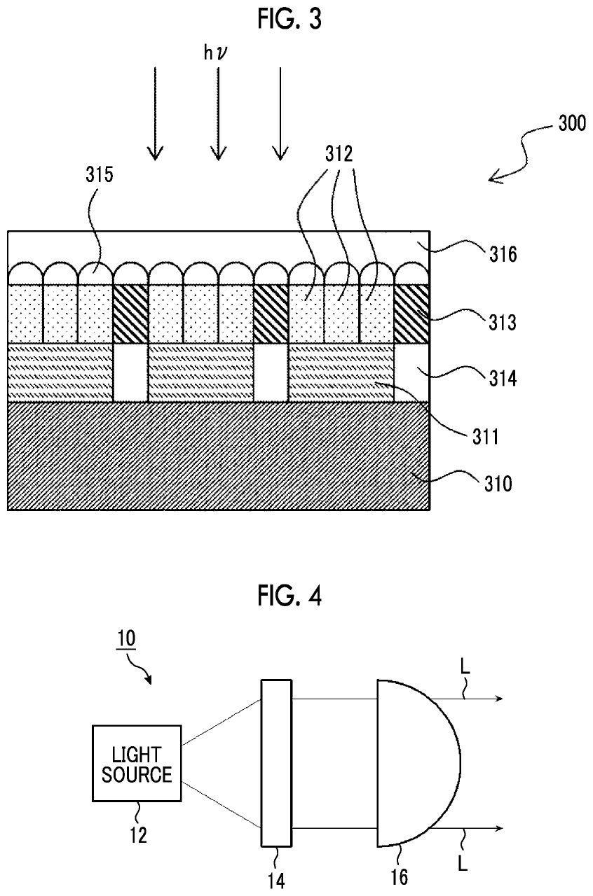

The infrared sensor according to the embodiment will be described with reference to FIG. 3. FIG. 3 is a schematic cross-sectional view illustrating an example of the configuration of an infrared sensor comprising the cured film according to the embodiment of the present invention. An infrared sensor 300 illustrated in FIG. 3 includes a solid-state imaging element 310.

An imaging region provided on the solid-state imaging element 310 is configured by combining an infrared absorption filter 311 and a color filter 312 according to the embodiment of the present invention.

The infrared absorption filter 311 is a film which transmits light (for example, light having wavelengths of 400 to 700 nm) in the visible light range and shields light (for example, light having wavelengths of 800 to 1,300 nm, preferably light having wavelengths of 900 to 1,200 nm, and more preferably light having wavelengths of 900 to 1,000 nm) in the infrared range, and a cured film containing an infrared absorbing agent (the form of the infrared absorbing agent is as described above) as a coloring material can be used.

The color filter 312 is a color filter in which pixels transmitting or absorbing light having a specific wavelength in the visible light range are formed, for example, a color filter in which pixels of red (R), green (G), and blue (B) are formed, or the like is used, and the form thereof is as described above.

Between an infrared transmitting filter 313 and the solid-state imaging element 310, a resin film 314 (for example, a transparent resin film or the like), which is capable of transmitting light having the wavelength transmitted through the infrared transmitting filter 313, is disposed.

The infrared transmitting filter 313 is a filter which has visible light shielding properties and transmits infrared rays having a specific wavelength, and the cured film according to the embodiment of the present invention can be used, which contains a coloring agent (for example, a perylene compound and/or a bisbenzofuranone compound) absorbing light in a visible light range, and an infrared absorbing agent (for example, a pyrrolo pyrrole compound, a phthalocyanine compound, a naphthalocyanine compound, a polymethine compound, or the like). It is preferable that, for example, the infrared transmitting filter 313 shields light having wavelengths of 400 to 830 nm and transmits light having wavelengths of 900 to 1,300 nm.

On the incidence ray hv side of the color filter 312 and the infrared transmitting filter 313, micro lenses 315 are arranged. A planarization film 316 is formed to cover the micro lenses 315.

In the form illustrated in FIG. 3, the resin film 314 is disposed; however, the infrared transmitting filter 313 may be formed instead of the resin film 314. That is, on the solid-state imaging element 310, the infrared transmitting filter 313 may be formed.

In the form illustrated in FIG. 3, the film thickness of the color filter 312 is the same as the film thickness of the infrared transmitting filter 313, but both the film thicknesses may be different from each other.

In the form illustrated in FIG. 3, the color filter 312 is provided to be closer to the incidence ray hv side than the infrared absorption filter 311, but the order of the infrared absorption filter 311 and the color filter 312 may be switched so that the infrared absorption filter 311 is provided to be closer to the incidence ray hv side than the color filter 312.

In the form illustrated in FIG. 3, the infrared absorption filter 311 and the color filter 312 are laminated to be adjacent to each other, but both the filters are not necessarily adjacent to each other, and another layer may be provided between the filters. The cured film according to the embodiment of the present invention can be used as a light shielding film on an end part of the surface and/or a lateral surface of the infrared absorption filter 311, and in a case of being used in an interior wall of a device of an infrared sensor, the internal reflection and/or the unintended incidence of light on the light-receiving part can be prevented and thus sensitivity can be improved.

According to the infrared sensor, image information can be simultaneously taken in, and thus motion sensing or the like by which a subject whose movement is to be detected is recognized can be carried out. In addition, according to the infrared sensor, distance information can be obtained, and thus images including 3D information and the like can also be captured. Further, this infrared sensor can also be used as a biometric authentication sensor.

Next, a solid-state imaging device to which the above-described infrared sensor is applied will be described.

The solid-state imaging device includes a lens optical system, a solid-state imaging element, an infrared light emitting diode. It is noted that regarding each of the configurations of the solid-state imaging device, reference can be made to paragraphs 0032 to 0036 of JP2011-233983A, the contents of which are incorporated into the specification of the present application.

[Headlight Unit]

It is also preferable that the cured film according to the embodiment of the present invention is included, as the light shielding film, in a headlight unit of a lighting tool for a vehicle such as an automobile. The cured film according to the embodiment of the present invention, which is included in the headlight unit as the light shielding film, is preferably formed in a patterned manner to shield at least a part of light emitted from a light source.

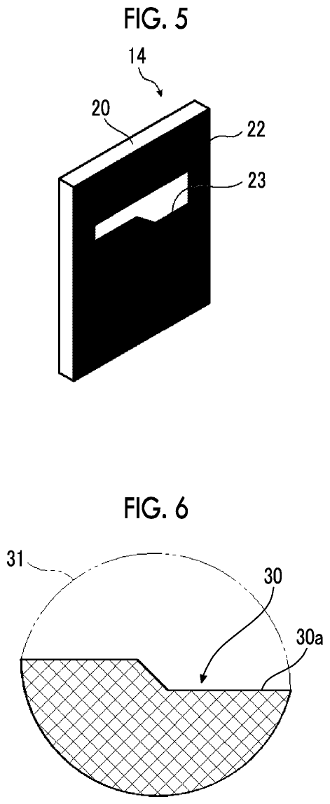

The headlight unit according to the embodiment will be described with reference to FIGS. 4 and 5. FIG. 4 is a schematic view illustrating an example of the configuration of the headlight unit, and FIG. 5 is a schematic perspective view illustrating an example of the configuration of a light shielding unit of the headlight unit.

As illustrated in FIG. 4, a headlight unit 10 includes a light source 12, a light shielding unit 14, and a lens 16, and the light source 12, the light shielding unit 14, and the lens 16 are arranged in this order.

As illustrated in FIG. 5, the light shielding unit 14 has a base body 20 and a light shielding film 22.

In the light shielding film 22, a patterned opening portion 23 for radiating light emitted from the light source 12 into a specific shape is formed. A light distribution pattern radiated from the lens 16 is determined by the shape of the opening portion 23 of the light shielding film 22. The lens 16 projects light L from the light source 12, which has passed through the light shielding unit 14. In a case where a specific light distribution pattern can be radiated from the light source 12, the lens 16 is not necessarily required. The lens 16 is appropriately determined according to an irradiation distance and an irradiation range of the light L.

In addition, the configuration of the base body 20 is not particularly limited as long as the substrate can hold the light shielding film 22. However, the base body 20 is preferably not deformed by the heat of the light source 12, and it is, for example, made of glass.

An example of the light distribution pattern is illustrated in FIG. 5, which is not limited thereto.

In addition, the number of the light sources 12 is also not limited to one, and the light sources may be arranged, for example, in a row or in a matrix. In a case where a plurality of light sources are provided, for example, one light shielding unit 14 may be provided for one light source 12. In this case, the respective light shielding films 22 of a plurality of light shielding units 14 may all have the same pattern or may have different patterns.

The light distribution pattern based on the pattern of the light shielding film 22 will be described.

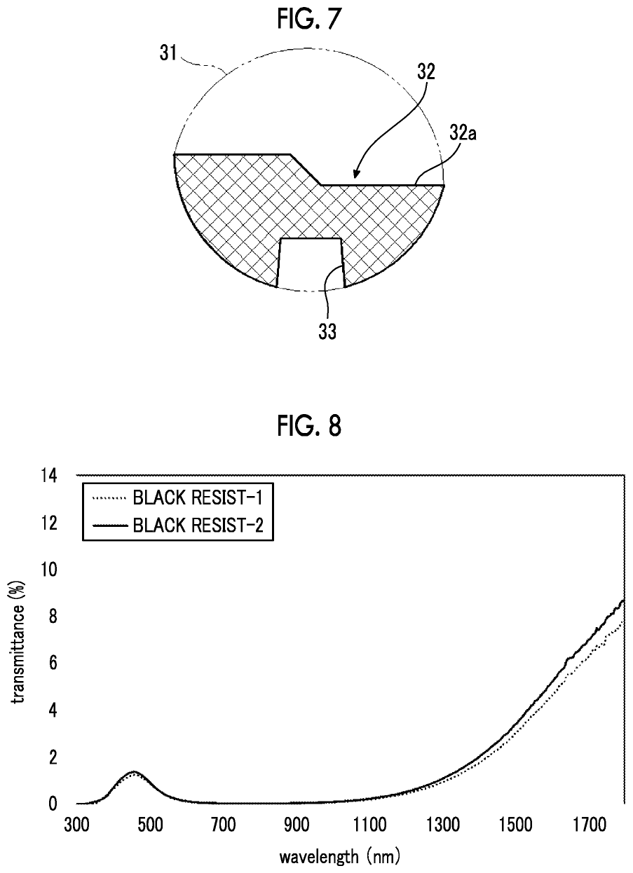

FIG. 6 is a schematic view illustrating an example of the light distribution pattern formed by the headlight unit, and FIG. 7 is a schematic view illustrating another example of the light distribution pattern formed by the headlight unit. It is noted that a light distribution pattern 30 illustrated in FIG. 6 and a light distribution pattern 32 illustrated in FIG. 7 both indicate a region irradiated with light. Further, a region 31 illustrated in FIG. 6 and a region 31 illustrated in FIG. 7 both indicate an irradiation region irradiated by the light source 12 (see FIG. 4) in a case where the light shielding film 22 is not provided.

Due to the pattern of the light shielding film 22, the intensity of light is sharply reduced at an edge 30a, for example, as in the light distribution pattern 30 illustrated in FIG. 6. The light distribution pattern 30 illustrated in FIG. 6 is, for example, a pattern in which light is not flashed at an oncoming vehicle in a case of left-side traveling.

In addition, as in the light distribution pattern 32 illustrated in FIG. 7, a pattern in which a part of the light distribution pattern 30 illustrated in FIG. 6 is notched can also be used. In this case as well, similar to the light distribution pattern 30 illustrated in FIG. 6, the intensity of light is sharply reduced at an edge 32a, and the pattern is, for example, a pattern in which light is not flashed at an oncoming vehicle in a case of left-side traveling. Further, the intensity of light is sharply reduced even at a notched portion 33. As a result, in a region corresponding to the notched portion 33, a mark indicating a state where the road is curved, inclined upward, inclined downward, or the like can be displayed. This makes it possible to improve the safety during night-time traveling.

In addition, the light shielding unit 14 is not limited to being fixedly disposed between the light source 12 and the lens 16, and a configuration in which the light shielding unit 14 is allowed to enter between the light source 12 and the lens 16, as necessary, by a driving mechanism (not shown) to obtain a specific light distribution pattern may be adopted.

In addition, in the light shielding unit 14, a shade member capable of shielding the light from the light source 12 may be formed. In this case, a configuration in which the shade member is allowed to enter between the light source 12 and the lens 16, as necessary, by the driving mechanism (not shown) to obtain a specific light distribution pattern may be adopted.

It is also preferable that the cured film according to the embodiment of the present invention is used as a light shielding film for fingerprint authentication. The light shielding film preferably has a plurality of pores (apertures) for allowing light to pass through. The pores may be filled with a material that allows light to pass through.

### EXAMPLES

Hereinafter, the present invention will be described in more detail based on Examples below. Materials, using amounts, proportions, treatment contents, treatment procedures, and the like shown in Examples below can be properly changed without departing from the gist of the present invention. Accordingly, the scope of the present invention shall not be restrictively interpreted by Examples shown below. The content in the table means a content based on the mass standard unless otherwise specified.

### Synthesis Example 1: Synthesis of Polysiloxane Compound (S-1)

A mixed solution of 30 parts by mass of a silane coupling agent (A-1) and 70 parts by mass of ethanol shown in Table 1 was stirred at room temperature, and 15 parts by mass of a 0.1% by mass nitric acid aqueous solution was added thereto over 1 hour, and then, stirring was carried out at 50° C. for 24 hours. The reaction solution was concentrated under reduced pressure with an evaporator to obtain 27 parts by mass of a polysiloxane compound (S-1).

### Synthesis Examples 2 to 25: Synthesis of Polysiloxane Compounds (S-2) to (S-25)

The same operation as in Synthesis Example 1 was carried out except that the silane coupling agent shown in Table 1 or Table 2 was used to obtain polysiloxane compounds (S-2) to (S-25). Table 3 shows the physical properties.

<Silane Coupling Agent>

In Tables 1 and 2, * in the group shown in column X represents the bonding position to * in the group shown in column Y. In addition, Me represents a methyl group, and Et represents an ethyl group.

TABLE 1

| Silane coupling agent | X | Y |
|---|---|---|
| (A-1) | 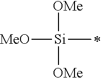 | *—CH═CH₂ |
| (A-2) | 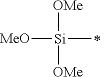 | *—CH₂—CH═CH₂ |
| (A-3) | 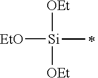 | 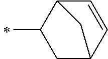 |
| (A-4) | 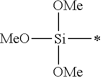 | 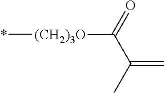 |
| (A-5) | 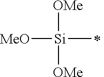 | 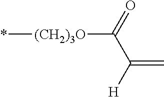 |
| (A-6) | 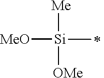 | 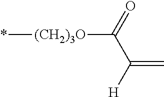 |
| (A-7) | 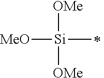 | 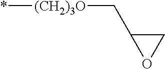 |
| (A-8) | 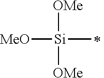 | *—(CH₂)₃NMe₂ |
| (A-9) | 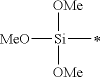 | *—(CH₂)₇CH₃ |
| (A-10) | 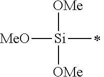 | *—(CH₂)₁₁CH₃ |
| (A-11) | 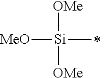 | *—(CH₂)₁₇CH₃ |
| (A-12) | 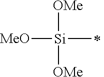 | 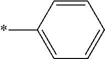 [SMILES: *c1ccccc1] |
| (A-13) | 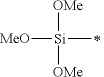 | 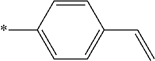 [SMILES: *c1ccc(C=C)cc1] |

TABLE 2

| Silane coupling agent | X | Y |
|---|---|---|
| (A-14) | 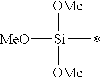 | 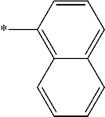 [SMILES: *c1cccc2ccccc12] |
| (A-15) | 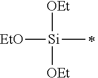 | 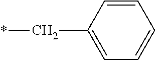 [SMILES: *Cc1ccccc1] |
| (A-16) | 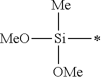 | *—CH₂CH₂CF₃ |
| (A-17) | 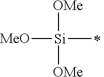 | *—CH₂CH₂(CF₂)₅CF₃ |
| (A-18) | 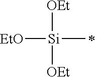 | *—CH₂CH₂(CF₂)₇CF₃ |
| (A-19) | 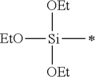 | 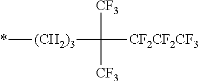 |
| (A-20) | 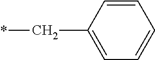 [SMILES: *Cc1ccccc1] | 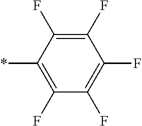 [SMILES: *c1c(F)c(F)c(F)c(F)c1F] |
| (A-21) | 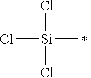 | 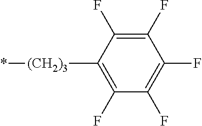 |
| (A-22) | 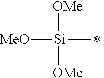 | 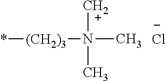 |
| (A-23) | 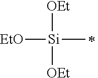 | *—(CH₂)₂—CN |
| (A-24) | 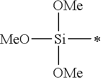 | *—(CH₂)₃—SH |
| (A-25) | 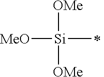 | 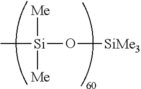 |

TABLE 3

| | | Silane coupling agent | | |
|---|---|---|---|---|
| Synthesis | | | Adding amount | |
| Example | Polysiloxane | Kind | (part by mass) | Mw |
| 1 | S-1 | A-1 | 30 | 600 |
| 2 | S-2 | A-2 | 30 | 900 |
| 3 | S-3 | A-3 | 30 | 800 |
| 4 | S-4 | A-4 | 30 | 1000 |
| 5 | S-5 | A-5 | 30 | 700 |
| 6 | S-6 | A-6 | 30 | 800 |
| 7 | S-7 | A-7 | 30 | 600 |
| 8 | S-8 | A-8 | 30 | 900 |
| 9 | S-9 | A-9 | 30 | 900 |
| 10 | S-10 | A-10 | 30 | 800 |
| 11 | S-11 | A-11 | 30 | 900 |
| 12 | S-12 | A-12 | 30 | 1100 |
| 13 | S-13 | A-13 | 30 | 1000 |
| 14 | S-14 | A-14 | 30 | 800 |
| 15 | S-15 | A-15 | 30 | 900 |
| 16 | S-16 | A-16 | 30 | 700 |
| 17 | S-17 | A-17 | 30 | 900 |
| 18 | S-18 | A-18 | 30 | 600 |
| 19 | S-19 | A-19 | 30 | 700 |
| 20 | S-20 | A-20 | 30 | 800 |
| 21 | S-21 | A-21 | 30 | 900 |
| 22 | S-22 | A-22 | 30 | 1200 |
| 23 | S-23 | A-23 | 30 | 800 |
| 24 | S-24 | A-24 | 30 | 1100 |
| 25 | S-25 | A-25 | 30 | 3500 |
| 26 | S-26 | A-4/A-25 | 10/20 | 2900 |

### Synthesis Example 27: Synthesis of Surface-Modified Particle (L-1)

1% by mass of a 1% by mass aqueous ammonia was added to a solution in which 100 parts by mass of a dispersion liquid (X-1) containing unmodified particles (a aqueous silica particle dispersion liquid (manufactured by Nissan Chemical Corporation, SNOWTEX ST-O-40, solid content concentration: 40% by mass)), 100 parts by mass of ethanol, and 2 parts by mass of a surface modifier (a silane coupling agent (A-1)) were mixed, and stirring was carried at 25° C. for 72 hours. The obtained solution was concentrated until the content thereof was 100 parts by mass. This solution was subjected to centrifugal separation (10,000 revolutions per minute), and a supernatant solution was discarded. 1,000 parts by mass of 1-methoxy-2-propanol was added to the precipitate, and centrifugal separation was carried out again to remove a supernatant solution. The obtained precipitate was dried at 50° C. for 24 hours under reduced pressure to obtain 39 parts by mass of surface-modified particles (L-1)

(Analysis of Residual Amount of Surface Modifier and Condensate (Polysiloxane) Thereof in Surface-Modified Particle)

1 part by mass of the obtained surface-modified particle (L-1) was added to 9 parts by mass of 1-methoxy-2-propanol and dispersed by ultrasonic waves for 1 hour. Then, a centrifugation operation was carried out, and the obtained supernatant solution was concentrated and observed by ²⁹Si nuclear magnetic resonance (NMR). As a result of the observation, the peak was below the detection limit (0.1% by mass).

### Synthesis Examples 27 to 60: Synthesis of Surface-Modified Particle (L-1) to (L-34)

The same operation as in Synthesis Example 1 was carried out except that the dispersion liquid containing unmodified particles and the surface modifier (the silane coupling agent) were changed to those shown in Table 4, whereby surface-modified particle (L-1) to (L-34) were synthesized. In the same manner as in the surface-modified particle (L-1), the residual amount analysis of the surface modifier and the condensate (the polysiloxane) thereof in each of the surface-modified particles was carried out, and as a result of the analysis, the peak was below the detection limit (0.1% by mass) in any case.

<Dispersion Liquid Containing Unmodified Particles>

X-1: A aqueous dispersion liquid of silica particles (SNOWTEX ST-O-40, manufactured by Nissan Chemical Corporation, solid content concentration: 40% by mass) X-2: An isopropanol dispersion liquid of silica particles (manufactured by Nissan Chemical Corporation, Organo silica sol IPA-STL, solid content concentration: 30% by mass) X-3: A Methanol dispersion liquid of titanium oxide particles obtained by the operation of Example 1 of WO2016/136764A (solid content concentration: 15% by mass) X-4: An aqueous dispersion liquid of zirconium oxide particles obtained by the operation of Example 1 of JP2010-150066A (solid content concentration: 5% by mass)

TABLE 4

| | Surface- | Unmodified | Surface modifier | |
|---|---|---|---|---|
| | modified | inorganic | | Adding |
| Synthesis | inorganic oxide | oxide | | amount |
| Example | particle | particle | Kind | (part by mass) |
| 27 | L-1 | X-1 | A-1 | 2 |
| 28 | L-2 | X-1 | A-2 | 3 |
| 29 | L-3 | X-1 | A-3 | 4 |
| 30 | L-4 | X-1 | A-4 | 1 |
| 31 | L-5 | X-1 | A-5 | 2 |
| 32 | L-6 | X-2 | A-6 | 3 |
| 33 | L-7 | X-1 | A-7 | 1 |
| 34 | L-8 | X-1 | A-8 | 2 |
| 35 | L-9 | X-1 | A-9 | 2 |
| 36 | L-10 | X-1 | A-10 | 3 |
| 37 | L-11 | X-2 | A-11 | 2 |
| 38 | L-12 | X-1 | A-12 | 1 |
| 39 | L-13 | X-1 | A-13 | 2 |
| 40 | L-14 | X-1 | A-14 | 2 |
| 41 | L-15 | X-1 | A-15 | 2 |
| 42 | L-16 | X-1 | A-16 | 1 |
| 43 | L-17 | X-2 | A-17 | 2 |
| 44 | L-18 | X-1 | A-18 | 3 |
| 45 | L-19 | X-1 | A-19 | 2 |
| 46 | L-20 | X-1 | A-20 | 1 |
| 47 | L-21 | X-1 | A-21 | 2 |
| 48 | L-22 | X-1 | A-22 | 2 |
| 49 | L-23 | X-1 | A-23 | 2 |
| 50 | L-24 | X-1 | A-24 | 4 |
| 51 | L-25 | X-2 | A-25 | 3 |
| 52 | L-26 | X-1 | A-4/A-25 | 2 |
| 53 | L-27 | X-2 | A-25 | 1 |
| 54 | L-28 | X-3 | A-16 | 1 |
| 55 | L-29 | X-4 | A-17 | 1 |
| 56 | L-30 | X-1 | S-11 | 3 |
| 57 | L-31 | X-1 | S-17 | 4 |
| 58 | L-32 | X-1 | S-22 | 2 |
| 59 | L-33 | X-1 | S-25 | 3 |
| 60 | L-34 | X-1 | S-26 | 4 |

### Synthesis Example 61: Synthesis of Unmodified Particles X-5 for Comparative Example

The same operation was carried out except that the silane coupling agent (A-1) was not added in Synthesis Example 27, whereby 38 parts by mass of unmodified particle X-5 was obtained.

### Examples 1-1 to 1-43 and Comparative Examples 1-1 to 1-3: Production and Evaluation of Dispersion Liquid of Surface-Modified Particles

15 parts by mass of the surface-modified particle (L-1), 100 parts by mass of dehydrated 1-methoxy-2-propanol, and polysiloxane (the kind and the adding amount are shown in Table 5) were added, and ultrasonic dispersion was carried out for 10 hours. The moisture content of the obtained dispersion liquid was measured, and water was added so that the moisture content thereof was adjusted to the moisture content in Table 5.

In Table 5, the polysiloxane content rate (the polysiloxane content) was calculated based on the following expression. The moisture content is in terms of % by mass of water with respect to the total mass of the dispersion liquid.

The polysiloxane content rate (%)=100×(the adding amount of polysiloxane)/{(the adding amount of surface-modified particles or unmodified particles)+(the adding amount of polysiloxane)}

<Evaluation of Storage Stability>

The obtained dispersion liquid was forcibly heated at 45° C. for 60 days, and the storage stability thereof was checked by viscosity measurement. The viscosity of the dispersion liquid was measured using a viscometer (a TV-22 type viscometer, cone plate type, manufactured by TOM SANGYO Co., Ltd.). The viscosity of the dispersion liquid was measured by adjusting the temperature of the dispersion liquid to 25° C.

A: The rate of change in viscosity of the dispersion liquid is less than 2%.

B: The rate of change in viscosity of the dispersion liquid is 2% or more and less than 5%.

C: The rate of change in viscosity of the dispersion liquid is 5% or more and less than 8%.

D: The rate of change in viscosity of the dispersion liquid is 8% or more and less than 10%.

E: The rate of change in viscosity of the dispersion liquid is 10% or more.

TABLE 5

| | | Surface-modified | | | | | |
|---|---|---|---|---|---|---|---|
| | | inorganic oxide | Polysiloxane | | | | |
| | Dispersion | particle or Unmodified | | Adding amount | Content | Moisture | Storage |
| | liquid | inorganic oxide particle | Kind | part by mass | rate % | content % | stability |
| Example 1-1 | D-1 | L-1 | S-1 | 5.0 | 25.0 | 2.2 | A |
| Example 1-2 | D-2 | L-2 | S-2 | 2.2 | 13.0 | 2.7 | A |
| Example 1-3 | D-3 | L-3 | S-3 | 1.7 | 10.0 | 2.9 | A |
| Example 1-4 | D-4 | L-4 | S-4 | 0.2 | 1.0 | 2.7 | A |
| Example 1-5 | D-5 | L-5 | S-5 | 3.8 | 20.0 | 2.8 | A |
| Example 1-6 | D-6 | L-6 | S-6 | 4.0 | 21.0 | 1.2 | A |
| Example 1-7 | D-7 | L-7 | S-7 | 0.8 | 5.0 | 2.5 | A |
| Example 1-8 | D-8 | L-8 | S-8 | 4.0 | 21.0 | 1.4 | A |
| Example 1-9 | D-9 | L-9 | S-9 | 0.2 | 1.0 | 2.8 | A |
| Example 1-10 | D-10 | L-10 | S-10 | 4.0 | 21.0 | 1.9 | A |
| Example 1-11 | D-11 | L-11 | S-11 | 1.9 | 11.0 | 0.9 | A |
| Example 1-12 | D-12 | L-12 | S-12 | 1.9 | 11.0 | 2.5 | A |
| Example 1-13 | D-13 | L-13 | S-13 | 4.7 | 24.0 | 1.3 | A |
| Example 1-14 | D-14 | L-14 | S-14 | 3.8 | 20.0 | 2.3 | A |
| Example 1-15 | D-15 | L-15 | S-15 | 3.3 | 18.0 | 2.6 | A |
| Example 1-16 | D-16 | L-16 | S-16 | 4.2 | 22.0 | 2.5 | A |
| Example 1-17 | D-17 | L-17 | S-17 | 1.7 | 10.0 | 2.1 | A |
| Example 1-18 | D-18 | L-18 | S-18 | 2.2 | 13.0 | 0.7 | A |
| Example 1-19 | D-19 | L-19 | S-19 | 0.8 | 5.0 | 2.5 | A |
| Example 1-20 | D-20 | L-20 | S-20 | 5.0 | 25.0 | 2.8 | A |
| Example 1-21 | D-21 | L-21 | S-21 | 2.4 | 14.0 | 2.9 | A |
| Example 1-22 | D-22 | L-22 | S-22 | 4.5 | 23.0 | 2.8 | A |
| Example 1-23 | D-23 | L-23 | S-23 | 5.0 | 25.0 | 2.7 | A |
| Example 1-24 | D-24 | L-24 | S-24 | 3.8 | 20.0 | 1.9 | A |
| Example 1-25 | D-25 | L-25 | S-25 | 4.2 | 22.0 | 0.5 | A |
| Example 1-26 | D-26 | L-26 | S-26 | 4.7 | 24.0 | 2.8 | A |
| Example 1-27 | D-27 | L-27 | S-25 | 3.8 | 20.0 | 0.1 | A |
| Example 1-28 | D-28 | L-28 | S-16 | 0.6 | 4.0 | 1.2 | A |
| Example 1-29 | D-29 | L-29 | S-17 | 4.5 | 23.0 | 2.9 | A |
| Example 1-30 | D-30 | L-30 | S-11 | 0.3 | 2.0 | 0.2 | A |
| Example 1-31 | D-31 | L-31 | S-17 | 0.2 | 1.2 | 0.1 | A |
| Example 1-32 | D-32 | L-32 | S-22 | 0.2 | 1.0 | 1.4 | A |
| Example 1-33 | D-33 | L-33 | S-25 | 4.2 | 22.0 | 2.4 | A |
| Example 1-34 | D-34 | L-34 | S-26 | 1.7 | 10.0 | 1.0 | A |
| Example 1-35 | D-35 | L-16 | S-12 | 4.7 | 24.0 | 2.1 | B |
| Example 1-36 | D-36 | L-16 | S-13 | 0.2 | 1.1 | 2.3 | B |
| Example 1-37 | D-37 | L-16 | S-16 | 6.4 | 30.0 | 1.2 | B |
| Example 1-38 | D-38 | L-16 | S-16 | 0.1 | 0.5 | 2.9 | B |
| Example 1-39 | D-39 | L-16 | S-16 | 2.1 | 12.1 | 5.5 | B |
| Example 1-40 | D-40 | L-16 | S-16 | 2.0 | 11.9 | 0.005 | B |
| Example 1-41 | D-41 | L-16 | S-16 | 2.5 | 30.0 | 5.9 | C |
| Example 1-42 | D-42 | L-16 | S-12 | 2.3 | 30.0 | 1.3 | C |
| Example 1-43 | D-43 | L-16 | S-12 | 1.2 | 30.0 | 5.5 | D |
| Comparative | D-44 | L-16 | S-16 | 10.0 | 40.0 | 2.1 | E |
| Example 1-1 | | | | | | | |
| Comparative | D-45 | L-16 | — | — | — | 1.2 | E |
| Example 1-2 | | | | | | | |
| Comparative | D-46 | X-5 | S-16 | 5.0 | 25.0 | 1.3 | E |
| Example 1-3 | | | | | | | |

As shown in Table 5, all the dispersion liquids containing the surface-modified particles and the polysiloxane in the present invention and having a polysiloxane content rate of 1% to 39% by mass were excellent in storage stability (Examples).

From the comparison between Examples 1-16 and Examples 1-35 as well as 1-36, it was shown that in a case where the group contained in the modified moiety of the surface-modified particle (that is, R^{A1} of Formula A1 or R^{A2} of Formula A2) and the functional group contained in the unit that constitutes siloxane (that is, R^{B1} of Formula B1 or R^{B2} of Formula B2) are the same (Example 1-16), the storage stability is better.

From the comparison between Examples 1-16 and Examples 1-37 as well as 1-38, it was shown that in a case where the polysiloxane content rate is in a range of 1% to 25% by mass (Example 1-16), the storage stability is more excellent. In addition, it was confirmed that the same tendency was also obtained from the comparison between Example 1-39 and Example 1-41 and the comparison between Example 1-35 and Example 1-42.

From the comparison between Examples 1-16 and Examples 1-39 as well as 1-40, it was shown that in a case where the moisture content is in a range of 0.1% to 3% by mass (Example 1-16), the storage stability is more excellent. Further, it was confirmed that the same tendency was also obtained from the comparison between Example 1-42 and Example 1-43.

On the other hand, it was shown that in a case where the polysiloxane content rate exceeds 39% by mass (Comparative Example 1-1), in a case where polysiloxane is not contained (Comparative Example 1-2), and in a case where unmodified particles are used (Comparative Example 1-3), the storage stability is inferior.

### Examples 2-1 to 2-43 and Comparative Examples 2-1 to 2-3: Preparation of Curable Composition

The following components were mixed to prepare a curable composition. With regard to the dispersion liquid, the polymerizable compound, and the resin, the components shown in Table 6 were used.
Dispersion liquid: 100 parts by mass
Polymerizable compound: 10 parts by mass
Resin: 5 parts by mass
Thermal polymerization initiator (tert-butyl peroxybenzoate): 1 part by mass
Surfactant W1 (the following structure): 1 part by mass

<Resin>

b1: A resin having the following structure (the numerical value noted to the main chain is in terms of molar ratio, Mw=30,000)

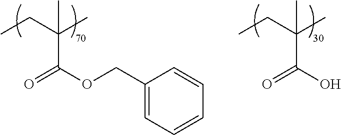

b2: A resin having the following structure (the numerical value noted to the main chain is in terms of molar ratio, Mw: 11,000)

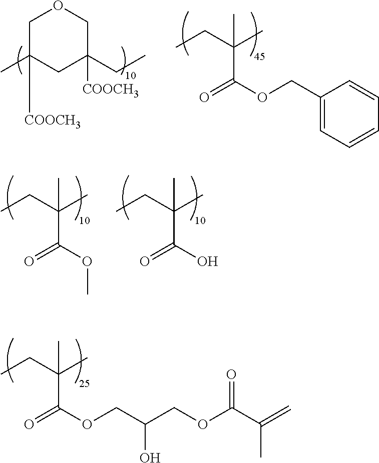

b3: A resin having the following structure (the numerical value noted to the main chain is in terms of molar ratio, Mw: 10,000)

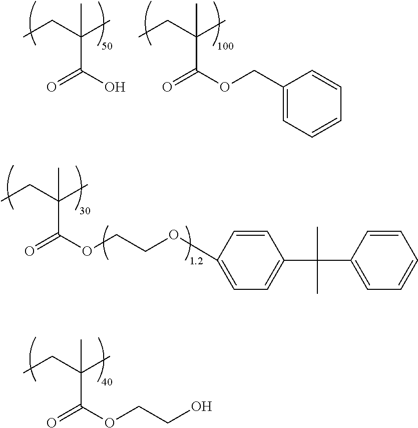

(Polymerizable Compound)

M-1: KAYARAD DPHA (manufactured by Nippon Kayaku Co., Ltd.)

M-2: NK ESTER A-DPH-12E (manufactured by SHIN-NAKAMURA CHEMICAL Co., Ltd.)

M-3: NK ESTER A-TMMT (manufactured by SHIN-NAKAMURA CHEMICAL Co., Ltd.).

M-4: Succinic acid-modified dipentaerythritol pentaacrylate M-5: Dipentaerythritol hexaacrylate

(Surfactant)

Surfactant W1: A propylene glycol monomethyl ether acetate (PGMEA) solution of 1% by mass of the following compound (the proportion of the repeating unit means a value in terms of % by mole, Mw: 14,000)

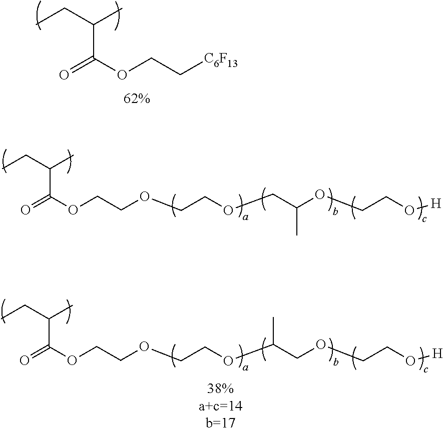

<Evaluation of Storage Stability>

The storage stability of the curable composition was evaluated according to the same procedure and evaluation standards as in the above-described evaluation of the storage stability using the dispersion liquid described except that the curable composition obtained as described above was used.

TABLE 6

| | Curable | Dispersion | Polymerizable | | Storage |
|---|---|---|---|---|---|
| | composition | liquid | compound | Resin | stability |
| Example 2-1 | E-1 | D-1 | M-1 | b1 | A |
| Example 2-2 | E-2 | D-2 | M-1 | b1 | A |
| Example 2-3 | E-3 | D-3 | M-1 | b2 | A |
| Example 2-4 | E-4 | D-4 | M-1 | b1 | A |
| Example 2-5 | E-5 | D-5 | M-2 | b1 | A |
| Example 2-6 | E-6 | D-6 | M-1 | b2 | A |
| Example 2-7 | E-7 | D-7 | M-1 | b1 | A |
| Example 2-8 | E-8 | D-8 | M-4 | b1 | A |
| Example 2-9 | E-9 | D-9 | M-1 | b1 | A |
| Example 2-10 | E-10 | D-10 | M-1 | b1 | A |
| Example 2-11 | E-11 | D-11 | M-3 | b1 | A |
| Example 2-12 | E-12 | D-12 | M-1 | b3 | A |
| Example 2-13 | E-13 | D-13 | M-1 | b3 | A |
| Example 2-14 | E-14 | D-14 | M-1 | b1 | A |
| Example 2-15 | E-15 | D-15 | M-1 | b1 | A |
| Example 2-16 | E-16 | D-16 | M-1 | b2 | A |
| Example 2-17 | E-17 | D-17 | M-1 | b1 | A |
| Example 2-18 | E-18 | D-18 | M-5 | b1 | A |
| Example 2-19 | E-19 | D-19 | M-1 | b1 | A |
| Example 2-20 | E-20 | D-20 | M-1 | b1 | A |
| Example 2-21 | E-21 | D-21 | M-1 | b1 | A |
| Example 2-22 | E-22 | D-22 | M-1 | b1 | A |
| Example 2-23 | E-23 | D-23 | M-1 | b1 | A |
| Example 2-24 | E-24 | D-24 | M-1 | b1 | A |
| Example 2-25 | E-25 | D-25 | M-1 | b1 | A |
| Example 2-26 | E-26 | D-26 | M-1 | b1 | A |
| Example 2-27 | E-27 | D-27 | M-1 | b1 | A |
| Example 2-28 | E-28 | D-28 | M-1 | b1 | A |
| Example 2-29 | E-29 | D-29 | M-1 | b1 | A |
| Example 2-30 | E-30 | D-30 | M-1 | b1 | A |
| Example 2-31 | E-31 | D-31 | M-1 | b1 | A |
| Example 2-32 | E-32 | D-32 | M-1 | b1 | A |
| Example 2-33 | E-33 | D-33 | M-1 | b1 | A |
| Example 2-34 | E-34 | D-34 | M-1 | b1 | A |
| Example 2-35 | E-35 | D-35 | M-1 | b2 | B |
| Example 2-36 | E-36 | D-36 | M-1 | b2 | B |
| Example 2-37 | E-37 | D-37 | M-1 | b2 | B |
| Example 2-38 | E-38 | D-38 | M-1 | b2 | B |
| Example 2-39 | E-39 | D-39 | M-1 | b2 | B |
| Example 2-40 | E-40 | D-40 | M-1 | b2 | B |
| Example 2-41 | E-41 | D-41 | M-1 | b2 | C |
| Example 2-42 | E-42 | D-42 | M-1 | b2 | C |
| Example 2-43 | E-43 | D-43 | M-1 | b2 | D |
| Comparative | E-44 | D-44 | M-1 | b1 | E |
| Example 2-1 | | | | | |
| Comparative | E-45 | D-45 | M-1 | b1 | E |
| Example 2-2 | | | | | |
| Comparative | E-46 | D-46 | M-1 | b1 | E |
| Example 2-3 | | | | | |

As shown in Table 6, it could be confirmed that from the evaluation results of the storage stability of the curable composition, the same tendency as that obtained from the above-described dispersion liquid is shown.

<Evaluation of Cured Film>

A CT-4000L solution (manufactured by Fujifilm Electronic Materials Co., Ltd.; a transparent base coat agent) was applied onto a glass substrate of 10 cm×10 cm so that the thickness of the film to be dried was 0.1 μm, and dried to form a transparent film, and the heating treatment was performed at 220° C. for 5 minutes.

Next, a curable composition (E-1) was applied by a spin coating method so that the film thickness after pre-baking was 0.6 μm. Next, pre-baking was carried out using a hot plate at 100° C. for 2 minutes, and then post-baking was carried out at 200° C. for 3 minutes.

The surface shape of the obtained cured film was good, and no haze could be confirmed. In addition, when the peeling test (in which the evaluation was executed by attaching a Cellophane tape (NICHIBAN Co., Ltd., registered trade name to the film and then peeling off it) was carried out, no peeling or chipping was observed in the cured film, and thus it was confirmed that a tough film is formed.

In a case the curable compositions (E-2) to (E-34) were subjected to the same operation and valuation, similar tough films were obtained. In particular, the cured films of (E-16) to (E-19), (E-25) to (E-29), (E-31), (E-33), and (E-34), which had a fluoroalkyl group or a polysiloxane structure, had a smooth and good film surface shape after the tape was peeled off.

On the other hand, when curable compositions (E-35) to (E-43) were used, a part of the cured film was chipped or peeled off in the peeling test although a cured film having a good surface shape was obtained.

Further, in the curable compositions (E-44) to (E-46) of Comparative Examples, the haze was observed in the surface shape of the coating film, and the much occurrence of peeling and chipping of the cured film was observed in the peeling test as compared with the case where the curable compositions (E-35) to (E-43) were used.

### Examples 3-1 to 3-47 and Comparative Examples 3-1 to 3-3: Preparation of Coloring Composition

<Preparation of Pigment Dispersion Liquid>

A mixed solution in which each kind of dispersion resin, pigment, pigment derivative, solvent shown in Table 7 below was mixed at the proportion shown in Table 7 below was mixed and dispersed for 3 hours using a beads mill (zirconia bead diameter: 0.3 mm) to prepare a dispersion liquid. Then, the mixture was further subjected to a dispersion treatment at a flow rate of 500 g/min under a pressure of 2,000 kg/cm³ using a high-pressure disperser equipped with a pressure reducing mechanism, NANO-3000-10 (manufactured by Beryu Co., Ltd.). The dispersion treatment was repeated 10 times to obtain each pigment dispersion liquid.

TABLE 7

| | Pigment | | Pigment derivative | | Dispersion resin | | Solvent | |
|---|---|---|---|---|---|---|---|---|
| | | Adding | | Adding | | Adding | | Adding |
| Pigment | | amount | | amount | | amount | | amount |
| dispersion | | (part by | | (part by | | (part by | | (part by |
| liquid | Kind | mass) | Kind | mass) | Kind | mass) | Kind | mass) |
| DP-1 | PB15:6/PV23 | 10/5 | SY-1 | 1 | DPB-1 | 20 | PGMEA | 65 |
| DP-2 | PR254/PY139 | 10/5 | SY-3 | 1 | DPB-2 | 20 | PGMEA | 65 |
| DP-3 | PG36/PY185 | 10/5 | SY-2 | 1 | DPB-3 | 20 | PGMEA | 65 |
| DP-4 | PB 15:6 | 15 | SY-1 | 1 | DPB-1 | 20 | PGMEA | 65 |
| DP-5 | PR122 | 15 | SY-5 | 1 | DPB-2 | 20 | Cyclopentane | 65 |
| DP-6 | PY150 | 15 | SY-2 | 1 | DPB-3 | 20 | PGMEA | 65 |
| DP-7 | Titanium | 15 | — | — | DPB-1 | 20 | PGMEA | 65 |
| | oxynitride | | | | | | | |
| DP-8 | Titanium | 15 | — | — | DPB-1 | 20 | PGMEA | 65 |
| | nitride | | | | | | | |
| DP-9 | Carbon black | 15 | — | — | DPB-1 | 20 | PGMEA/PGME | 50/15 |
| DP-10 | Titanium | 15 | — | — | DPB-1 | 20 | PGMEA | 65 |
| | oxide | | | | | | | |

(Dispersion Resin)
DPB-1: The following compound (solid content: 30% by mass, a PGMEA solution, Mw: 16,000)
DPB-2: The following compound (solid content: 30% by mass, a PGMEA solution, Mw: 8,000)
DPB-3: The following compound (solid content: 30% by mass, a PGMEA solution, Mw: 15,000)

In the following formula, Me represents a methyl group, and Bu represents a butyl group.

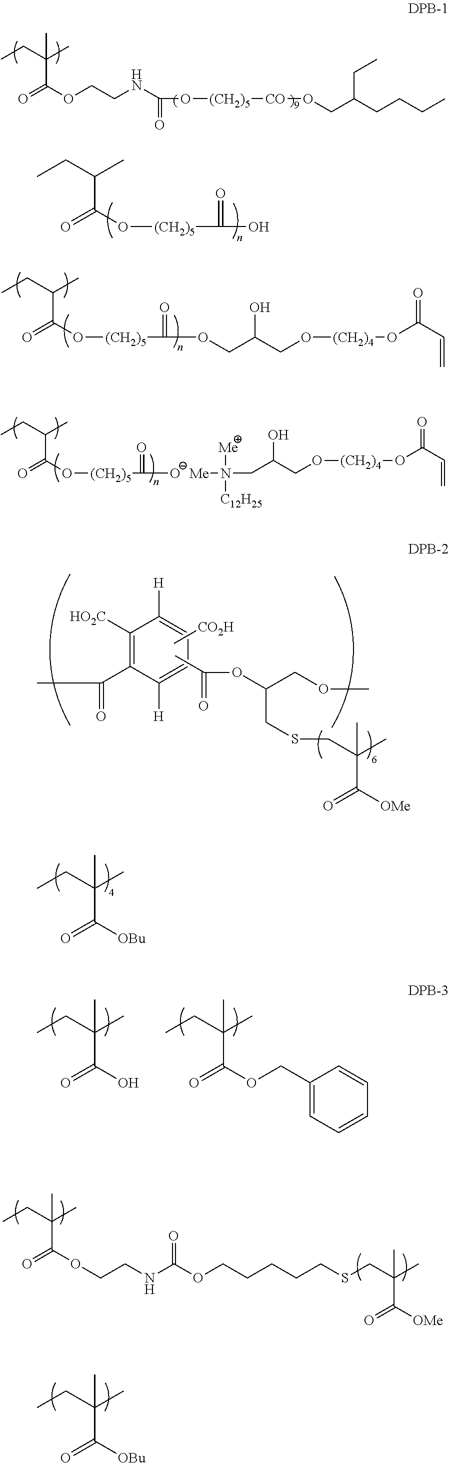

(Pigment Derivative)

The following compounds

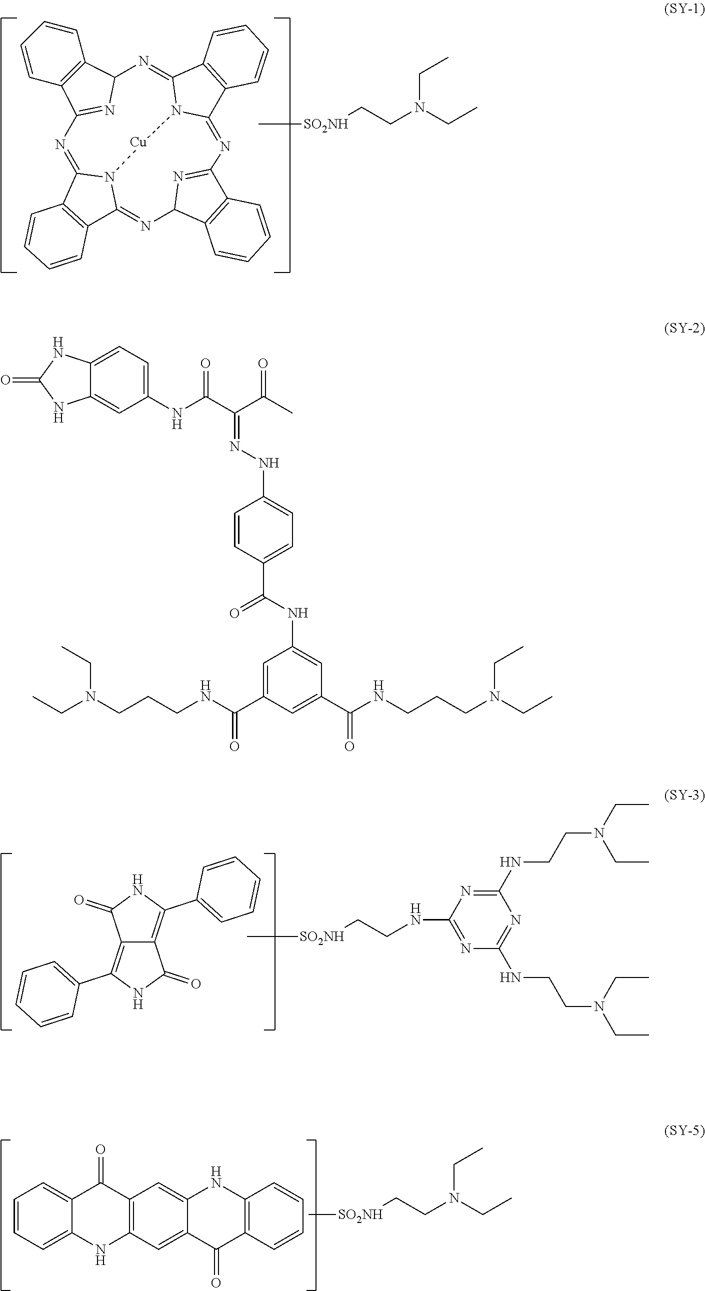

(Solvent)
Propylene glycol monomethyl ether acetate (PGMEA)
Cyclopentanone
Propylene glycol monomethyl ether (PGME)

<Preparation of Coloring Composition>

The following components were mixed to prepare a coloring composition. Components shown in Table 8 were used for the dispersion liquid, the pigment dispersion liquid, the resin, the polymerizable compound, and the photopolymerization initiator.
Dispersion liquid: 10 parts by mass
Pigment dispersion liquid: 100 parts by mass
Resin: an amount shown in Table 8
Polymerizable compound: an amount listed in Table 8
Photopolymerization initiator: an amount shown in Table 8
Surfactant W1: 1 part by mass
p-methoxyphenol: 0.01 parts by mass

(Photopolymerization Initiator)

The following compounds (in the formulae, Me represents a methyl group, and Ph represents a phenyl group)

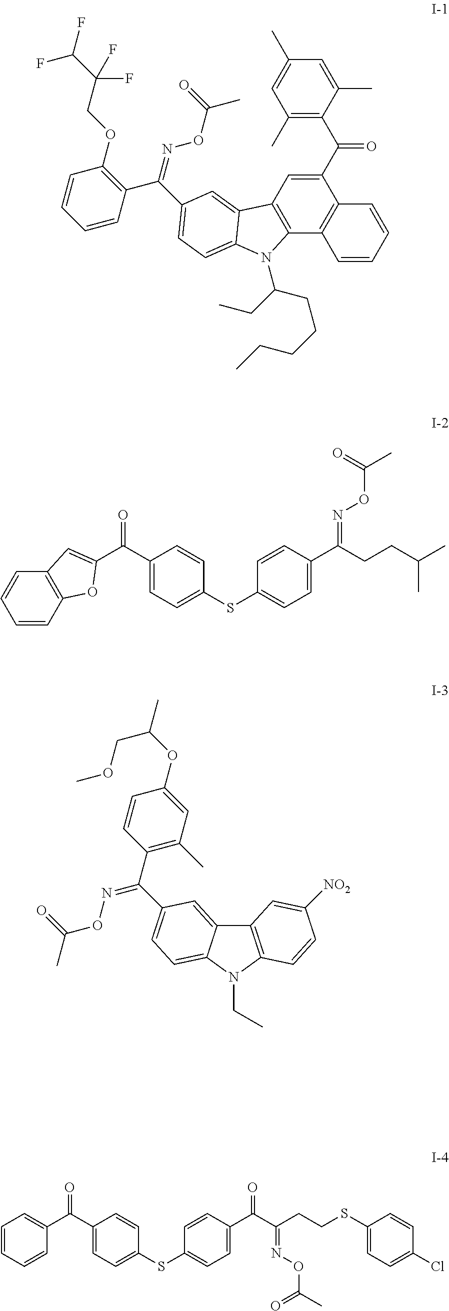 [SMILES: CCCCCC(CC)n1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\CCC(C)C)c1ccc(Sc2ccc(C(=O)c3cc4ccccc4o3)cc2)cc1 ; CCn1c2ccc(/C(=N\OC(C)=O)c3ccc(OC(C)COC)cc3C)cc2c2cc([N+](=O)[O-])ccc21 ; CC(=O)O/N=C(\CCSc1ccc(Cl)cc1)C(=O)c1ccc(Sc2ccc(C(=O)c3ccccc3)cc2)cc1]

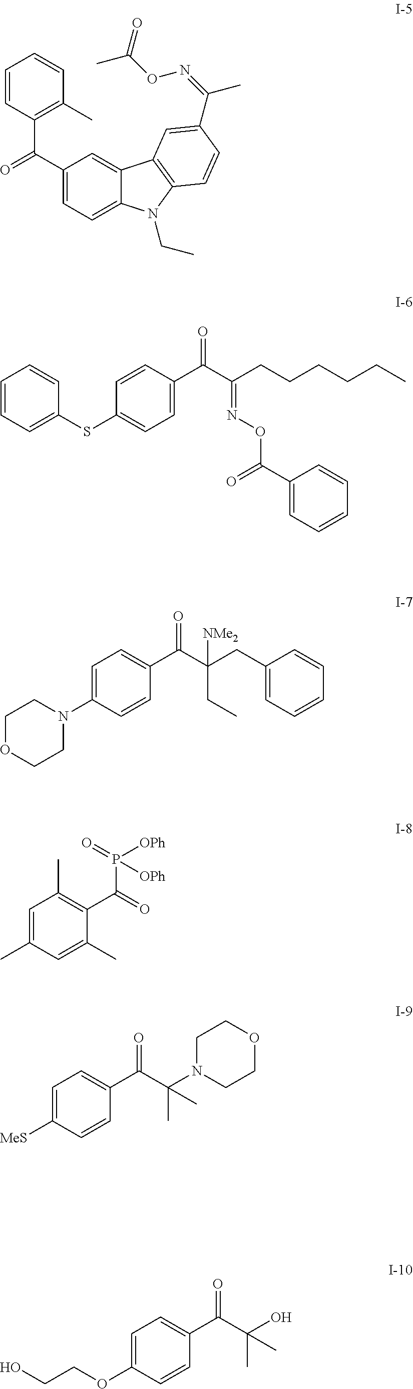

<Evaluation of Storage Stability>

The storage stability of the curable composition was evaluated according to the same procedure and evaluation standards as in the above-described evaluation of the storage stability using the dispersion liquid described except that the coloring composition obtained as described above was used.

TABLE 8

| | | | | | | Polymerizable | | Photopolymerization | | |
|---|---|---|---|---|---|---|---|---|---|---|
| | | | | Resin | | compound | | initiator | | |
| | | | | | Adding | | Adding | | Adding | |
| | | | Pigment | | amount | | amount | | amount | |
| | Coloring | Dispersion | dispersion | | part by | | part by | | part by | Storage |
| | composition | liquid | liquid | Kind | mass | Kind | mass | Kind | mass | stability |
| Example 3-1 | F-1 | D-1 | DP-1 | b2 | 2 | M1 | 1 | I-1 | 1 | A |
| Example 3-2 | F-2 | D-2 | DP-2 | b2 | 2 | M1 | 1 | I-2 | 1 | A |
| Example 3-3 | F-3 | D-3 | DP-3 | b2 | 1 | M2 | 2 | I-3 | 1 | A |
| Example 3-4 | F-4 | D-4 | DP-4 | b2 | 2 | M1 | 1 | I-4 | 1 | A |
| Example 3-5 | F-5 | D-5 | DP-5 | b1 | 3 | M1 | 1 | I-5 | 1 | A |
| Example 3-6 | F-6 | D-6 | DP-7 | b2 | 2 | M3 | 1 | I-6 | 1 | A |
| Example 3-7 | F-7 | D-7 | DP-6 | b2 | 1 | M5 | 1 | I-1/I-3 | 0.5/0.5 | A |
| Example 3-8 | F-8 | D-8 | DP-8 | b2 | 4 | M1 | 1 | I-1/I-3 | 0.5/0.5 | A |
| Example 3-9 | F-9 | D-9 | DP-9 | b2 | 2 | M1 | 1 | I-1 | 1 | A |
| Example 3-10 | F-10 | D-10 | DP-7 | b2 | 2 | M4 | 2 | I-1 | 1 | A |
| Example 3-11 | F-11 | D-11 | DP-7 | b2 | 2 | M1 | 1 | I-1 | 1 | A |
| Example 3-12 | F-12 | D-12 | DP-6 | b3 | 2 | M1 | 3 | I-1 | 1 | A |
| Example 3-13 | F-13 | D-13 | DP-7 | b2 | 2 | M1/M2 | 1/1 | I-1 | 1 | A |
| Example 3-14 | F-14 | D-14 | DP-7 | b2 | 2 | M1 | 1 | I-1 | 1 | A |
| Example 3-15 | F-15 | D-15 | DP-7 | b2 | 2 | M1 | 1 | I-1/I-10 | 0.8/0.2 | A |
| Example 3-16 | F-16 | D-16 | DP-7 | b1/b2 | 1/1 | M1 | 1 | I-1 | 1 | A |
| Example 3-17 | F-17 | D-17 | DP-2 | b2 | 2 | M1 | 1 | I-1 | 1 | A |
| Example 3-18 | F-18 | D-18 | DP-7 | b2 | 2 | M1 | 1 | I-1 | 1 | A |
| Example 3-19 | F-19 | D-19 | DP-10 | b2 | 2 | M1 | 1 | I-1 | 1 | A |
| Example 3-20 | F-20 | D-20 | DP-7 | b2 | 2 | M1 | 1 | I-1 | 1 | A |
| Example 3-21 | F-21 | D-21 | DP-7 | b2 | 2 | M1 | 1 | I-1 | 1 | A |
| Example 3-22 | F-22 | D-22 | DP-7 | b2 | 2 | M1 | 1 | I-1 | 1 | A |
| Example 3-23 | F-23 | D-23 | DP-8 | b2 | 2 | M1 | 1 | I-1 | 1 | A |
| Example 3-24 | F-24 | D-24 | DP-7 | b2 | 2 | M1 | 1 | I-1 | 1 | A |
| Example 3-25 | F-25 | D-25 | DP-4 | b2 | 2 | M1 | 1 | I-1 | 1 | A |
| Example 3-26 | F-26 | D-26 | DP-7 | b2 | 2 | M1 | 1 | I-1 | 1 | A |
| Example 3-27 | F-27 | D-27 | DP-2 | b2 | 2 | M1 | 1 | I-1 | 1 | A |
| Example 3-28 | F-28 | D-28 | DP-3 | b2 | 2 | M1 | 1 | I-1 | 1 | A |
| Example 3-29 | F-29 | D-29 | DP-7 | b2 | 2 | M1 | 1 | I-1 | 1 | A |
| Example 3-30 | F-30 | D-30 | DP-7 | b2 | 2 | M1 | 1 | I-1 | 1 | A |
| Example 3-31 | F-31 | D-31 | DP-7 | b2 | 2 | M1 | 1 | I-1 | 1 | A |
| Example 3-32 | F-32 | D-32 | DP-7 | b2 | 2 | M1 | 1 | I-1 | 1 | A |
| Example 3-33 | F-33 | D-33 | DP-7 | b2 | 2 | M1 | 1 | I-1 | 1 | A |
| Example 3-34 | F-34 | D-34 | DP-7 | b2 | 2 | M1 | 1 | I-1 | 1 | A |
| Example 3-35 | F-35 | D-15 | DP-6 | b2 | 2 | M1 | 1 | I-7 | 1 | A |
| Example 3-36 | F-36 | D-23 | DP-7 | b2 | 2 | M1 | 1 | I-8 | 1 | A |
| Example 3-37 | F-37 | D-9 | DP-1 | b2 | 2 | M1 | 1 | I-9 | 1 | A |
| Example 3-38 | F-38 | D-1 | DP-6 | b2 | 2 | M1 | 1 | I-10 | 1 | A |
| Example 3-39 | F-39 | D-35 | DP-7 | b1/b2 | 1/1 | M1 | 1 | I-1 | 1 | B |
| Example 3-40 | F-40 | D-36 | DP-7 | b1/b2 | 1/1 | M1 | 1 | I-1 | 1 | B |
| Example 3-41 | F-41 | D-37 | DP-7 | b1/b2 | 1/1 | M1 | 1 | I-1 | 1 | B |
| Example 3-42 | F-42 | D-38 | DP-7 | b1/b2 | 1/1 | M1 | 1 | I-1 | 1 | B |
| Example 3-43 | F-43 | D-39 | DP-7 | b1/b2 | 1/1 | M1 | 1 | I-1 | 1 | B |
| Example 3-44 | F-44 | D-40 | DP-7 | b1/b2 | 1/1 | M1 | 1 | I-1 | 1 | B |
| Example 3-45 | F-45 | D-41 | DP-7 | b1/b2 | 1/1 | M1 | 1 | I-1 | 1 | C |
| Example 3-46 | F-46 | D-42 | DP-7 | b1/b2 | 1/1 | M1 | 1 | I-1 | 1 | C |
| Example 3-47 | F-47 | D-43 | DP-7 | b1/b2 | 1/1 | M1 | 1 | I-1 | 1 | D |
| Comparative | F-48 | D-44 | DP-9 | b2 | 2 | M1 | 1 | I-9 | 1 | E |
| Example 3-1 | | | | | | | | | | |
| Comparative | F-49 | D-45 | DP-9 | b2 | 2 | M1 | 1 | I-9 | 1 | E |
| Example 3-2 | | | | | | | | | | |
| Comparative | F-50 | D-46 | DP-9 | b2 | 2 | M1 | 1 | I-9 | 1 | E |
| Example 3-3 | | | | | | | | | | |

As shown in Table 8, it could be confirmed that from the evaluation results of the storage stability of the coloring composition, the same tendency as that obtained from the above-described dispersion liquid is shown. Even in a case where the pigment was changed from titanium oxynitride to zirconium nitride in Example 3-16, the same results as in Example 3-16 were obtained.

<Evaluation of Patterned Cured Film>

A CT-4000L solution (manufactured by FUJIFILM Electronic Materials Co., Ltd.; transparent base coat agent) was applied to a silicon wafer so that the thickness of the film to be dried was 0.1 μm, and dried to form a transparent film, and the heating treatment was carried out at 220° C. for 5 minutes.

Next, a curable composition (F-1) was applied by a spin coating method so that the film thickness after pre-baking was 0.6 μm. Next, pre-baking was carried out using a hot plate at 100° C. for 2 minutes.

Next, using an i-line stepper exposure device FPA-3000 i5+ (manufactured by Canon Inc.), the composition layer was exposed at an exposure amount of 500 mJ/cm² with light having a wavelength of 365 nm through a mask pattern in which each of the square pixels of which one side was 2.0 μm was arranged on the substrate in a region of 4 mm×3 mm. Next, the composition layer after exposure was placed on a horizontal rotary table of a spin shower developing machine (DW-30 type, manufactured by Chemitronics Co., Ltd.) and subjected to a puddle development at 23° C. for 60 seconds using CD-2000 (manufactured by FUJIFILM Electronic Materials Co., Ltd.), a rinse treatment was carried out by supplying pure water from a jet nozzle from above the rotation center in a shower-like manner while rotating the silicon wafer substrate at a rotation speed of 50 rpm by a rotating device, and then spraying and drying were carried out. The obtained pattern shape was good and there was no pattern defect.

As a result of subjecting the compositions (F-2) to (F-50) to the same evaluation, a good pattern similar to that from (F-2) was obtained from each of the compositions (F-2) to (F-34) and (F-39) to (F-47).

On the other hand, in (F-35) to (F-38) and (F-48) to (F-50) in which a non-oxime-based initiator was used as the photopolymerization initiator, defects were confirmed in a part of the pattern.

Further, in (F-48) to (F-50), relatively more pattern defects were observed than in the case of using the coloring compositions (F-35) to (F-38), and the level of pattern defects was practically problematic.

It was seen that among the coloring compositions, particularly the compositions (F-16) to (F-19), (F-25) to (F-27), (F-31), (F-33), and (F-34), which contain a group having a fluoroalkyl group or a polysiloxane structure and in which unmodified particles are silica, have a specifically lower reflectance than other cured films and thus are useful.

<Evaluation of Light Transmittance and Reflectance>

SK-9010 (product name) and SK-7000 (product name), which are black resist materials manufactured by FUJIFILM Electronic Materials Co., Ltd., and a dispersion liquid D-25 of Example 1-25 were mixed as described in Table 9 to obtain black resist-1 to black resist-4.

TABLE 9

| | Black coloring | | Dispersion liquid of | |
|---|---|---|---|---|
| | material | | surface-modified particle | |
| | Kind | Content | Kind | Content |
| Black resist-1 | SK-9010 | 100 g | — | 0 g |
| Black resist-2 | SK-9010 | 100 g | D-25 | 13 g |
| Black resist-3 | SK-7000 | 100 g | — | 0 g |
| Black resist-4 | SK-7000 | 100 g | D-25 | 13 g |

Each of the black resist-1 to the black resist-4 was applied onto a glass substrate of 10 cm×10 cm by adjusting the rotation speed so that the film thickness shown in Table 10 was obtained, and heating treatment (pre-baking) was carried out on a hot plate of 100° C. for 120 seconds. Next, exposure was carried out at an exposure amount of 1,000 mJ/cm² using a UV irradiation exposure device (UPE-1255ML) manufactured by USHIO LIGHTING, INC., and then an additional heating treatment (post-baking) was carried out on a hot plate of 220° C., whereby a black resist film 1 to a black resist film 6 were obtained. The transmission spectra and reflection spectra of the obtained black resist film 1 to black resist film 6 were measured using an ultraviolet-visible-near infrared spectrophotometer V-7200 manufactured by JASCO Corporation. The results are shown in FIG. 8 to FIG. 13.

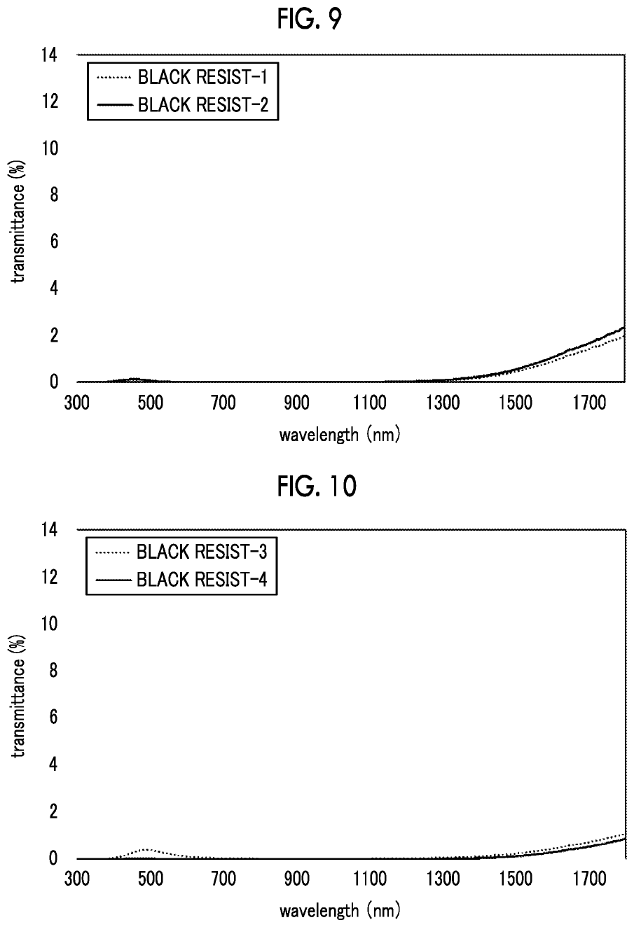

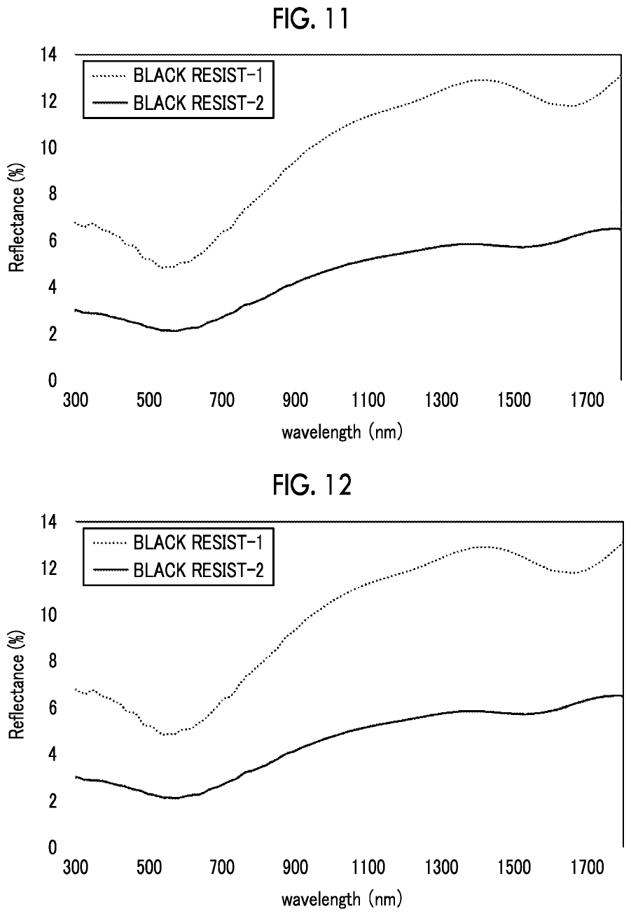

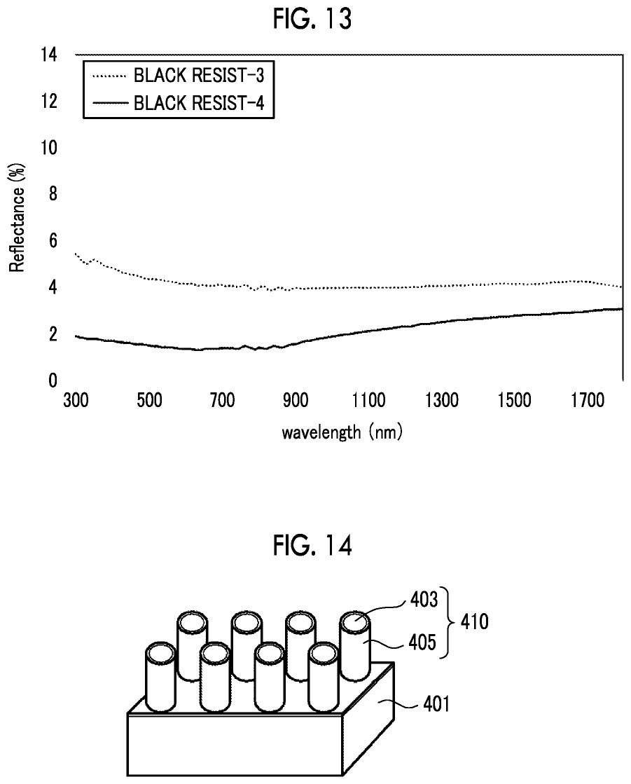

TABLE 10

| | Black resist | Film | Transmission | Reflectance |
|---|---|---|---|---|
| | Kind | thickness | spectrum | spectrum |
| Black resist-1 | Black resist-1 | 1.3 μm | FIG. 8 | FIG. 11 |
| Black resist-2 | Black resist-2 | 1.3 μm | FIG. 8 | FIG. 11 |
| Black resist-3 | Black resist-1 | 2.0 μm | FIG. 9 | FIG. 12 |
| Black resist-4 | Black resist-2 | 2.0 μm | FIG. 9 | FIG. 12 |
| Black resist-5 | Black resist-3 | 3.5 μm | FIG. 10 | FIG. 13 |
| Black resist-6 | Black resist-4 | 3.5 μm | FIG. 10 | FIG. 13 |

As shown in FIG. 8 to FIG. 10, it could be confirmed that the black resist film formed from the black resist containing the dispersion liquid D-25 of Example 1-25 has the same high light shielding properties as the black resist film formed without adding the dispersion liquid D-25.

Further, as shown in FIG. 11 to FIG. 13, it could be confirmed that the black resist film formed from the black resist containing the dispersion liquid D-25 of Example 1-25 can reduce the reflectance.

<Application I to Use Application to Optical Fingerprint Authentication>

Using SW-7001 (product name) manufactured by FUJIFILM Electronic Materials Co., Ltd., coating was carried out by spin coating on a device board for fingerprint authentication so that the film thickness was 3.5 μm. Using an i-line stepper exposure device FPA-3000 i5+(manufactured by Canon Inc.), exposure was carried out through an appropriate mask. Next, a development treatment was carried out using a development device (Act-8 manufactured by Tokyo Electron Limited). The puddle development was carried out at 23° C. for 60 seconds using a 0.3% tetramethylammonium hydroxide (TMAH) aqueous solution as the developer. Then, rinsing was carried out with a spin shower using pure water, and post-baking was carried out at 200° C. for 5 minutes to produce transparent columnar structures having a diameter of 3.5 μm.

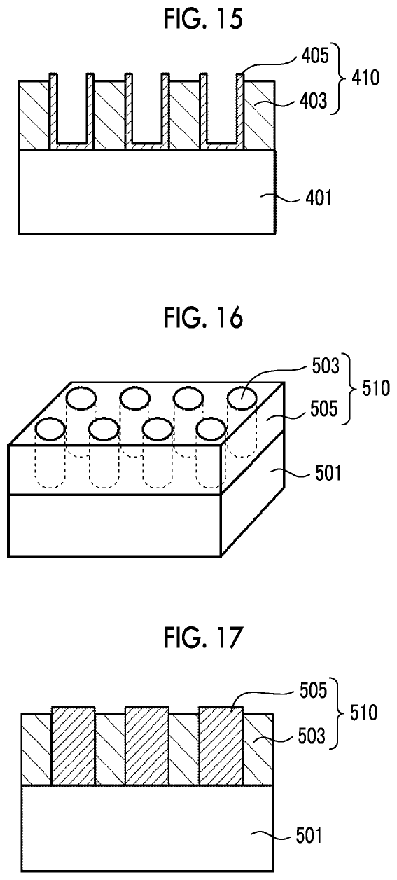

Then, the above black resist-1 was applied to a thickness of 1 μm. Then, exposure, development, and post-baking were appropriately carried out to form structures A in which the uppermost part of the transparent columnar structures was developed, and the other parts were coated with the black resist film (see FIG. 14 and FIG. 15). As illustrated in FIG. 14 and FIG. 15, black structures 410 (the structures A) having transparent columnar structures 403 and a black resist film 405 are formed on a device board for fingerprint authentication 401.

In a case where the structures A were used as a light shielding film for fingerprint authentication, the fingerprint authentication accuracy could be improved.

Even in a case where the black resists 2 to 4 were used instead of the black resist-1, the fingerprint authentication accuracy could be improved.

<Application II to Use Application to Optical Fingerprint Authentication>

In the same manner as in “Application I to use application to optical fingerprint authentication” described above, a columnar structure having a diameter of 3.5 μm was prepared on a device board for fingerprint authentication. Then, the black resist-1 was applied to a thickness of 3.7 μm so that the space between the columnar structures was filled. Then, exposure, development, and post-baking were appropriately carried out to form structure B in which transparent columnar structures were embedded in the black resist film was formed (see FIG. 16 and FIG. 17). As illustrated in FIG. 16 and FIG. 17, black structures 510 (the structures B) having transparent columnar structures 503 and a black resist film 505 are formed on a device board for fingerprint authentication 501.

In a case where the structure B was used as a light shielding film for fingerprint authentication, the fingerprint authentication accuracy could be improved.

Even in a case where the black resists 2 to 4 were used instead of the black resist-1, the fingerprint authentication accuracy could be improved.

### EXPLANATION OF REFERENCES

10: headlight unit
12: light source
14: light shielding unit
16: lens
20: base body
22: light shielding film
23: opening portion
30: light distribution pattern
30a: edge
31: region
32: light distribution pattern
32a: edge
33: notched portion
100: solid-state imaging device
101: solid-state imaging element
102: imaging unit
103: cover glass
104: spacer
105: laminated substrate
106: chip substrate
107: circuit board
108: electrode pad
109: external connection terminal
110: through-electrode
111: lens layer
112: lens material
113: support
114, 115: light shielding film
201: light-receiving element
202: color filter
203: micro lens
204: substrate
205b: blue pixel
205r: red pixel
205g: green pixel
205bm: black matrix
206: p-well layer
207: reading gate part
208: vertical electric charge transfer path
209: element separation region
210: gate insulating film
211: vertical electric charge transfer electrode
212: light shielding film
213, 214: insulating film
215: planarization film
300: infrared sensor
310: solid-state imaging element
311: infrared absorption filter
312: color filter
313: infrared transmitting filter
314: resin film
315: micro lens
316: planarization film
401: device board for fingerprint authentication
403: transparent columnar structure
405: black resist film
410: black structure (structure A)
501: device board for fingerprint authentication
503: transparent columnar structure
505: black resist film
510: black structure (structure B)

What is claimed is:

1. A dispersion liquid comprising:
an inorganic oxide particle surface-treated with at least one compound selected from the group consisting of a compound represented by Formula A1 and a compound represented by Formula A2;
polysiloxane having at least one unit selected from the group consisting of a T unit represented by Formula B1 and a D unit represented by Formula B2; and
an organic solvent,
wherein a content of the polysiloxane is 0.5% to 39% by mass with respect to a total amount of the inorganic oxide particle and the polysiloxane,
Si(R^{A1})(X^{A1})₃ Formula A1:
Si(R^{A2})(R^{A20})(X^{A2})₂ Formula A2:
[R^{B1}SiO_{3/2}] Formula B1:
[R^{B2}R^{B20}SiO] Formula B2:
in Formula A1, R^{A1} represents a monovalent functional group, and X^{A1} represents a hydroxyl group or a monovalent hydrolyzable group,
in Formula A1, three pieces of X^{A1} may be the same or different from each other,
in Formula A2, R^{A2} represents a monovalent functional group, R^{A20} represents an alkyl group or an aryl group, and X^{A2} represents a hydroxyl group or a monovalent hydrolyzable group,
in Formula A2, two pieces of X^{A2} may be the same or different from each other,
in Formula B1, R^{B1} represents a monovalent functional group, and
in Formula B2, R^{B2} represents a monovalent functional group, and R^{B20} represents an alkyl group or an aryl group.

2. The dispersion liquid according to claim 1,
wherein a content of the polysiloxane is 1% to 25% by mass with respect to the total amount of the inorganic oxide particle and the polysiloxane.

3. The dispersion liquid according to claim 1, further comprising:
water,
wherein a content of the water is 0.01% to 5% by mass with respect to a total mass of the dispersion liquid.

4. The dispersion liquid according to claim 3,
wherein the content of the water is 0.1% to 3% by mass.

5. The dispersion liquid according to claim 1,
wherein R^{A1} of Formula A1, R^{A2} of Formula A2, R^{B1} of Formula B1, and R^{B2} of Formula B2 each independently contain at least one group selected from the group consisting of an aliphatic hydrocarbon group, an aryl group, an acryloyloxy group, a methacryloyloxy group, a fluoroalkyl group, a group having a polysiloxane structure, an epoxy group, an amino group, a group having a quaternary ammonium group or a salt thereof, a cyano group, a thiol group, and an oxetanyl group.

6. The dispersion liquid according to claim 1,
wherein R^{A1} of Formula A1, R^{A2} of Formula A2, R^{B1} of Formula B1, and R^{B2} of Formula B2 each independently contain at least one group selected from the group consisting of a fluoroalkyl group and a group having a polysiloxane structure.

7. The dispersion liquid according to claim 1,
wherein in a case where the inorganic oxide particle is surface-treated with the compound represented by Formula A1 and the polysiloxane contains the T unit represented by Formula B1,
R^{A1} of Formula A1 and R^{B1} of Formula B1 are the same group.

8. The dispersion liquid according to claim 1,
wherein in a case where the inorganic oxide particle is surface-treated with the compound represented by Formula A2 and the polysiloxane contains the D unit represented by Formula B2,
R^{A2} of Formula A2 and R^{B2} of Formula B2 are the same group.

9. The dispersion liquid according to claim 1,
wherein the inorganic oxide particle includes silica.

10. The dispersion liquid according to claim 1,
wherein the inorganic oxide particle is a silica particle.

11. A composition comprising:
the dispersion liquid according to claim 1; and
a polymerizable compound.

12. The composition according to claim 11, further comprising a resin.

13. The composition according to claim 11, further comprising a polymerization initiator.

14. The composition according to claim 11, further comprising a coloring material.

15. A cured film formed from the composition according to claim 11.

16. A color filter comprising the cured film:
according to claim 15.

17. A solid-state imaging element comprising:
the cured film according to claim 15.

18. An image display device comprising:
the cured film according to claim 15.
